(19) United States
(12) Patent Application Publication
(10) Pub. No.: US 2010/0176751 A1
(43) Pub. Date: Jul. 15, 2010

(54) SEMICONDUCTOR LIGHT-EMITTING DEVICE AS WELL AS LIGHT SOURCE DEVICE AND LIGHTING SYSTEM INCLUDING THE SAME

(75) Inventors: Shozo Oshio, Osaka (JP); Noriyasu Tanimoto, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Kadoma-shi, Osaka (JP)

(21) Appl. No.: 12/663,678

(22) PCT Filed: Apr. 17, 2009
(86) PCT No.: PCT/JP2009/001777

§ 371 Date: Dec. 8, 2009

(30) Foreign Application Priority Data
May 20, 2008 (JP) 2008-132083

(51) Int. Cl. H05B 39/06; H01L 33/00

(52) U.S. Cl. 315/362; 257/98; 257/E33.001

(57) ABSTRACT

A semiconductor light-emitting device of the present invention includes at least one conductor A, that is patterned electrode, 2a, a conductor B, that is patterned electrode, 2b, and a solid-state light-emitting element 3 on one side of an insulating heat dissipating substrate 1. The solid-state light-emitting element 3 is mounted on the conductor A 2a but is not mounted on the conductor B 2b. The solid-state light-emitting element 3 is mounted in such a manner that the whole lower surface that is a surface opposing to a main light extraction surface of the solid-state light-emitting element 3 adheres to the conductor A 2a. When a mounting surface of the solid-state light-emitting element 3 is viewed from above, the conductor A 2a has an element mounting area on which the whole lower surface of the solid-state light-emitting element 3 is mounted and a plurality of outflow-adhesive capturing areas that are provided adjacent to the periphery of the element mounting area without directional bias with respect to the periphery of the element mounting area. The conductor B 2b is disposed in a portion adjacent to the periphery of the element mounting area other than the outflow-adhesive capturing areas while being electrically separated from the conductor A 2a. In this manner, a semiconductor light-emitting device can be provided that can be produced using orthodox practical techniques, can have high output power, can be mounted with high density, and can be designed with consideration given to the case of lighting failures.

### TECHNICAL FIELD

The present invention relates to all-solid-state semiconductor light-emitting devices that can be produced using highly proven practical techniques and that have high output power and can be mounted with high density, and to light source devices and lighting systems including the same.

### BACKGROUND ART

Conventionally, a semiconductor light-emitting device has been known that includes a patterned wiring conductor, a solid-state light-emitting element, and a wavelength converter on a heat dissipating substrate, with the wavelength converter emitting light with a longer wavelength than that of primary light emitted by the solid-state light-emitting element through excitation by the primary light.

An example of such a semiconductor light-emitting device is a light source that is known as a white LED. Various light source devices and lighting systems that include such semiconductor light-emitting devices have been proposed (see, for example, Patent Literatures 1 and 2).

In the white LED, for example, various ceramic substrates (Al₂O₃, AlN, etc.) or metal substrates (Cu, Al, etc.) are used for the heat dissipating substrate, and a light-emitting diode (hereinafter described as an “LED chip” or simply as a “chip”) with an InGaN-based compound semiconductor used as a light-emitting layer is used widely as the solid-state light-emitting element.

Furthermore, it has been proposed to use, as the wavelength converter, for example, a resin phosphor film with a structure in which powdered inorganic phosphor (phosphor particles) is dispersed in a translucent resin (see, for example, Patent Literatures 1 and 2 described above), translucent phosphor ceramic (see, for example, Patent Literatures 3 and 4), phosphor glass (see, for example, Patent Literatures 5 to 7), and composite ceramic with an optical function (hereinafter described as a “MGC” optical conversion member; see, for example, Patent Literature 8).

The configuration of the LED chip varies depending on the product manufactured by each chip making company, but LED chips are classified roughly into four types according to the leading out configuration of a pair of power supply electrodes and the position of the active layer disposed when the chip is mounted on a heat dissipating substrate, with examples of the four types being shown in FIGS. 17, 19, 21, and 22, respectively.

The LED chip shown in FIG. 17 has a semiconductor light-emitting layer (active layer) that generates LED light near the upper surface of the chip, with the chip mounting surface being taken as a lower surface. It has a structure having a pair of a power supply electrode A 14a and a power supply electrode B 14b on the upper surface. The side with the pair of the power supply electrode A 14a and the power supply electrode B 14b is a light emitting surface.

The LED chip shown in FIG. 19 has the active layer near the upper surface of the chip, with the chip mounting surface being taken as a lower surface. It has a structure having a pair of a power supply electrode A 14a and a power supply electrode B 14b on the upper and lower surfaces of the chip. The side with the power supply electrode A 14a located in the upper part is a light emitting surface.

The LED chip shown in FIG. 21 has the active layer near the lower surface of the chip, with the chip mounting surface being taken as the lower surface. It has a structure having a pair of a power supply electrode A 14a and power supply electrode B 14b on the upper and lower surfaces of the chip. The side with the power supply electrode A 14a located in the upper part is a light emitting surface.

The LED chip shown in FIG. 22 has the active layer near the lower surface of the chip, with the chip mounting surface being taken as the lower surface. It has a structure having a pair of a power supply electrode A 14a and a power supply electrode B 14b on the lower surface. The surface opposing to the side with the pair of the power supply electrode A 14a and the power supply electrode B 14b is a light emitting surface.

Hereinafter, chip mounted structures whose typical examples are shown in FIGS. 17, 19, 21, and 22 are described as “face-up upper-surface two-electrode structure”, “face-up upper- and lower-electrode structure”, “flip-chip upper- and lower-electrode structure”, “flip-chip lower-surface two-electrode structure”, respectively, as required.

Furthermore, for convenience of description, LED chips with the face-up upper- and lower-electrode structure and the flip-chip upper- and lower-electrode structure are described collectively as an “LED chip with an upper- and lower-electrode structure”.

These LED chips are being increased in size every year regardless of the chip structure in order to achieve not only an increase in efficiency accompanied by an improvement in crystal quality but also an increase in intensity (output power) of light (primary light) emitted by one chip.

Moreover, in order to achieve the aforementioned increase in output power, the area of the main light extraction surface of one chip, the input power to one chip, and the density are being increased.

As in the case of LED chips, semiconductor light-emitting devices also are being improved in performance every year.

Particularly, there are strong market demands for an increase in light intensity with a reduction in cost. In order to increase light output, there are tendencies to increase the area of main light extraction surface per LED chip, the total light-emitting area through, for example, mounting of a plurality of chips, and input power and input power density to increase current, every year.

On the other hand, there also are strong demands for small-sized compact lighting sources and high-power point light sources. There are tendencies to reduce the sizes thereof or to increase the output power with chips mounted with high density, and to increase the input power density per chip, every year.

Furthermore, a technique for high-precision mounting of a solid-state light-emitting element also is necessitated as the size thereof is reduced to be compact.

In the case of using the aforementioned conventional LED chip with the face-up upper-surface two-electrode structure, generally, the LED chip is fixed onto a heat dissipating substrate by using, for example, a silver paste. In many cases, a pair of a conductor A, that is patterned electrode, and a conductor B, that is patterned electrode, is provided additionally on the heat dissipating substrate of the chip lower surface and/or at the periphery of the chip, and a pair of a power supply electrode A 14a and a power supply electrode B 14b located on the chip upper surface is electrically connected to the pair of the conductor A and the conductor B by using at least two conductors C, that are conducting wires (see, for instance, Patent Literature 1 described above and Patent Literatures 9 to 13).

On the other hand, in the case of using the aforementioned conventional LED chip with the face-up upper- and lower-electrode structure, generally, the LED chip (or the LED chip fixed onto a submount) is fixed onto a conductor A provided on a heat dissipating substrate, which is one of a pair of the conductor A and a conductor B provided on the heat dissipating substrate and/or at the periphery of the chip, by using an electrically conductive adhesive such as a silver paste or using a solder. The conductor A is connected electrically to a power supply electrode (a lower electrode; the power supply electrode B 14b) located on the chip lower surface. The conductor B is electrically connected to a power supply electrode (an upper electrode; the power supply electrode A 14a) located on the chip upper surface by using at least one conductor C (see, for example, Patent Literature 2 described above and Patent Literatures 14 to 17).

In the case of using the aforementioned conventional LED chip with the flip-chip upper- and lower-electrode structure, generally, the LED chip (or the LED chip fixed onto a submount) is fixed onto a conductor A provided on a heat dissipating substrate (or a submount) by a method using a solder or a solder alloy (for example, Sn, Au/Sn, or Ag/Sn) or a method using ultrasonic bonding or thermocompression bonding, with a metal pad (for example, Au) being provided. The conductor A is connected electrically to a power supply electrode (a lower electrode; the power supply electrode B 14b) located on the chip lower surface. A conductor B is connected electrically to a power supply electrode (an upper electrode; the power supply electrode A 14a) located on the chip upper surface by using at least one conductor C (see, for instance, Patent Literatures 18 to 21).

Furthermore, in the case of using the conventional LED chip with the flip-chip lower-surface two-electrode structure, generally, the chip is fixed with bumps onto a pair of a conductor A and a conductor B provided on a heat dissipating substrate (or a submount) so that a pair of a power supply electrode A 14a and a power supply electrode B 14b located on the chip lower surface is connected to the pair of a conductor A and a conductor B, respectively (see, for example, Patent Literatures 22 to 24).

At least, in the case of using the LED chip with the flip-chip lower-surface two-electrode structure, the lower surface of the chip is fixed not to the conductor A alone but to both members of the pair made up of the conductor A and the conductor B.

Accordingly, in the case of using the LED chip with the flip-chip lower-surface two-electrode structure, basically, the whole lower surface of the chip is not fixed to the heat dissipating substrate so as to adhere thereto.

Hereinafter, the fixing of the LED chips with the aforementioned face-up upper-surface two-electrode structure and the upper- and lower-electrode structure onto heat dissipating substrates will be described, which is known conventionally.

For example, in the case of the LED chip with the aforementioned face-up upper-surface two-electrode structure that is a structure to be mounted on a heat dissipating substrate, for instance, as disclosed in Patent Literatures 9 to 11 and 13 described above, for convenience of, for example, mounting and wiring (for convenience of connection of the conductor C led out from the power supply electrode (upper electrode) located on the chip upper surface to the conductor B to which the chip is not fixed, and arrangement of the chip on the heat dissipating substrate), generally, the LED chip is fixed to an edge portion of one conductor (the conductor A) selected from a pair of the conductor A and the conductor B or it is fixed to a portion that is on the heat dissipating substrate but is not located above the conductor (the conductor A or the conductor B), as disclosed in Patent Literatures 1 and 12 described above.

This tendency also applies to the case of the LED chip with the upper- and lower-electrode structure that is a structure to be mounted on a heat dissipating substrate. This also is disclosed in, for example, Patent Literatures 2 and 16 described above.

In a conventional semiconductor light-emitting device provided with the conductor A (a conductor on which a solid-state light-emitting element is mounted) and the conductor B (a conductor on which no solid-state light-emitting element is mounted) on a heat dissipating substrate, the solid-state light-emitting element is mounted on an edge portion of the conductor A or is mounted on a conductor A with a shape whose outer frame has no recess in many cases.

Furthermore, generally, the area ratio of wiring conductors X, that are patterned electrodes, to the mounting surface of the solid-state light-emitting element on the heat dissipating substrate was low.

The mounting structures relating to the LED chip with the upper- and lower-electrode structure are described briefly, respectively, since they also are mentioned in the following Patent Literatures.

Patent Literature 14 described above discloses a mounting technique in which an LED chip is disposed directly on a contact layer provided on a substrate, and the LED chip is fixed in such a manner that the whole lower surface of the LED chip adheres to the contact layer.

Patent Literature 15 described above discloses a mounting technique in which an LED chip is disposed directly on a base, and the LED chip is fixed in such a manner that the whole lower surface of the LED chip adheres to the base.

Patent Literature 17 described above discloses a mounting technique in which an LED chip is disposed directly on a solid pattern provided on a composite material substrate, and the LED chip is fixed in such a manner that the whole lower surface of the LED chip adheres to the solid pattern.

Patent Literature 25 discloses a mounting technique in which an electrically conductive layer having a rectangular parallelepiped shape with rotational symmetry and line symmetry when viewed from the upper surface is provided on an insulating layer provided on a planar conductive substrate, an LED chip is disposed on the central part of the electrically conductive layer, and the LED chip is fixed in such a manner that the whole lower surface of the LED chip adheres to the electrically conductive layer.

However, all the above-mentioned techniques are not intended either to control the temperature increase in an LED chip or to mount a plurality of chips with high density as in the present invention.

Furthermore, many of the patent literatures disclose sectional side views only, and it is not indicated, for example, that the LED chip is disposed on the central part of the conductor corresponding to the conductor A and that the conductor corresponding to the conductor A has a shape that substantially has rotational symmetry but does not have line symmetry, which are described in this application.

In the conventional technique described in Patent Literature 17 mentioned above, the width of the solid pattern is the same as that of the lower surface of the LED chip in at least the sectional side view, the areas of the upper surfaces of the LED chip, the solid pattern, and the composite material substrate decrease in this order when the LED lighting device is viewed from the upper surface. Thus, it cannot be said that at least the outer frame of the lower surface of the LED chip is located inside the outer frame of the upper surface of the solid pattern, and the solid pattern is not formed to have an edge along the whole outer periphery of the lower surface of the LED chip.

Patent Literature 26 discloses a mounting technique in which an LED chip is disposed on the central part of a conductor pattern provided on a submount member, and the LED chip is fixed in such a manner that the whole lower surface of the LED chip adheres to the conductor pattern. However, it is not intended to mount a plurality of chips with high density, and the conductor pattern has a shape similar to a rectangular parallelepiped shape having line symmetry but no rotational symmetry.

### CITATION LIST

### Patent Literature

[Patent Literature 1] Japanese Patent No. 2927279
[Patent Literature 2] U.S. Pat. No. 6,812,500
[Patent Literature 3] JP 2004-146835A
[Patent Literature 4] JP 2006-5367A
[Patent Literature 5] JP 2001-214162A
[Patent Literature 6] JP 2007-39303A
[Patent Literature 7] JP 2006-117511A
[Patent Literature 8] WO/2004/065324
[Patent Literature 9] Japanese Patent No. 3139618
[Patent Literature 10] Japanese Patent No. 3393089
[Patent Literature 11] Japanese Patent No. 3400958
[Patent Literature 12] Japanese Patent No. 3640153
[Patent Literature 13] JP 2001-223388A
[Patent Literature 14] U.S. Pat. No. 6,670,748
[Patent Literature 15] JP 2000-244021A
[Patent Literature 16] Japanese Patent No. 3813599
[Patent Literature 17] JP 2007-5709A [Patent Literature 18] JP 2006-502563W [Patent Literature 19] JP 2007-535823W [Patent Literature 20] JP 2006-344682A [Patent Literature 21] JP 2007-294728A [Patent Literature 22] Japanese Patent No. 3257455
[Patent Literature 23] JP 2006-352085A
[Patent Literature 24] U.S. Patent No. 2006/0124947A1
[Patent Literature 25] JP 2003-347599A
[Patent Literature 26] Japanese Patent No. 3948483

### SUMMARY OF INVENTION

### Technical Problem

In conventional semiconductor light-emitting devices, many potential problems that have not been recognized until now are becoming apparent with an increase in input power density, an increase in current, or an increase in mounting density, and there has been a problem in that it is difficult to obtain a highly practicable small-sized compact semiconductor light-emitting device that has both high output power and high reliability and that can be produced at low cost.

Particularly, it was difficult to achieve a reduction in the size and an increase in output power while obtaining high production speed and high reliability.

Hereinafter, the problems in the mounting techniques are described in detail with reference to drawings.

Generally, the more the size of a point light source is intended to be reduced, the more the mounting surface of a solid-state light-emitting element 3 on a heat dissipating substrate 1 is limited (see FIG. 42), which in turn requires a highly precise mounting technique.

This is because a slight mounting misalignment of the solid-state light-emitting element 3 on a conductor A 2a tends to cause defects in electrical connection or on the mounting surface.

For example, when an LED chip is mounted on the conductor A 2a by using a solder material as an adhesive, generally, a method is employed in which the solder material provided with flowability is placed on the mounting center portion of the conductor A 2a, the solid-state light-emitting element 3 is placed thereon, and the solder material is then solidified, so that the solid-state light-emitting element 3 is bonded onto the conductor A 2a.

Hereinafter, descriptions are made with reference to FIG. 43.

In this case, the solder material (adhesive 23) with flowability is pressed together with the solid-state light-emitting element 3 to spread so that the gap between the surface of the conductor A 2a and the solid-state light-emitting element 3 is reduced and then it fills a part or the whole of the gap with a certain thickness distribution (see the lower row in FIGS. 43(b) and 43(c) (sectional side views)).

Thereafter, the solder material (adhesive 23) is hardened and the solid-state light-emitting element 3 is fixed thereonto (see the lower row in FIG. 43(d)).

In such a mounting technique, basically, the solder material (adhesive 23) is placed, with the center thereof being located at a position (the intersection of alternate long and short dash lines in the upper row in FIG. 43) that coincides with the center position of the region where the solid-state light-emitting element 3 is intended to be mounted.

However, in the conventional semiconductor light-emitting devices, as shown in the upper row in FIG. 43 as an example (top view), the conductor A 2a has a shape having no symmetry around the position (around the mounting center of the solid-state light-emitting element 3) where the solder material (adhesive 23) is placed and a shape having edge portions in at least a place near the position where the solder material is placed and a place distant from there, in many cases.

Accordingly, the solder material with flowability spreads to reduce the gap between the conductor A 2a and the solid-state light-emitting element 3 during the process of mounting the solid-state light-emitting element 3. Generally, however, since the solder material does not flow beyond the edge portion (hereinafter described as a “proximal end”) of the conductor A 2a located in the place near the position where the solder material is placed due to its physical property, the solder material trapped thereby flows in the direction toward the edge portion located in a place distant from the position where the solder material is placed (see the upper row in FIG. 43(c)).

Consequently, a phenomenon occurs in which the center of gravity M of the solder material shifts in the direction going away from the proximal end, with the initial position where the solder material is placed being taken as a reference point (see the upper row in FIG. 43(c)).

Generally, the solder thickness is at its maximum around the center-of-gravity part of the solder material. Therefore, in such a case, the solid-state light-emitting element 3 is mounted, with the part having a maximum solder thickness being shifted a little towards the above-mentioned direction from the mounting center (see the upper row in FIG. 43(c)).

In such a case, the solid-state light-emitting element 3 is shifted from the mounting center during the latter half of the mounting process during which the solder material with flowability is solidified, and mounting is completed in this state (see the upper row in FIG. 43(d)).

In many conventional semiconductor light-emitting devices, as shown in the upper row in FIG. 43, the conductor A 2a has a shape with no symmetry with respect to the mounting center of the solid-state light-emitting element 3 and a shape having edge portions in at least a place near the position where the solder material is placed and a place distant from there. Accordingly, there is a problem in that such a device is mounted in a position shifted towards the above-mentioned direction from the mounting center, which results in a mounted state thereof where defects in the electrical connection and on the mounting surface become problematic (see the upper row in FIG. 43(d)).

Furthermore, in the case of the conductor A 2a with such a shape, since the solid-state light-emitting element 3 is mounted while the solder material is scant on the side of the proximal end and is slightly excessive on the opposite side to the proximal end under the lower surface of the solid-state light-emitting element 3, a defectively-mounted/poorly-mounted state tends to occur around the side of the proximal end of the lower surface of the solid-state light-emitting element 3 and therefore a gap tends to be generated between the solid-state light-emitting element 3 and the conductor A 2a, which also is a problem (see the lower row in FIGS. 43(c) and 43(d)).

The gap generated between the lower surface of the solid-state light-emitting element 3 and the conductor A 2a results in a decrease in heat dissipation efficiency, which causes local heating. In the case of such a mounted state, the output efficiency of primary light is decreased and thereby the output light intensity is reduced, which is a problem.

On the other hand, generally, with respect to the semiconductor light-emitting device, in order to reduce the size of a point light source without impairing the appearance, i) the solid-state light-emitting element 3 is disposed in the central part of the heat dissipating substrate 1, ii) the area of the upper surface of the heat dissipating substrate 1 is reduced as much as possible, so that the area and shape of the upper surface of the heat dissipating substrate 1 are allowed to be similar to those of the main light extraction surface of the solid-state light-emitting element 3 as much as possible, and then iii) a part of the conductor A 2a (the part other than the mounting surface of the solid-state light-emitting element 3) and the conductor B 2b may be disposed in the space other than the part where the solid-state light-emitting element 3 is mounted on the heat dissipating substrate 1 (see FIG. 42).

However, as also can be seen from FIG. 42, the more the size of the point light source is intended to be reduced, the more the space other than the part where the solid-state light-emitting element 3 is mounted on the heat dissipating substrate 1 is limited and is reduced. Therefore it becomes difficult to use the conductor A 2a effectively as a heat dissipator and an increase in output power becomes difficult, which also is a problem.

Furthermore, in addition to the problems described above, there are, for example, the following problems relating to the present invention.

(1) Decrease in Luminous Efficiency Due to Temperature Increase in LED Chip that Serves as Excitation Source

That is, an increase in current for increasing input power density results in an increase in the level of, for example, Joule heat generated due to a resistance component of the LED chip. Also, the chip temperature increases, the lattice vibration in the solid increases, and the recombination probability of an electron-hole pair in the light-emitting layer decreases. As a result, the electro-optic conversion efficiency of the chip is decreased.

(2) Decrease in Luminous Efficiency Due to Uneven Temperature Distribution and Local Heating in the LED Chip, which Become Further Apparent with an Increase in Size of the Chip

That is, because of uneven heat dissipation of the LED chip due to, for example, variations in mounting of the LED chip (particularly, uneven joint/bonding to the heat dissipating substrate), the electrode pattern of the chip, the condition of leading out the chip wiring, and the shape of the wiring pattern on which the chip is mounted, a slight difference in temperature distribution that occurs inside the chip is amplified with an increase in input power to cause local heating. As a result, the portion corresponding thereto has a decreased luminous efficiency, which results in a decrease in luminous efficiency of the chip.

(3) Decrease in Power Efficiency with Heat Generation in Wiring Conductor

That is, an increase in current results in an increase in the level of, for example, Joule heat generated due to wiring resistance. Also, the temperature of the wiring conductor increases, wiring resistance increases to cause a rapid increase in temperature, and further wiring resistance increases, which result in an increase in rate of heat loss of input power.

(4) Decrease in Reliability Accompanying Heat Generation in Wiring Joint Portion

That is, with an increase in current, due to, for example, temperature increase caused by the resistance of the wiring joint portion and the change in various properties of the member accompanying heat generation in the LED chip and the wiring conductor, thermal stress at the joint portion increases and joint strength decreases, and, for example, cracks and peeling tend to occur, which results in a decrease in durability.

(5) Decrease in Reliability and Product Yield Due to Damage Caused Through Mounting of LED Chip

That is, particularly, not only a semiconductor light-emitting device with a flip-chip structure (the semiconductor light-emitting devices with the flip-chip upper- and lower-electrode structure or the flip-chip lower-surface two-electrode structure) has a high probability of being damaged while being mounted because it is fixed, with a large area in the vicinity of the active layer with relatively sensitive properties being used as a mounting surface, but also the active layer tends to be subjected to, for example, distortion from heating accompanying an increase in input power density or an increase in current due to its structure. These are amplified with an increase in input power and thereby variations in properties and cracks tend to be caused. Furthermore, the good product rate tends to be decreased with an increase in the number of chips accompanying high-density mounting.

(6) Decrease in Light Extraction Efficiency Due to Light Absorption by High Heat Dissipating Substrate

That is, when employing a substrate (for instance, an aluminum nitride (AlN) ceramic substrate) of a material with high thermal conductivity for improving the heat dissipation properties of the semiconductor light-emitting device, the rate of absorption of LED chip light by the heat dissipating substrate increases, which decreases the ratio of output light of the semiconductor light-emitting device.

Furthermore, there are not only problems from such technical viewpoints but also problems from the following viewpoints of production and sale.

(7) Low Price Level Demanded in the Market with Respect to White LED

That is, regardless of the short development history of the white LED, the market thereof is growing rapidly and popularity thereof is increasing, which results in severe market competition. Accordingly, in a small developing market, it is difficult to develop products that satisfy the market demands unless expensive components (for example, high power LED chips, red phosphors, heat dissipating substrates, etc.) are used that are under development and that have a high value due to scarcity. This inevitably makes the production cost high.

Due to such background circumstances, it has been necessary to solve all those problems by using only orthodox practical techniques that have been practically proven sufficiently in, for example, their applications to electronic devices in the past without using new techniques that have not been practically proven until now.

Moreover, from the user's point of view, with consideration given to the situations of use as light sources, semiconductor light-emitting devices are demanded that can be restored instantly and can light up immediately without requiring replacement of the light source even if a wiring joint portion is disconnected due to, for example, the life of the wiring or vibration that stops lighting up, for example, in the darkness or while driving a vehicle at night.

However, it is a reality that there are not many such highly convenient semiconductor light-emitting devices for lighting that are designed with consideration given to daily life.

The present invention is intended to solve such problems and to provide small-sized, high power semiconductor light-emitting devices capable of high production speed and having high reliability.

Furthermore, the present invention also is intended to provide semiconductor light-emitting devices that can be produced using orthodox practical techniques, can have high power, can be mounted with high density, and also can be designed with consideration given to the case of lighting failures according to customer's needs and convenience, particularly, semiconductor light-emitting devices that are suitable, for example, for general lighting, camera flashes, vehicle headlights, projection light sources, and liquid crystal backlights, and to provide light source devices and lighting systems including the same.

### Solution to Problem

In order to achieve the object described above, a semiconductor light-emitting device according to the present invention has a configuration that includes at least one conductor A, that is patterned electrode, a conductor B, that is patterned electrode, and a solid-state light-emitting element on one side of an insulating heat dissipating substrate, with the solid-state light-emitting element being mounted on the conductor A but not being mounted on the conductor B, wherein the solid-state light-emitting element has a pair of power supply electrodes either on an upper surface or on the upper and lower surfaces thereof. Furthermore, the solid-state light-emitting element is mounted in such a manner that a whole lower surface that is a surface opposing to a main light extraction surface of the solid-state light-emitting element adheres to the conductor A, the conductor A has an element mounting area on which the whole lower surface of the solid-state light-emitting element is mounted and a plurality of outflow-adhesive capturing areas that are provided adjacent to the periphery of the element mounting area without directional bias with respect to the periphery of the element mounting area when the mounting surface of the solid-state light-emitting element is viewed from above. The conductor B is disposed in a portion adjacent to the periphery of the element mounting area other than the outflow-adhesive capturing areas while being electrically separated from the conductor A.

According to this configuration of the semiconductor light-emitting device, the conductor A has a shape in which the outflow-adhesive capturing areas are provided without directional bias in the periphery of the element mounting area on which the whole lower surface of the solid-state light-emitting element is mounted. In a preferred aspect, the conductor A has a shape with at least two edge portions located in places that are relatively distant from each other in opposing directions with respect to the mounting center and that are distant from the mounting surface. Accordingly, the conductor A can prevent mounting defects/mounting failures as well as displacement of the center of gravity of the adhesive (solder material) placed in a position to serve as the mounting center of the solid-state light-emitting element. In this manner, the conductor A of the semiconductor light-emitting device according to the present invention controls the aforementioned mounting misalignment of the solid-state light-emitting element and the aforementioned local heating, and promotes increases in reliability and in output power of primary light to increase the output power of the semi-conductor light-emitting device.

Furthermore, the conductor A with the aforementioned shape also functions as a good balanced heat dissipator and light reflector. Accordingly, it is possible to obtain a semiconductor light-emitting device having a configuration that provides a higher heat dissipation effect and a higher light extraction effect.

Moreover, in the configuration of the semiconductor light-emitting device according to the present invention, it is preferable that the conductor B is disposed in such a manner as to have the outer frame center (centroid) in a position to avoid the centerlines of the vertical and horizontal directions of the solid-state light-emitting element, and it is preferable that the conductor A have a shape with rotational symmetry.

According to this preferable example, the conductor B is disposed in a place near the power supply electrode (generally, disposed in a position to avoid the centerlines of the vertical and horizontal directions of the solid-state light-emitting element) of the solid-state light-emitting element, and thereby an alignment configuration can be obtained in which the space above the heat dissipating substrate is used effectively to adapt to the structure and operating principle of the solid-state light-emitting element. Thus the size of the semiconductor light-emitting device can be reduced.

Furthermore, it is preferable that the solid-state light-emitting element is mounted in a position that falls on a central part of an outer frame of the conductor A, the conductor A have a shape based on the same shape as that of the lower surface of the solid-state light-emitting element, and it is formed to have an edge along the whole outer periphery of the lower surface of the solid-state light-emitting element.

According to this preferred example, since the conductor A has some tolerance to the aforementioned mounting misalignment of the solid-state light-emitting element, a semiconductor light-emitting device can be obtained that allows relatively high reliability to be obtained even when the production speed is increased.

Furthermore, in the configuration of the semiconductor light-emitting device according to the present invention, it is preferable that a conductor X that denotes all the conductor A and the conductor B has an area ratio of at least 50% but less than 100% on the heat dissipating substrate. In this case, it is preferable that the conductor A has a total area ratio of at least 50% of the conductor X. Furthermore, in this case, it is preferable that the heat dissipating substrate has a shape with inversion symmetry, and the solid-state light-emitting element has a mounting surface on a line of symmetry of the heat dissipating substrate.

According to this preferred example, the minimum required conductors X have a high area ratio on the heat dissipating substrate and the alignment configuration can be obtained in which the space above the heat dissipating substrate is used effectively to adapt further to the structure and operating principle of the solid-state light-emitting element. Thus, the size of the semiconductor light-emitting device further can be reduced.

Furthermore, since the conductor A accounts for the majority of the total area of the conductors X, the conductor A that also functions as a heat dissipator of the solid-state light-emitting element accounts for a high area ratio on the heat dissipating substrate. As a result, a semiconductor light-emitting device can be obtained that has a configuration in which the solid-state light-emitting element has a high heat dissipation effect.

Moreover, the solid-state light-emitting element is allowed to be located on the line of symmetry of the heat dissipating substrate, so that a good appearance also can be obtained.

These synergistic effects make it possible to obtain small-sized, high-power semi-conductor light-emitting devices with high production speed and high reliability.

Furthermore, in the configuration of the semiconductor light-emitting device according to the present invention, it is preferable that a conductor X that denotes all the conductor A and the conductor B has substantially rotational symmetry on one flat surface of the heat dissipating substrate.

Moreover, in the configuration of the semiconductor light-emitting device according to the present invention, it is preferable that the conductor B and an electrode lead-out part of the solid-state light-emitting element are connected electrically to each other with a conductor C, that is conducting wire, the conductor B has a larger number of wiring structures as compared to the conductor A. Electric power is supplied to the solid-state light-emitting element using a pair of the conductor A and the conductor B, and the semiconductor light-emitting device has a wiring structure that allows the same electric power to be supplied to the same solid-state light-emitting element under the same conditions through switching at least the conductor B.

In the configuration of the semiconductor light-emitting device according to the present invention, it is preferable that the solid-state light-emitting element has a structure including a semiconductor light-emitting layer that serves as a source of primary light near an upper surface when the mounting surface of the solid-state light-emitting element is taken as a lower surface, and electrodes on the upper and lower surfaces of the solid-state light-emitting element.

In the configuration of the semiconductor light-emitting device according to the present invention, which further includes a wavelength converter on the main light extraction surface of the solid-state light-emitting element, it is preferable that the wavelength converter emits light with a longer wavelength than that of primary light through excitation by the primary light that is emitted by the solid-state light-emitting element.

The configuration of a light source device according to the present invention is characterized by including the aforementioned semiconductor light-emitting device of the present invention.

The configuration of this light source device makes it possible to obtain small-sized, high-power light source devices.

In this manner, heat generated in the solid-state light-emitting element that increases with an increase in input power is conducted at a uniform and high speed to high thermal conductors (for example, the conductor A, heat dissipating substrate, and external heat dissipator) disposed under the solid-state light-emitting element through heat conduction that utilizes the whole lower surface of the solid-state light-emitting element that serves as a mounting surface, and the temperature increase in the solid-state light-emitting element can be controlled.

At the same time, also in the horizontal direction of the mounting surface that diverges from the lower surface of the solid-state light-emitting element, heat is transmitted through the conductor A with good thermal conductive properties to diffuse relatively uniformly, and heat dissipation efficiency is improved by fully using good thermal conductive properties and a relatively large area of a portion of the conductor A that is not located under the lower surface of the solid-state light-emitting element, so that the decrease in luminous efficiency of the solid-state light-emitting element that is caused by temperature increase and uneven heat dissipation (particularly, uneven heat dissipation in the plane of the light-emitting layer) in the solid-state light-emitting element, which gradually are becoming considered as problems with an increase in size of the solid-state light-emitting element, is controlled. As a result, the output power of the semiconductor light-emitting device can be increased.

Furthermore, while the heat dissipation paths for transmitting heat through the conductor A in the horizontal direction of the mounting surface are obtained by using a shape with no line symmetry of the conductor A, the area ratio of the lower surface of the solid-state light-emitting element in the central part of the conductor A is increased and a plurality of solid-state light-emitting elements are allowed to be disposed in close proximity, so that it is possible to mount a plurality of solid-state light-emitting elements with high density.

Furthermore, the configuration of a lighting system according to the present invention is characterized by including the aforementioned semiconductor light-emitting device of the present invention and a circuit switching device for switching a power supply terminal of the semiconductor light-emitting device. In this case, in the aforementioned semiconductor light-emitting device of the present invention, the conductor B and the electrode lead-out part of the solid-state light-emitting element are connected electrically to each other with the conductor C. The conductor B has a larger number of wiring structures as compared to the conductor A, and electric power is supplied to the solid-state light-emitting element by using a pair of the conductor A and the conductor B. The semiconductor light-emitting device is characterized by having a wiring structure that allows the same electric power to be supplied to the same solid-state light-emitting element under the same conditions through switching of at least the conductor B.

According to the configuration of this lighting system, even if a wiring joint portion is disconnected and it stops lighting up, it is possible to restore it instantly without replacing the light source and to light up immediately using the same semiconductor light-emitting device.

### Advantageous Effects of Invention

According to the present invention, small-sized, compact, high-power, highly reliable semiconductor light-emitting devices (for example, white LEDs) and light source devices that can be produced at low cost and can allow a circuit design to be made with precautions for lighting failure can be provided by using orthodox practical techniques.

Furthermore, a lighting system can be provided that can be restored instantly without replacing the semiconductor light-emitting device and light source even if the wiring joint portion is disconnected and thereby lighting failure is caused.

### BRIEF DESCRIPTION OF DRAWINGS

FIG. 1 is a top view showing an example of a semiconductor light-emitting device according to the present invention.

FIG. 2 is a top view showing an example of a semiconductor light-emitting device according to the present invention.

FIG. 3 is a top view showing an example of a semiconductor light-emitting device according to the present invention.

FIG. 4 is a top view showing an example of a semiconductor light-emitting device according to the present invention.

FIG. 5 is a top view showing an example of a semiconductor light-emitting device according to the present invention.

FIG. 6 is a top view showing an example of a semiconductor light-emitting device according to the present invention.

FIG. 7 is a top view showing an example of a semiconductor light-emitting device according to the present invention.

FIG. 8 is a top view showing an example of a semiconductor light-emitting device according to the present invention.

FIG. 9 is a diagram showing an example of an electrical circuit configuration in a semiconductor light-emitting device according to the present invention.

FIG. 10 is a diagram showing an example of an electrical circuit configuration in a semiconductor light-emitting device according to the present invention.

FIG. 11 is a diagram showing an example of an electrical circuit configuration in a semiconductor light-emitting device according to the present invention.

FIG. 12 is a top view showing an example of a semiconductor light-emitting device according to the present invention.

FIG. 13 is a top view showing an example of a semiconductor light-emitting device according to the present invention.

FIG. 14 is a top view showing an example of a semiconductor light-emitting device according to the present invention.

FIG. 15 is a top view showing an example of a semiconductor light-emitting device according to the present invention.

FIG. 16 is a top view showing an example of a semiconductor light-emitting device according to the present invention.

FIG. 17 is a longitudinal sectional view showing an example of a solid-state light-emitting element that is used in a semiconductor light-emitting device of the present invention.

FIG. 18 is a longitudinal sectional view showing an example of a solid-state light-emitting element that is used in a semiconductor light-emitting device of the present invention.

FIG. 19 is a longitudinal sectional view showing an example of a solid-state light-emitting element that is used in a semiconductor light-emitting device of the present invention.

FIG. 20 is a longitudinal sectional view showing an example of a solid-state light-emitting element that is used in a semiconductor light-emitting device of the present invention.

FIG. 21 is a longitudinal sectional view showing an example of a solid-state light-emitting element that is used in a semiconductor light-emitting device of the present invention.

FIG. 22 is a reference drawing showing a solid-state light-emitting element having a different structure from that of a solid-state light-emitting element that is used in a semiconductor light-emitting device of the present invention.

FIG. 23 is a schematic view showing an example of a wavelength converter that is used in a semiconductor light-emitting device of the present invention.

FIG. 24 is a side view showing an example of a wavelength converter that is used in a semiconductor light-emitting device of the present invention.

FIG. 25 is a side view showing an example of a wavelength converter that is used in a semiconductor light-emitting device of the present invention.

FIG. 26 is a longitudinal sectional view (a cross-sectional view taken on line I-I′ shown in FIG. 1) showing an example of a semiconductor light-emitting device according to the present invention.

FIG. 27 is a longitudinal sectional view showing an example of a semi-conductor light-emitting device according to the present invention.

FIG. 28 is a longitudinal sectional view showing an example of a semi-conductor light-emitting device according to the present invention.

FIG. 29 is a schematic view (top view) showing an example of a heat dissipation path in a semiconductor light-emitting device according to the present invention.

FIG. 30 is a schematic view (longitudinal sectional view) showing an example of a heat dissipation path in a semiconductor light-emitting device according to the present invention.

FIG. 31 is a schematic view (longitudinal sectional view) showing an example of a heat dissipation path in a semiconductor light-emitting device according to the present invention.

FIG. 32 is a longitudinal sectional view showing an example of a semi-conductor light-emitting device according to the present invention.

FIG. 33 is a longitudinal sectional view showing an example of a semi-conductor light-emitting device according to the present invention.

FIG. 34 is a longitudinal sectional view showing an example of a semi-conductor light-emitting device according to the present invention.

FIG. 35 is a longitudinal sectional view showing an example of a semi-conductor light-emitting device according to the present invention.

FIG. 36 is a longitudinal sectional view showing an example of a semi-conductor light-emitting device according to the present invention.

FIG. 37 is a longitudinal sectional view showing an example of a light source device according to the present invention.

FIG. 38 is a longitudinal sectional view showing an example of a light source device according to the present invention.

FIG. 39 is a longitudinal sectional view showing an example of a light source device according to the present invention.

FIG. 40 shows a top view and schematic sectional side views (sectional views taken on line II-II′ and line III-III′ shown in the top view) showing an example of a light source device according to the present invention.

FIG. 41 is a diagram showing an example of a lighting system according to the present invention.

FIG. 42 is a top view showing a conventional semiconductor light-emitting device.

FIG. 43 is a diagram for explaining problems of a conventional semiconductor light-emitting device.

### DESCRIPTION OF EMBODIMENTS

Hereinafter, the present invention will be described in further detail with reference to embodiments.

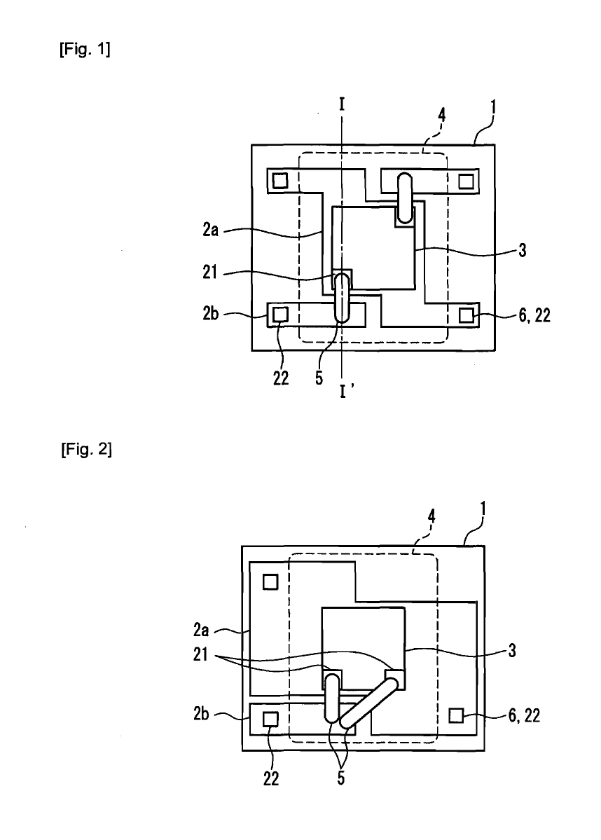

First, with reference to FIG. 1, common items to the respective embodiments of the present invention will be described. FIG. 1 is a top view showing an embodiment of the semiconductor light-emitting device according to the present invention.

(Heat Dissipating Substrate 1)

As shown in FIG. 1, the heat dissipating substrate 1 is a substrate for mounting a solid-state light-emitting element 3, with the substrate being provided with at least one conductor A, that is patterned electrode, 2a.

The heat dissipating substrate 1 has one flat surface at least on one side, and this one side with the flat surface is used as a mounting surface for the solid-state light-emitting element 3.

The heat dissipating substrate 1 is a substrate made of at least one material selected from metal, a semiconductor material, a ceramic material, and resin, with at least the mounting surface being an electrically insulating surface (hereinafter, described as an “insulating heat dissipating substrate” or simply as an “insulating substrate”).

The base of the heat dissipating substrate 1 may be basically either an electrically insulating substrate or an electrically conductive substrate (particularly, a metal substrate). However, a particularly preferable heat dissipating substrate 1 is an insulating substrate formed only of an electrical insulator for the reason described later.

The base of the heat dissipating substrate 1 to be used can be selected suitably from, specifically, substrates made of inorganic materials, such as copper, aluminum, stainless steel, metal oxides (for example, aluminum oxide, silicon oxide, and glass), metal nitrides (for example, aluminum nitride and silicon nitride), silicon carbide, metal silicon, and carbon, silicone-based resin, and epoxy-based resin.

The mounting surface to be used is selected suitably from, for example, metal oxides (for instance, aluminum oxide, silicon oxide, titanium oxide, magnesium oxide, and glass), metal nitrides (for instance, aluminum nitride and silicon nitride), and other inorganic insulating materials, as well as silicone-based resin, epoxy-based resin, and other organic insulating materials.

A preferable heat dissipating substrate 1 for obtaining good heat dissipation properties is an insulating substrate in which the aforementioned base is any one of metal, ceramic compact, or a complex of metal and ceramic.

On the other hand, the heat dissipating substrate 1 that is preferable for reducing the production cost is a forming body composed mainly of resin (for example, silicone-based resin), and is, for example, an insulating substrate of a resin forming body containing a filler (for instance, inorganic particles of alumina, silica, or various metals).

Furthermore, the heat dissipating substrate 1 that is preferable for improving light extraction efficiency is a heat dissipating substrate with the mounting surface having excellent visible light reflection properties, for example, a heat dissipating substrate with a white body color.

Such a heat dissipating substrate 1 not only is easy to obtain at a relatively low price and to handle but also has high thermal conductivity. Accordingly, it works to control a temperature increase in the solid-state light-emitting element 3.

When using an insulating substrate formed only of an insulator, as the heat dissipating substrate 1, a semiconductor light-emitting device having electrical potentials in only the limited regions can be provided relatively easily. Accordingly, it becomes easy to take electricity into account in structural design, and therefore, for example, a light source device that is easy to handle with respect to electricity flow can be provided relatively easily.

On the other hand, when an insulating substrate including an electrically conductive substrate as its base is used as the heat dissipating substrate 1, very high thermal conductivity can be obtained. Accordingly, it becomes possible to provide a semi-conductor light-emitting device with excellent heat dissipation properties.

Therefore, when the ease of electrical structural design is considered to be important, it is preferable that an insulating substrate formed only of an insulator is used. On the other hand, when the heat dissipation properties are considered to be important, it is preferable that an insulating substrate including an electrically conductive substrate as its base is used.

In the case of any of the above-mentioned insulating substrates, a preferable heat dissipating substrate 1 is a substrate with a thermal conductivity of at least 1 W/mK or a substrate formed of a material with a thermal conductivity of at least 1 W/mK. The thermal conductivity is preferably at least 10 W/mK and more preferably at least 100 W/mK.

When using such a heat dissipating substrate 1, the heat that is generated upon input of electric power to the semiconductor light-emitting device is conducted easily to a lower temperature portion through the heat dissipating substrate 1. Accordingly, thermal diffusion is promoted and thereby the temperature increase in the whole semi-conductor light-emitting device is controlled. As a result, a high heat dissipation effect can be obtained.

A preferable heat dissipating substrate 1 is one that is easy to handle and has a flat plate shape. The use of such a heat dissipating substrate makes it easy to mount the solid-state light-emitting element 3 and also allows the production process to be simplified.

(Conductor A 2a and conductor B, that is patterned electrode, 2b (Conductors X))

Hereinafter, the conductor A 2a and the conductor B 2b are described collectively as conductors X.

The conductor A 2a and the conductor B 2b are paired conductors for supplying electric power to the solid-state light-emitting element 3.

The conductors X can be conductors composed mainly of at least one material selected from, for example, metal, an electrically conductive compound, and a semi-conductor. However, in order to obtain a conductor capable of having both low resistivity and high thermal conductivity, it is preferable that the conductors X each be formed of a material composed mainly of metal, with the material having a metal component ratio of at least 80% by weight.

Specific examples of the above-mentioned metal include gold (Au), silver (Ag), copper (Cu), platinum (Pt), palladium (Pd), zinc (Zn), nickel (Ni), titanium (Ti), zircon (Zr), hafnium (Hf), vanadium (V), niobium (Nb), tantalum (Ta), chromium (Cr), molybdenum (Mo), tungsten (W), rhodium (Rh), iridium (Jr), aluminum (Al), tin (Sn), silicon (Si), and iron (Fe) as well as alloys and silicides of these metals. Examples of the electrically conductive compound include low-resistance materials such as titanium nitride (TiN) and tantalum nitride (TaN), and examples of the semiconductor include transparent electrically conductive materials such as In—Sn—O and ZnO:Al.

In order to obtain a semiconductor light-emitting device with high light extraction efficiency, the conductors X are preferably conductors with metallic luster.

When examples of a rough guide of preferable metallic luster are indicated using the light reflectance obtained in the evaluation at room temperature as the scale, for example, the light reflectance within the wavelength range (420 to 660 nm) between blue and red is at least 50%, and preferably the light reflectance within the wavelength range (380 to 780 nm) of visible light is at least 80%.

It is preferable that both the conductor A 2a and the conductor B 2b have the afore-mentioned metallic luster. However, basically, it is no problem when at least the conductor A 2a has metallic luster.

Such conductors X to be used each are at least one selected from a conductor plate, a conductor forming body, a conductor thick film, and a conductor thin film. However, the conductors X that are preferable from the viewpoint of production cost are conductor thick films.

The above-mentioned conductor thick film and conductor thin film are preferably those proven practically in many cases, for example, in forming wirings for electronics in the past. For example, the conductor thick film is preferably a thick film formed using a screen printing method, ink jet method, doctor blade method, slurry casting method, spin coating method, precipitation method, electrophoresis method, or plating technology. The conductor thin film is preferably a thin film formed using any one of a vapor deposition technique, sputtering technique, and chemical vapor deposition.

The conductor plate refers to, for example, a metal plate (Al, Ti, Nb, Ta, Cr, Mo, W, Rh, Jr, Fe, Ni, Pd, Pt, Cu, Ag, Zn, alloys thereof, stainless steel, or others) that has been subjected to a patterning process.

When the aforementioned metal plate that has been subjected to a patterning process is bonded to the heat dissipating substrate 1 with, for example, an adhesive, it can be used as a heat dissipating substrate 1 with a conductor A 2a.

For convenience of designing the semiconductor light-emitting device, the thickness of the conductor A 2a is desirably as thick as possible within a range of about 3 mm or less. Specific examples of the thickness are at least 10 mum but less than 3 mm, preferably at least 100 mum but less than 3 mm, and more preferably at least 300 mum but less than 3 mm.

Such a thick conductor A 2a has excellent thermal conductivity and therefore functions as a good heat dissipator.

Moreover, such a thick conductor A 2a has low wiring resistance and thereby generation of Joule heat is controlled in the conductor A 2a. Thus, it is possible to control the temperature increase in the solid-state light-emitting element 3.

The electrode pads 6 shown in FIG. 1 are conductors (usually, metal) that are provided for the conductors X, for example, for leading out wiring as required. They also can be used as power supply terminals.

(Overview of Solid-State Light-Emitting Element 3)

The solid-state light-emitting element 3 is an electro-optic conversion element for converting electrical energy into light energy, for example, a light-emitting diode (LED), a semiconductor laser (LD), an inorganic EL element (EL), or an organic EL element (OLED).

In terms of principle of operation of the electro-optic conversion element, the solid-state light-emitting element 3 of the semiconductor light-emitting device that is preferable for obtaining a high power point light source is either an LED or an LD, while the solid-state light-emitting element 3 that is preferable for obtaining high power surface light source is either an EL or an OLED.

The solid-state light-emitting element 3 that is preferable for obtaining a highly reliable semiconductor light-emitting device is any one of an LED, an LD, and an EL, each of which includes a light-emitting layer formed of an inorganic material.

The solid-state light-emitting element 3 that is preferable for obtaining output light with good color rendering properties of light and output light with uniform light diffusing surface is either an EL or an OLED that has a relatively wide emission spectrum half width and emits light with little directionality.

Furthermore, the solid-state light-emitting element 3 that is preferable from the viewpoint of energy efficiency obtained in wavelength conversion performed by the wavelength converter 4 is a solid-state light-emitting element that emits primary light (visible light) having an emission peak in the range of wavelengths that are as long as possible in the visible range of wavelengths longer than 380 nm. In order to obtain white output light, it is preferably a solid-state light-emitting element that emits primary light having an emission peak in the violet to blue-green wavelength range of at least 380 nm but shorter than 510 nm.

When consideration is given to the present situation of, for example, output level of the solid-state light-emitting element 3, it is preferably a solid-state light-emitting element that emits primary light having an emission peak preferably in the violet to blue wavelength range of at least 400 nm but shorter than 480 nm and more preferably in the blue wavelength range of at least 430 nm but shorter than 475 nm.

The use of such a solid-state light-emitting element 3 makes it possible to configure a semiconductor light-emitting device in such a manner that the difference in energy between light absorption and emission performed by the wavelength converter 4 is relatively small. Accordingly, in terms of principle of wavelength conversion, it is allowed to function so as to reduce the light energy loss that accompanies the wavelength conversion. Therefore, the heating value of the wavelength converter 4 due to the energy loss is reduced and the temperature increase caused by the heat accumulation action of the wavelength converter 4 is controlled, which results in alleviation of, for example, temperature quenching of a phosphor contained in the wavelength converter 4. For such reasons, even when an increase in the intensity of the light output (primary light) from the solid-state light-emitting element 3 is achieved by increasing the input power density, a semiconductor light-emitting device can be obtained that tends to maintain relatively high wavelength conversion efficiency.

The size of the solid-state light-emitting element 3 is not particularly limited, and an example thereof is 0.01 mm² to 100 cm² in terms of the outer frame area in top view.

When the solid-state light-emitting element 3 is an LED, as an example, the outer frame area per LED in top view is about at least 0.01 mm² but smaller than 5 cm². However, in terms of the balance between the input power and point light source properties, in order to obtain high power point light source, the outer frame area is preferably in the range of about at least 0.25 mm² but smaller than 4 cm², particularly about at least 0.6 mm² but smaller than 2 cm².

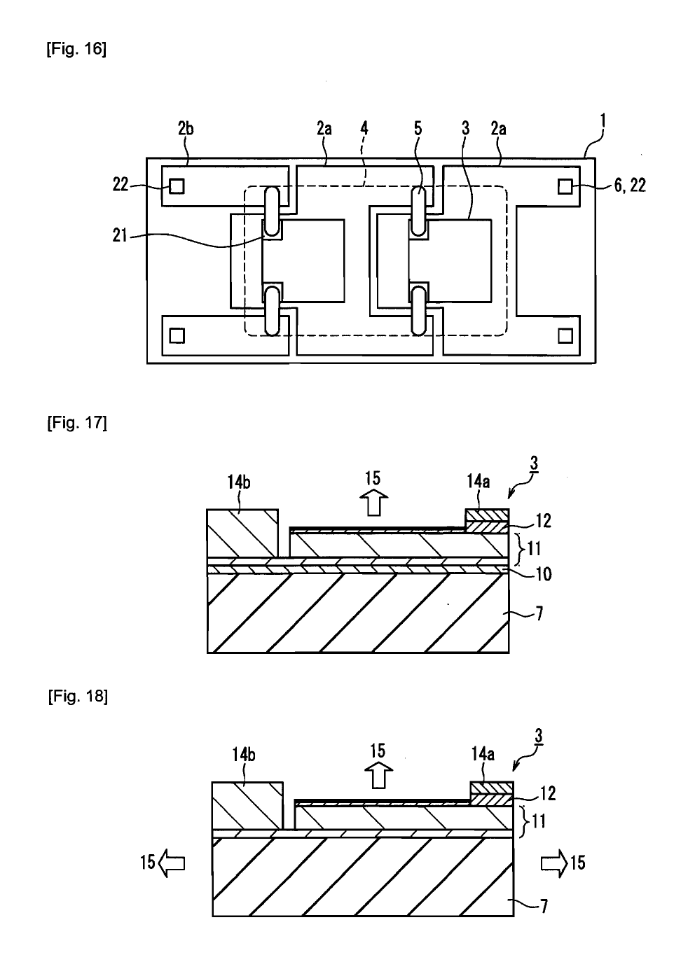

FIGS. 17 to 22 each show a longitudinal sectional view of the structure of an LED as an example of the solid-state light-emitting element 3.

Preferably, the semiconductor light-emitting layer 11 that serves as a source of the primary light 15 of the solid-state light-emitting element 3 has a structure that is supported by either an insulating base 7 or an electrically conductive base 8. This reinforces poor mechanical strength of the semiconductor light-emitting layer 11 and makes it easy to handle.

A suitable production method of the solid-state light-emitting element 3 with such a structure is disclosed in, for example, JP 2007-150331A and therefore is not described in detail herein.

A preferable insulating base 7 or electrically conductive base 8 is at least one semi-conductor base selected from metal composed mainly of a group IV metal element, a compound composed mainly of a group IV element, and a compound composed mainly of a group III-V element.

The semiconductor base not only can be either the insulating base 7 or the electrically conductive base 8 depending on the presence or absence of impurities contained therein but also functions as a base with good thermal conductive properties. Accordingly, it also is possible to control the temperature increase in the solid-state light-emitting element 3.

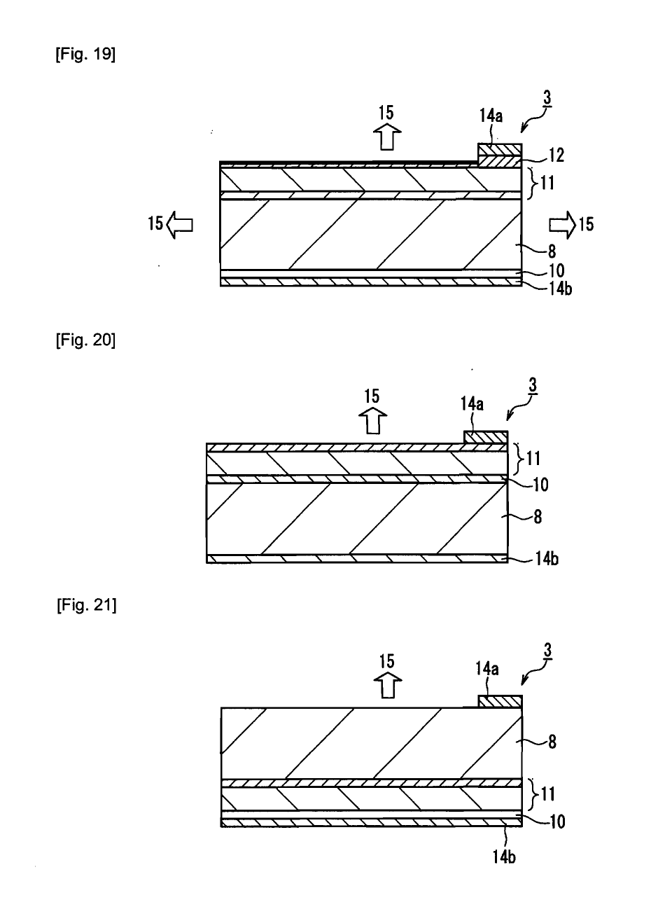

As shown in FIGS. 19 to 21, it is preferable that the solid-state light-emitting element 3 have at least one electrode on the same surface as the main light extraction surface that emits the primary light 15, and have an upper- and lower-electrode structure that emits the primary light 15 upon voltage application to the whole in thickness direction extending from the upper surface to the lower surface of the solid-state light-emitting element 3. This can reduce the number of conductors C 5 (see, for example, FIG. 1) that are disposed in the vicinity of the light extraction surface and that block part of the primary light 15. Thus, a relatively high power primary light 15 can be obtained.

More preferably, as shown in FIGS. 19 and 20, the solid-state light-emitting element 3 is provided with a semiconductor light-emitting layer 11 (active layer) that serves as a source of the primary light 15, near the upper surface, with the mounting surface of the solid-state light-emitting element 3 being taken as a lower surface. Preferably, it has a structure (the aforementioned face-up upper- and lower-electrode structure) with electrodes (a pair of the power supply electrode A 14a and the power supply electrode B 14b) on the upper and lower surfaces of the solid-state light-emitting element 3. This can avoid fixing a large area in the vicinity of the semiconductor light-emitting layer 11 with relatively sensitive properties, and thereby the semiconductor light-emitting layer 11 tends not to be subjected to, for example, distortion by heating that accompanies an increase in input power density and an increase in current and the electric leak in the semiconductor light-emitting layer 11 after mounting caused by an electrically conductive adhesive tends not to occur. Thus, a structure can be obtained that tends not to cause cracks or variations in properties.

Furthermore, since the primary light 15 that is emitted by the semiconductor light-emitting layer 11 is output without passing through the base, there also is an advantage that it is easy to obtain a primary light 15 with strong directionality that is suitable for use in, for example, a headlight.

Furthermore, it is preferable that the solid-state light-emitting element 3 have a structure composed mainly of a metal material and a semiconductor material. Since this allows a solid-state light-emitting element 3 composed of only materials with good thermal conductive properties to be obtained, the solid-state light-emitting element 3 has increased thermal conductivity. As a result, the heat dissipation properties are improved and as a result the temperature increase can be controlled.

Preferably, the vicinity of the main light extraction surface has an uneven structure formed by a surface roughening treatment. This allows high light extraction efficiency to be obtained and thereby the output power of the primary light 15 can be increased.

Preferably, the material for the semiconductor light-emitting layer 11 is any one of a group II-VI compound, a group III-V compound, and a group IV compound. Since such a semiconductor light-emitting layer 11 functions as a highly efficient inorganic electro-optic conversion structure, there are less problems in terms of reliability and high power primary light 15 can be obtained.

Preferably, the lower surface of the solid-state light-emitting element 3 has an area that is either equal to or larger than that of the upper surface located on the main light extraction surface. This not only allows the base (the insulating base 7, electrically conductive base 8, or semiconductor base) to have a larger volume than that of the semiconductor light-emitting layer 11 that acts as a heat source but also increases the area where it is in contact with the wiring electrode A 2a that also functions as a heat conductor and a heat dissipator. Accordingly, the transfer rate of the generated heat increases, and thereby the temperature increase in the solid-state light-emitting element 3 can be controlled.

Preferably, the solid-state light-emitting element 3 and the conductor A 2a are bonded to each other with a material (for instance, a silver paste or a solder) composed mainly of metal.

Generally, a metal material has high thermal conductivity. Accordingly, this makes it possible to transmit heat generated by the solid-state light-emitting element 3 to the conductor A 2a and the heat dissipating substrate 1 efficiently. Thus, the temperature increase in the solid-state light-emitting element 3 can be controlled.

Hereinafter, for example, the structure and arrangement of the solid-state light-emitting element 3 are described in detail.

(Specific Structural Example of Solid-State Light-Emitting Element 3)

Hereinafter, specific structural examples of the solid-state light-emitting element 3 are described. However, the production of the solid-state light-emitting elements 3 with such structures can be carried out by the method disclosed in, for example, JP 2007-150331A and is not described in detail herein.

(Specific Structural Example 1 of Solid-State Light-Emitting Element 3)

FIG. 17 is a longitudinal sectional view showing an example of the structure of the solid-state light-emitting element 3 that is used in a semiconductor light-emitting device of the present invention. As shown in FIG. 17, a reflective layer 10 is provided on the insulating base 7, and the semiconductor light-emitting layer 11 is provided on the reflective layer 10. The upper surface of the semiconductor layer (not shown) located on the upper surface of the reflective layer 10 and the upper surface of the semiconductor light-emitting layer 11 are provided with electrodes (the power supply electrode B 14b and the translucent electrode 12) for applying voltage to the semi-conductor light-emitting layer 11, respectively.

In order to facilitate wiring connection, a part of the translucent electrode 12 is provided with the power supply electrode A 14a as required.

The insulating base 7 is provided for supporting the semiconductor light-emitting layer 11 to increase the mechanical strength of the semiconductor light-emitting layer 11 and for supplying electric power to the semiconductor light-emitting layer 11 by using a pair of the power supply electrode A 14a and the power supply electrode B 14b provided on the upper surface of the solid-state light-emitting element 3.

The material for the electrically insulating base 7 to be used herein can be the same material as that for the heat dissipating substrate 1 that can be used as the afore-mentioned insulating substrate. Specifically, the insulating base 7 to be used can be one formed of at least one material selected from a ceramic material, a semiconductor material, and glass.

For further specific examples, the electrically insulating base 7 is an insulating base formed of an inorganic material such as metal oxide (for example, aluminum oxide, silicon oxide, glass, or various composite oxides (Y₃Al₅O₁₂ or others)), metal nitride (for example, aluminum nitride or silicon nitride), or silicon carbide.

The reflective layer 10 reflects light emitted in the direction of the insulating base 7 among the light emitted by the semiconductor light-emitting layer 11 and is provided for improving the efficiency of light extraction from the upper surface of the solid-state light-emitting element 3 that serves as a main light extraction surface.

The reflective layer 10 to be used can be selected suitably from thick films (with a thickness of about at least 1 mum but less than 1 mm) or thin films (with a thickness of about at least 10 nm but less than 1 mum) formed of the same metals (for instance, Au, Ag, Cu, Pt, Pd, Zn, Ni, Ti, Zr, Hf, V, Nb, Ta, Cr, Mo, W, Rh, Ir, Al, Sn, Si, and Fe) as those used for the conductors X, alloys or silicides of these metals, and the afore-mentioned electrically conductive compounds (TiN, TaN, and others) as well as inorganic compound powder with a white body color (for example, BaSO₄, TiO₂, Al₂O₃, SiO₂, and MgO) and thick films (with a thickness of about at least 1 mum but less than 1 mm) formed of mixed powder thereof.

The reflective layer 10 is not limited to those described above as long as it has high reflectance (for instance, the reflectance at room temperature is at least 70%, preferably at least 80%) with respect to visible light (light within a wavelength range of 380 to 780 nm).

A preferable reflective layer 10 is a reflective layer containing at least one selected from the above-mentioned metals, alloys, and silicides. Since such a reflective layer 10 has a relatively high thermal conductivity, it is possible to dissipate heat that is released from the semiconductor light-emitting layer 11 during the operation of the solid-state light-emitting element 3 to the insulating base 7 at a high speed.

Furthermore, when the reflective layer 10 is electrically conductive, it can be used as one that also serves as a power supply electrode.

The semiconductor light-emitting layer 11 is a multilayer structure formed of at least an inorganic or organic semiconductor contained therein that emits luminescence (injection electroluminescence or intrinsic electroluminescence) upon electric power supply.

Examples of the multilayer structure that emits injection electroluminescence can include a structure with at least p-type and n-type inorganic or organic semiconductors stacked therein. Examples of the inorganic semiconductor can include group IV compounds (for instance, SiC), group III-V compounds (for instance, InGaN-based compound), and group II-VI compounds (for instance, a ZnSSe-based compound and ZnO).

On the other hand, examples of the multilayer structure that emits intrinsic electroluminescence can include a structure containing at least an inorganic phosphor (particularly, a wide band gap semiconductor). Examples of the inorganic phosphor can include phosphors containing, as a phosphor matrix, sulfide (ZnS, CaS, SrS, SrGa₂ S₄, BaAl₂S₄, and others), oxysulfide (Y₂O₂S, La₂O₂S, and others), nitride (AlN, LaSi₃N₅, Sr₂Si₅N₈, CaAlSiN₃, and others), oxynitride (BaSi₂O₂N₂ and others), or oxide (Zn₂SiO₄ and others), with an activator being added to the phosphor matrix.

The production of the solid-state light-emitting element that emits intrinsic electroluminescence can be carried out by the method disclosed in, for example, Japanese Patent No. 2840185 and is not described in detail herein.

The translucent electrode 12 is used for supplying electric power to the semi-conductor light-emitting layer 11 and extracting the light emitted by the semiconductor light-emitting layer 11 to the outside of the solid-state light-emitting element 3 as the primary light 15. It is composed of semitransparent metal (for instance, Au) or the aforementioned transparent electrically conductive material (for instance, In—Sn—O or ZnO:Al).

The power supply electrode A 14a and the power supply electrode B 14b each serve as an electrical terminal for supplying electric power to the semiconductor light-emitting layer 11 and usually are composed of the same metal as that used for the conductors X.

When direct-current or alternating-current voltage or pulse voltage is applied to the power supply electrode A 14a and the power supply electrode B 14b of the solid-state light-emitting element 3 that is configured as described above, an electric current flows through the semiconductor light-emitting layer 11 and thereby electric power is supplied thereto.

The electric power supplied to the semiconductor light-emitting layer 11 is converted into light through an electro-optic conversion action of the multilayer structure formed of at least an inorganic or organic semiconductor contained therein. Accordingly, that light is emitted as the primary light 15 from the solid-state light-emitting element 3 through a translucent member (a translucent electrode 12 or the aforementioned translucent base).

Such a solid-state light-emitting element 3 can be produced by, for example, the following production method.

(1) After single crystal thin films formed of n-type and p-type InGaN-based compounds are staked on a single-crystal substrate (for example, sapphire, SiC, GaN, Si, or Y₃Al₅O₁₂) by using an epitaxial crystal growth technique, a metal film that forms the reflective layer 10 then is formed by, for example, vapor deposition, and thus a light-emitting structure is obtained.

(2) For example, the same metal film as that described above is formed on the substrate composed of, for example, Si, SiC, or AlN by a different production process from that described above, and thus a support structure is obtained.

(3) The light-emitting structure of the above-mentioned item (1) and the support structure of the above-mentioned item (2) are joined using a joining layer (alloy (for example, Au—Sn or Ag—Sn), metal (for example, Mo or Ti), or a compound (for example, SiO₂, Si₃N₄, HfO₂, or TiN) with a thickness of about at least 10 nm but less than 1000 nm) so that the two metal films formed as described above are bonded to each other.

(4) The single-crystal substrate obtained after joining is removed by a physical, chemical, or mechanical treatment and thereby a structure is obtained in which the light-emitting structure is attached onto the support structure. Thereafter, for example, Au is used to form the power supply electrode A 14a and the power supply electrode B 14b. Thus, the solid-state light-emitting element 3 is completed.

(Specific Structural Example 2 of Solid-State Light-Emitting Element 3)

Hereinafter, the structure and operation of another solid-state light-emitting element 3 will be described.

FIG. 18 is a longitudinal sectional view showing another example of the structure of the solid-state light-emitting element 3 that is used for a semiconductor light-emitting device of the present invention. The solid-state light-emitting element 3 shown in FIG. 18 is one having a structure with no reflective layer 10 in the solid-state light-emitting element 3 that has been described with reference to FIG. 17.

The details and basic operations of the respective members are identical to those described with reference to FIG. 17 and therefore the descriptions thereof are not repeated here.

Such a solid-state light-emitting element 3 can be obtained by, for example, stacking the aforementioned single crystal thin films of the n-type and p-type semiconductors on the aforementioned translucent single-crystal substrate by using the epitaxial crystal growth technique, and vacuum depositing the power supply electrode A 14a and power supply electrode B 14b (for example, Au).

Furthermore, such a solid-state light-emitting element 3 also can be obtained by, for example, sequentially stacking, on a glass substrate, respective thin films of a transparent electrode formed of the transparent electrically conductive material, an insulator, the aforementioned inorganic phosphor containing a wide band gap semi-conductor as its matrix, an insulator, the aforementioned transparent electrode by using, for example, a sputtering technique.

In the solid-state light-emitting element 3 with such a structure, the primary light 15 is output not only through the translucent electrode provided on the upper surface but also from the translucent insulating base 7 (particularly, side faces). Therefore, by arranging the wavelength converter 4 (see, for example, FIG. 1) in such a manner that it surrounds the upper surface and side faces of the solid-state light-emitting element 3, the primary light 15 that leaks from the side faces of the solid-state light-emitting element 3 also can be used as excitation light for the wavelength converter 4. As a result, not only the output power of the semiconductor light-emitting device can be increased, but also the variations in luminescence color can be reduced.

(Specific Structural Examples 3 and 4 of Solid-State Light-Emitting Element 3)

FIGS. 19 and 20 are longitudinal sectional views showing further examples of the structure of the solid-state light-emitting element 3 that is used for a semiconductor light-emitting device of the present invention. Each of the solid-state light-emitting elements 3 shown in FIGS. 19 and 20 is a solid-state light-emitting element with a structure in which the semiconductor light-emitting layer 11 is provided on the electrically conductive base 8 while the reflective layer 10 is provided under the semi-conductor light-emitting layer 11, and further a power supply electrode B 14b is provided on the lower surface of the solid-state light-emitting element 3.

The structure may include a translucent electrode 12 for applying voltage to the semi-conductor light-emitting layer 11 and if necessary, the power supply electrode A 14a that are provided on the semiconductor light-emitting layer 11 as shown in FIG. 19, or may include no translucent electrode 12, with a part of the semiconductor light-emitting layer 11 also functioning as the translucent electrode 12, as shown in FIG. 20.

Furthermore, the reflective layer 10 may be provided between the electrically conductive base 8 and the power supply electrode B 14b as shown in FIG. 19, or may be provided between the semiconductor light-emitting layer 11 and the electrically conductive base 8 as shown in FIG. 20.

The electrically conductive base 8 is provided for supporting the semiconductor light-emitting layer 11 to increase the mechanical strength of the semiconductor light-emitting layer 11 and supplying electric power to the semiconductor light-emitting layer 11 by using a pair of the power supply electrode A 14a and the power supply electrode B 14b provided on the upper and lower surfaces of the solid-state light-emitting element 3, respectively.

The electrically conductive base 8 to be used can be one formed of at least one material selected from metal and a semiconductor material. Examples of the afore-mentioned semiconductor material include gallium nitride, silicon carbide, and silicon.

In the solid-state light-emitting element 3 with the above-mentioned structure, in the case of a structure in which the injection electroluminescence is emitted, the reflective layer 10 needs to have electrical conductivity so that electrons or holes are injected into the semiconductor light-emitting layer 11. The reflective layer 10 to be used can be selected suitably from thick films and thin films of the aforementioned metals (for instance, Au, Ag, Cu, Pt, Pd, Zn, Ni, Ti, Zr, Hf, V, Nb, Ta, Cr, Mo, W, Rh, Jr, Al, Sn, Si, and Fe) as well as alloys and silicides of these metals.

The details of other members are as described above with reference to FIG. 17 and therefore the descriptions thereof are not repeated here.

When direct-current or alternating-current voltage or pulse voltage is applied to the power supply electrode A 14a and the power supply electrode B 14b that are provided on the upper and lower surfaces of the solid-state light-emitting element 3 with such a structure described above, an electric current flows through the semiconductor light-emitting layer 11 and as a result electric power is supplied thereto.

The electric power that has been supplied to the semiconductor light-emitting layer 11 is converted into light by an electro-optic conversion action of the multilayer structure. Accordingly, the light is emitted as the primary light 15 from the solid-state light-emitting element 3 through the translucent members (the translucent electrode 12 and the electrically conductive base 8 (in the case of having translucency)).

The solid-state light-emitting element 3 with the structure shown in FIG. 19 can be obtained by, for example, stacking the single crystal thin films of n-type and p-type semiconductors on the electrically conductive semiconductor single-crystal substrate (for instance, SiC or GaN) by using an epitaxial crystal growth technique, forming the power supply electrode A 14a (for instance, Au) by vapor deposition, and thereafter forming the reflective layer 10 and the power supply electrode B 14b on the surface of the semiconductor single-crystal substrate located on the side where the single crystal thin films of the semiconductors have not been formed.

On the other hand, the solid-state light-emitting element 3 with the structure shown in FIG. 20 can be produced by, for example, the same production method as that employed in the case of the solid-state light-emitting element 3 with the structure shown in FIG. 17.

The solid-state light-emitting elements 3 with the structures shown in FIGS. 19 and 20 each have a structure in which one (the power supply electrode B 14b) of a pair of power supply electrodes is provided on the lower surface of the solid-state light-emitting element 3. Accordingly, the light extraction surface from which the primary light 15 is extracted has a relatively large area, and thereby a structure suitable for obtaining high power semiconductor light-emitting device is obtained.

(Specific Structural Example 5 of Solid-State Light-Emitting Element 3)

FIG. 21 is a longitudinal sectional view showing yet another example of a structure of the solid-state light-emitting element 3 that is used in a semiconductor light-emitting device of the present invention. The solid-state light-emitting element 3 shown in FIG. 21 is a solid-state light-emitting element with a structure in which the semiconductor light-emitting layer 11 is provided under the electrically conductive base 8 and the power supply electrode B 14b is provided on the lower surface of the solid-state light-emitting element 3, while the power supply electrode A 14a is provided on the electrically conductive base 8, with the electrically conductive base 8 having translucency.

As shown in FIG. 21, the structure may include the reflective layer 10 provided under the semiconductor light-emitting layer 11, or may include no reflective layer 10, with the power supply electrode B 14b also functioning as the reflective layer 10.

The electrically conductive base 8 is provided not only for supporting the semi-conductor light-emitting layer 11 to increase the mechanical strength of the semi-conductor light-emitting layer 11 and supplying electric power to the semiconductor light-emitting layer 11 by using a pair of the power supply electrode A 14a and the power supply electrode B 14b that are provided on the upper and lower surfaces of the solid-state light-emitting element 3, but also for extracting the light emitted by the semiconductor light-emitting layer 11 to the outside of the solid-state light-emitting element 3 as the primary light 15.

The electrically conductive base 8 to be used can be one made of a semiconductor material. Examples of the semiconductor material include gallium nitride and silicon carbide.

In the solid-state light-emitting element 3 with the above-mentioned structure, in the case of a structure in which the injection electroluminescence is emitted, the reflective layer 10 needs to have electrical conductivity so that electrons or holes are injected into the semiconductor light-emitting layer 11 as described with reference to FIGS. 19 and 20. The reflective layer 10 to be used can be selected suitably from thick films and thin films of the aforementioned metals as well as alloys and silicides of these metals.

The details of other members are as described above with reference to FIG. 17 and therefore the descriptions thereof are not repeated here.

Furthermore, the operation of the solid-state light-emitting element 3 also is as described above with reference to FIGS. 19 and 20 and therefore the description thereof is not repeated here.

The solid-state light-emitting element 3 with the structure shown in FIG. 21 can be obtained by, for example, stacking the single crystal thin films of n-type and p-type semiconductors on the semiconductor single-crystal substrate (for instance, SiC or GaN) having electrical conductivity by using the epitaxial crystal growth technique, forming the power supply electrode B 14b that also functions as the reflective layer 10, and thereafter forming the power supply electrode A 14a on the surface of the semi-conductor single-crystal substrate located on the side where the semiconductor single crystal thin film has not been formed.

As in the case of the solid-state light-emitting elements 3 shown in FIGS. 19 and 20, in the solid-state light-emitting elements 3 with such structures, not only the light extraction surface from which the primary light 15 is extracted has a relatively large area but also the semiconductor light-emitting layer 11 where heat is generated is located in a place near the mounting surface of the heat dissipating substrate 1. Thus, this is a preferable structure in view of dissipating the heat of the semiconductor light-emitting layer 11 relatively efficiently.

The solid-state light-emitting element 3 with the structure shown in FIG. 21 is one that is known as a solid-state light-emitting element with the aforementioned flip-chip upper- and lower-electrode structure.

(Reference Structural Example of Solid-State Light-Emitting Element 3)

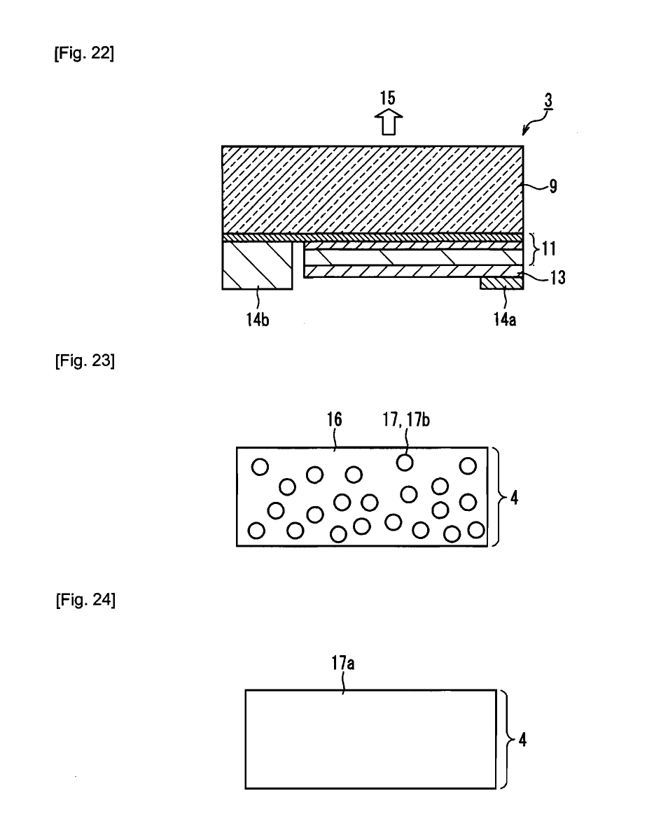

FIG. 22 is a longitudinal sectional view showing, for reference, an example of the solid-state light-emitting element 3 with a different structure from that of the solid-state light-emitting element 3 that is used in a semiconductor light-emitting device of the present invention. The solid-state light-emitting element 3 shown in FIG. 22 is one with a structure in which the semiconductor light-emitting layer 11 is provided under the translucent base 9 and the power supply electrode A 14a and the power supply electrode B 14b are provided on the lower surface of the solid-state light-emitting element 3. In FIG. 22, numeral 13 denotes an electrode.

The translucent base 9 is provided not only for supporting the semiconductor light-emitting layer 11 to increase the mechanical strength of the semiconductor light-emitting layer 11 and supplying electric power to the semiconductor light-emitting layer 11 by using a pair of the power supply electrode A 14a and the power supply electrode B 14b that are provided on the lower surfaces of the solid-state light-emitting element 3 but also for extracting the light emitted by the semiconductor light-emitting layer 11 to the outside of the solid-state light-emitting element 3 as the primary light 15.

The translucent base 9 to be used can be one made of a semiconductor material or an insulator material. Examples of the semiconductor material include gallium nitride and silicon carbide, and examples of the insulator material include various metal oxides (for instance, aluminum oxide, silicon oxide, and glass).

The details of other members are as described above with reference to FIG. 17 and therefore the descriptions thereof are not repeated here.

When direct-current or alternating-current voltage or pulse voltage is applied to the power supply electrode A 14a and the power supply electrode B 14b of the solid-state light-emitting element 3 with such a structure described above, an electric current flows through the semiconductor light-emitting layer 11 and thereby electric power is supplied thereto.

The electric power supplied to the semiconductor light-emitting layer 11 is converted into light through an electro-optic conversion action of the multilayer structure formed of at least an inorganic or organic semiconductor contained therein. Accordingly, this light is emitted as the primary light 15 from the solid-state light-emitting element 3 through the translucent base 9.

The solid-state light-emitting element 3 with the reference structure shown in FIG. 22 is one that is known as a solid-state light-emitting element with the aforementioned flip-chip lower-surface two-electrode structure.

(Wavelength Converter 4)

The wavelength converter 4 is a photoconverter that undergoes wavelength conversion in which light (primary light 15) emitted by the solid-state light-emitting element 3 is converted into light with a longer wavelength than that of the primary light 15. The wavelength converter 4 is a structure containing at least an organic or inorganic, so-called photoluminescence phosphor (one that satisfies the practical performance level; and hereinafter described simply as a “phosphor”) 17 (see, for example, FIG. 23).

Because of excellent chemical stability under a relatively high temperature condition of 100 to 200 degrees C., a preferable phosphor 17 is an inorganic phosphor. Accordingly, it is preferable that the wavelength converter 4 contains an inorganic phosphor. This allows it to function as a highly reliable wavelength converter 4.

The wavelength converter 4 is preferably any one of a resin phosphor film, a forming body containing an inorganic phosphor, and a complex containing an inorganic phosphor, and more preferably a phosphor plate.

Such a wavelength converter 4 is a wavelength converter that has been technically well-proven in the field of, for example, electronics, and a highly reliable wavelength converter 4 also is easy to produce.

Particularly, the phosphor plate also is easy to handle and therefore, it also is possible to simplify the process for producing the semiconductor light-emitting device.

Preferably, the forming body containing the inorganic phosphor is any one of translucent phosphor ceramic, phosphor glass, and composite ceramics with a phosphor function (the MGC optical conversion member). Such a forming body not only has been technically proven or nearly proven but also has high thermal conductivity because it is all inorganic and functions to control the temperature increase in the wavelength converter 4.

On the other hand, the complex containing the inorganic phosphor is preferably a translucent base with an inorganic phosphor film in which an inorganic phosphor film composed mainly of inorganic phosphor powder is provided on at least one side thereof. Such a translucent base with an inorganic phosphor film is a wavelength converter that has been practically proven sufficiently in, for example, phosphor lamps or electron tubes. Therefore, when using the translucent base with the inorganic phosphor film, the wavelength converter 4 with excellent performance can be produced easily. Furthermore, since the production of the wavelength converter 4, for which a wide range of know-how is required, can be carried out in a separate process beforehand, the risk management relating to the production process loss also is facilitated. Furthermore, the part where heat is generated due to wavelength conversion is only the phosphor film. When the translucent base is formed of an inorganic material, the translucent base functions as a heat dissipator with high thermal conductivity, and thereby it also is possible to control the temperature increase in the wavelength converter 4.

The above-mentioned temperature increase in the wavelength converter 4 is a phenomenon that is caused by energy loss (Stokes loss) accompanying wavelength conversion.

For example, in a white LED light source that has a configuration with a combination of a blue LED and an yellow phosphor and that has a correlated color temperature of around 5000 K, about 10 to 30% of the light energy of the primary light emitted by the blue LED is consumed to be converted into heat, which then is accumulated to cause the aforementioned temperature increase.

For example, in a white LED light source including a phosphor film formed with phosphor powder dispersed in translucent resin, the translucent resin has a thermal conductivity of 0.1 to 0.5 W/mK, which is lower than that of the inorganic material by one to two digits. This causes a large temperature increase, and a temperature increase exceeding 100 degrees C. with respect to the LED chip temperature can occur generally under a relatively low input power. As a result, the temperature of the wavelength converter 4 reaches a temperature range well above 150 degrees C.

Hereinafter, for example, embodiments of the wavelength converter 4 that is used in a semiconductor light-emitting device of the present invention, phosphor 17 (particularly, inorganic phosphor) that is used for the wavelength converter 4, and the specific structure of the wavelength converter 4 will be described in detail.

For example, the arrangement of the wavelength converter 4 is described later in detail separately.

(Phosphor 17 Used for Wavelength Converter 4)

As described above, the phosphor 17 that is used for the wavelength converter 4 is preferably an inorganic phosphor. Hereinafter, the inorganic phosphor is described in detail.

The inorganic phosphor to be used can be selected suitably from, for example, an inorganic phosphor that emits luminescence obtained due to interband energy transition in semiconductor, an inorganic phosphor that emits luminescence obtained due to impurity ions that form a donor or an acceptor in the semiconductor, and an inorganic phosphor (an inorganic phosphor that emits luminescence obtained due to electronic transition of transition metal ions or rare-earth ions) that emits luminescence due to the localized center.

A preferable inorganic phosphor is an inorganic phosphor that is activated with a rare-earth ion (such as Ce³⁺, Pr³⁺, Nd³⁺, Sm³⁺, Eu³⁺, Eu²⁺, Tb³⁺, Dy³⁺, Ho³⁺, Er³⁺, Tm³⁺, Yb³⁺, or Yb²⁺) or a transition metal ion (such as Mn²⁺, Mn⁴⁺, Sb³⁺, Sn²⁺, Ti⁴⁺, Tl⁺, Pb²⁺, Cu⁺, Cr³⁺, or Fe³⁺) as the luminescence center. Among them, many of the inorganic phosphors, each of which is activated with at least one metal ion selected from Ce³⁺, Pr³⁺, Eu³⁺, Eu²⁺, Tb³⁺, Yb²⁺, and Mn²⁺, are particularly preferable since they exhibit high photon conversion efficiency under photoexcitation in at least either a wavelength range of purple of at least 380 nm but shorter than 420 nm or a wavelength range of blue to blue-green of at least 420 nm but shorter than 510 nm.

Particularly, many of the inorganic phosphors, each of which contains at least one rare-earth ion selected from Ce³⁺ and Eu²⁺ as the luminescence center, are preferable since they exhibit high photon conversion efficiency under photoexcitation in a wavelength range of violet to blue-green of at least 380 nm but shorter than 510 nm, further in a wavelength range of violet to blue of at least 400 nm but shorter than 480 nm, and particularly in a wavelength range of blue of at least 430 nm but shorter than 475 nm.

The inorganic phosphor that is preferable for controlling temperature increase that is caused by energy loss accompanying wavelength conversion in the wavelength converter 4 is an inorganic phosphor that has high light absorptance with respect to the light emitted by the solid-state light-emitting element 3 and that has an internal quantum efficiency that is close to the theoretical limitation, that is, an inorganic phosphor that has high external quantum efficiency under photoexcitation in the emission peak wavelength of light emitted by the solid-state light-emitting element 3 and that has an absolute value of at least 80%.

Such an inorganic phosphor with high external quantum efficiency has high absorptance with respect to the primary light and converts the absorbed primary light into wavelength conversion light with a longer wavelength than that of the primary light with high photon conversion efficiency. Therefore, when the wavelength converter 4 is irradiated with the primary light, the rate of output of the wavelength conversion light that passes through the wavelength converter 4 in the direction of irradiation with the primary light increases. Accordingly, when light that contains the primary light as one of the output light components and is obtained by additive color mixing of the primary light and the wavelength conversion light, particularly, white light is to be obtained, the wavelength converter 4 can be thin. As a result, the wavelength converter 4 has good thermal conductivity in the thickness direction and excellent heat dissipation properties and therefore is preferable for controlling the temperature increase.

The aspect of the inorganic phosphor is not particularly limited and the inorganic phosphor can be selected widely from, for example, powder, sintered compacts, ceramic compacts, and single crystals.

It is no problem that the inorganic phosphor is not one that is used from the viewpoint of making a design to control the temperature increase in the wavelength converter 4 but one that is used from the viewpoint of improving the heat resistance of the wavelength converter 4. That is, in the wavelength converter 4, all types of the inorganic phosphors that function as wavelength conversion materials may be phosphors with high heat resistance and less temperature quenching, in which under the temperature condition of the inorganic phosphor reaching 150 degrees C., the emission peak at the time of photoexcitation in the same wavelength as the peak wavelength of the primary light maintains at least 70% of that obtained at room temperature. In this case, an inorganic phosphor in which the luminous efficiency tends not to decrease under the high temperature condition is used as the wavelength conversion material. Accordingly, a wavelength converter 4 can be provided in which light output tends not to decrease even when the temperature increases. Thus, it is possible to provide a semiconductor light-emitting device in which light output tends not to decrease even when the temperature increases.

Examples of such a highly efficient inorganic phosphor with high heat resistance include the following inorganic phosphors, and it is preferable that these are used as the wavelength conversion materials in the present invention.

(1) Ce³⁺-activated phosphor with a garnet crystal structure and with an emission peak wavelength in a range of at least 500 nm but shorter than 565 nm

(2) Nitride-based phosphor (for example, a nitride phosphor or an oxynitride phosphor) activated with at least one of Eu²⁺ and Ce³⁺

An inorganic phosphor that is preferable because it allows white light to be obtained relatively easily by being combined with a solid-state light-emitting element 3 that emits blue light is an yellow phosphor (a phosphor having an emission peak in the wavelength range of at least 550 nm but shorter than 600 nm) that has a complementary color relationship to blue.

For reference, the following are specific examples of the highly efficient inorganic phosphor with high heat resistance that can be excited by light of purple (at least 380 nm but shorter than 420 nm) or blue (at least 420 nm but shorter than 500 nm).

(1) Y₃Al₅O₁₂:Ce³⁺-based yellow-green phosphor (particularly, with an emission peak wavelength of at least 525 nm but shorter than 560 nm, or low concentration Ce³⁺-activated phosphor in which the amount of Ce³⁺ ions that replace a part of the rare-earth ions (for instance, Y³⁺ or Gd³⁺) of the phosphor matrix is 0.001 atom % to 2 atom %)

(2) BaY₂SiAl₄O₁₂:Ce³⁺-based green phosphor

(3) Ca₃Sc₂Si₃O₁₂:Ce³⁺-based green phosphor (including a phosphor in which a part of Ca or Sc has been replaced by Mg)

(4) MSi₂O₂N₂:Eu²⁺-based green/yellow phosphor (M denotes alkaline earth metal)

(5) M₃Si₆O₁₂N₂:Eu²⁺-based green phosphor (M denotes alkaline earth metal in which the majority is Ba)

(6) beta-Si₃N₄:Eu²⁺-based green phosphor (including a phosphor in which a part of Si—N has been replaced by Al—O)

(7) Ca-alpha-SiAlON:Eu²⁺-based yellow phosphor

(8) MAlSiN₃:Eu²⁺-based red phosphor (M denotes an alkaline earth metal)

(9) M₂(Al,Si)₅(N,O)₈:Eu²⁺-based red phosphor (M includes alkaline earth metal and M₂ Si₅Nₛ:Eu²⁺ red phosphor)

(10) BaMgAl₁₀O₁₇:Eu²⁺-based blue phosphor

Among the above-mentioned specific phosphors (1) to (10), the Ce³⁺-activated phosphor is an inorganic phosphor that can be excited by blue light, Eu²⁺-activated phosphors except for the phosphor of the above-mentioned item (10) are inorganic phosphors that can be excited highly efficiently with both the purple light and blue light (the Eu²⁺-activated phosphor of the above-mentioned item (10) is an inorganic phosphor that is not excited by blue light but can be excited highly efficiently with purple light).

In the present invention, it is preferable that such a highly efficient inorganic phosphor with high heat resistance is used as the wavelength conversion material for the wavelength converter 4.

Each of the inorganic phosphors of the above-mentioned items (1) to (10) each has a short afterglow time (tau_{1/10}), specifically, 1 msec or shorter, because the luminescence is based on parity-allowed transition 4 fⁿ-4 fⁿ⁻¹5 d¹ (where n is 1 in the case of Ce³⁺ ions and n is 7 in the case of Eu²⁺ ions) of Ce³⁺ or Eu²⁺ ions. Therefore, the wavelength converter 4 (and a semiconductor light-emitting device configured using the wavelength converter 4) formed using only an inorganic phosphor containing either such rare-earth ions Ce³⁺ or Eu²⁺ as the luminescence center is preferable as one for an image display unit that displays moving images.

The Eu²⁺-activated phosphor has a narrower emission spectrum half width than that of the Ce³⁺-activated phosphor and emits red, green, and blue light that are excellent in color purity. Therefore, among the inorganic phosphors of the above-mentioned items (1) to (10), the inorganic phosphors (the inorganic phosphors of the above-mentioned items (4) to (6) and (8) to (10)), each of which is activated with Eu²⁺ ions and emits light to be three primary colors (red, green, and blue), are preferable inorganic phosphors, for example, for liquid crystal backlights.

For example, a semiconductor light-emitting device of the present invention that has a structure formed of a combination of the solid-state light-emitting element 3 that emits ultraviolet light or purple light, Eu²⁺-activated blue phosphor (the inorganic phosphor of the above-mentioned item (10)), Eu²⁺-activated green phosphor (the inorganic phosphors of the above-mentioned items (4) to (6)), and Eu²⁺-activated red phosphor (the inorganic phosphor of the above-mentioned item (8) or (9)), or a structure formed of a combination of the solid-state light-emitting element 3 that emits blue light, Eu²⁺-activated green phosphor (the inorganic phosphors of the above-mentioned items (4) to (6)), and Eu²⁺-activated red phosphor (the inorganic phosphor of the above-mentioned item (8) or (9)) is a semiconductor light-emitting device that is preferable as a light source for a liquid crystal backlight, and the use of such a semi-conductor light-emitting device makes it possible to provide a light source device that is suitable for a liquid crystal backlight.

(Specific Structural Example 1 of Wavelength Converter 4)

FIG. 23 shows a wavelength converter 4 with a structure in which powdery phosphor 17 (phosphor particles 17b) is dispersed in a translucent matrix 16.

The translucent matrix 16 is a translucent organic or inorganic material. Examples of the organic material include various translucent resins (for instance, silicone resin, fluorine resin, epoxy resin, and acrylic resin), and examples of the inorganic material include low-melting-point glass.

Powdery phosphor 17 is phosphor particles 17b with a particle size of at least 1 nm but smaller than 1 mm, and is any one of nanoparticles (at least 1 nm but smaller than 10 nm), ultrafine particles (at least 10 nm but smaller than 100 nm), small particles (at least 100 nm but smaller than 100 mum), and grains (at least 100 mum but smaller than 1 mm).

The particle size refers to the mean diameter or center particle diameter (D₅₀) that is described generally as a measurement result obtained by a predetermined measurement method in, for example, a product catalog of powder products. For convenience, it is indicated as mean diameter when the particle size is smaller than 100 nm, while it is indicated as center particle diameter when the particle size is 100 nm or larger.

The wavelength converter 4 with the structure shown in FIG. 23 is preferable in practical use, because it not only can be produced by a simple production method but also is well proven.

Furthermore, the wavelength converter 4 in which the translucent matrix 16 is an inorganic material with relatively high thermal conductivity is preferable in terms of heat dissipation properties and from the viewpoint of controlling the temperature increase in the wavelength converter 4.

In order to improve light transmission properties and thermal conductive properties of the wavelength converter 4, in the wavelength converter 4 with the structure shown in FIG. 23, further translucent powder (for example, alumina or silica (not shown)) may be contained in the translucent matrix 16.

(Specific Structural Example 2 of Wavelength Converter 4)

FIG. 24 shows a wavelength converter 4 with a structure in which the phosphor 17 is a forming body (hereinafter described as a “phosphor forming body 17a”).

Examples of the phosphor forming body 17a include molded bodies that are known as sintered compact of phosphor powder, translucent phosphor ceramic, phosphor glass, and phosphor single crystal. However, in the present invention, a composite forming body formed of a ceramic material and a phosphor such as the MGC optical conversion member also is included as an example of the phosphor forming body 17a.

The wavelength converter 4 with the structure shown in FIG. 24 makes it possible to provide a wavelength converter that has high thermal conductivity and that is made only of inorganic, and therefore is preferable in terms of heat dissipation properties and from the viewpoint of controlling the temperature increase in the wavelength converter 4.

The phosphor forming body 17a that is preferable in terms of, for example, handling, is a phosphor forming body with a minimum thickness of at least 0.1 mm but less than 1 cm. Such a phosphor forming body 17a is excellent in mechanical strength.

(Specific Structural Example 3 of Wavelength Converter 4)

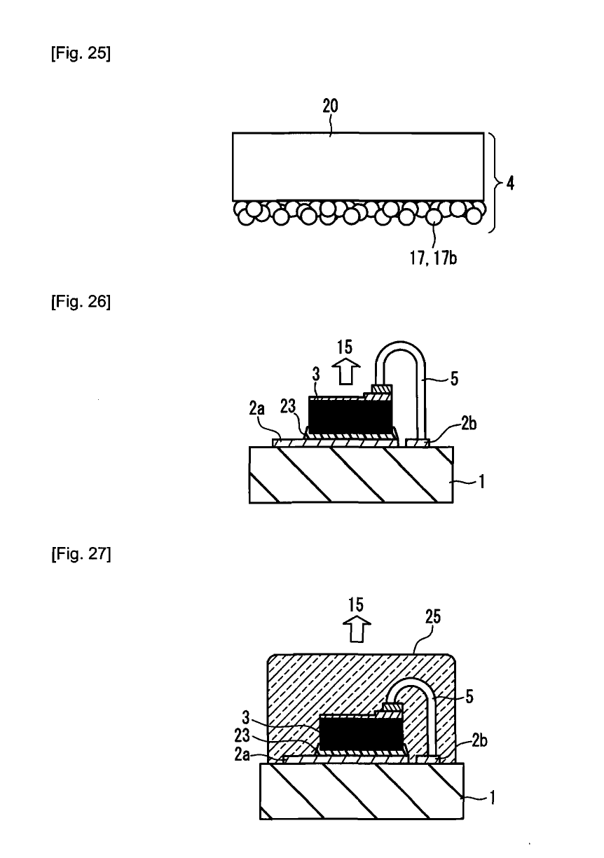

As shown in FIG. 25, the wavelength converter 4 also can have a structure in which phosphor particles 17b are allowed to adhere to at least one surface of the translucent adherend base 20 (for instance, glass, translucent ceramic, or acryl).

For example, many structures (glass with a phosphor film) in each of which phosphor particles 17b are allowed to adhere to glass in the form of a film have been employed in, for example, phosphorescent lamps, cathode-ray tubes (CRTs), and plasma display panels and are preferable from the practically proven point of view.

Furthermore, the portion where heat is generated due to wavelength conversion is limited to a part of the phosphor film of the wavelength converter 4, and the translucent adherend base 20 functions as a good heat dissipator when the translucent adherend base 20 is glass. Thus, a wavelength converter 4 that is excellent in controlling the temperature increase therein is obtained.

For example, as described in books such as “Handbook of Phosphors” (edited by Phosphor Research Society, Ohm Co., Ltd.), it is well known that such a wavelength converter 4 can be formed using various methods such as a printing method, a precipitation method, and a suspension method.

Such a wavelength converter 4 can be produced by, for example, applying a phosphor suspension onto at least an inner wall of a glass bulb and a glass plate, drying it to remove the organic solvent component, and then baking the phosphor film (for instance, heating at a temperature of around 400 to 600 degrees C. in the air). The phosphor suspension is prepared by mixing, for example, an organic solvent (for instance, butyl acetate), resin (for instance, nitrocellulose (abbreviation: NC) that functions as a viscosity agent or ethylcellulose (abbreviation: EC)), a low-melting-point inorganic material (for instance, low-melting-point glass containing Ca—Ba—B—P—O as constituent elements (abbreviation: CBBP)) that functions as a binding agent, and an inorganic phosphor (for instance, a Y₃Al₅O₁₂:Ce³⁺-based phosphor or a Eu²⁺-activated alkaline earth metal orthosilicate phosphor).

### Embodiment 1

Hereinafter, Embodiment 1 of the semiconductor light-emitting device of the present invention is described with reference to drawings.

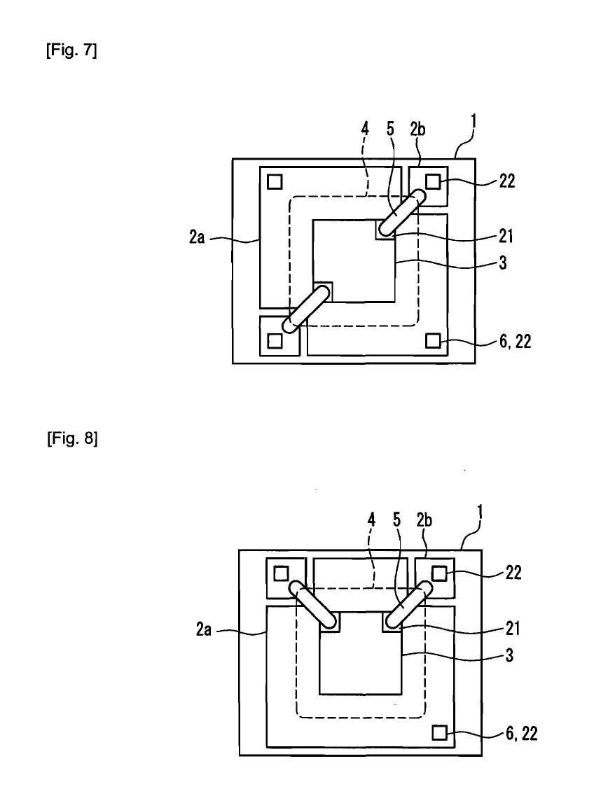

FIGS. 1 to 8 show top views showing semiconductor light-emitting devices according to Embodiment 1 of the present invention. The cross section taken on line I—I′ shown in FIG. 1 will be described later from Embodiment 3 onwards.

(Pattern Forms of Conductor a 2a, Conductor B 2B, and Conductors X)

As shown in FIGS. 1 to 8, Embodiment 1 of the semiconductor light-emitting device according to the present invention includes at least one conductor A 2a, a conductor B 2b, and a solid-state light-emitting element 3 on one side of an insulating heat dissipating substrate 1, and the solid-state light-emitting element 3 is mounted on the conductor A 2a but is not mounted on the conductor B 2b. Embodiment 1 is characterized as follows. The solid-state light-emitting element 3 has a pair of a power supply electrode A 14a and a power supply electrode B 14b (see FIGS. 17 to 21) either on the upper surface or on the upper and lower surfaces thereof. Furthermore, it is mounted in such a manner that the whole lower surface to be a surface opposing to the main light extraction surface adheres to the conductor A 2a. When the mounting surface of the solid-state light-emitting element 3 is viewed from above, the conductor A 2a has an element mounting area on which the whole lower surface of the solid-state light-emitting element 3 is mounted, and a plurality of outflow-adhesive capturing areas that are provided adjacent to the periphery of the element mounting area without directional bias with respect to the periphery of the element mounting area. The conductor B 2b is disposed in a portion adjacent to the periphery of the element mounting area other than the outflow-adhesive capturing areas while being electrically separated from the conductor A 2a. The phrase “the outflow-adhesive capturing areas” described above denotes the areas on the conductor A 2a, on which the adhesive that has run over to the area other than the element mounting area can flow when the LED chip is mounted on the conductor A 2a.

According to Embodiment 1 of the semiconductor light-emitting device, the conductor A 2a has a shape in which the outflow-adhesive capturing areas are provided without directional bias in the periphery of the element mounting area on which the whole lower surface of the solid-state light-emitting element 3 is mounted. In a preferred embodiment, the conductor A 2a has a shape with at least two edge portions located in places that are relatively distant from each other in opposing directions with respect to the mounting center and that are distant from the mounting surface. Accordingly, the conductor A can control mounting defects/mounting failures as well as displacement of the center of gravity of the adhesive (solder material) placed in a position to serve as the mounting center of the solid-state light-emitting element 3. In this manner, the conductor A 2a of the semiconductor light-emitting device according to Embodiment 1 controls the aforementioned mounting misalignment of the solid-state light-emitting element 3 and the aforementioned local heating, and can promote increases in reliability and in output power of primary light to increase the output power of the semiconductor light-emitting device.

Furthermore, the conductor A 2a with the aforementioned shape also functions as a good balanced heat dissipator and light reflector. Accordingly, it is possible to obtain a semiconductor light-emitting device having a configuration that provides a higher heat dissipation effect and light extraction effect.

In the above-mentioned preferred embodiment, apparently the conductor A 2a has a recess in a part of the outer periphery thereof and has a shape including at least a shape extending in the opposing directions while diverging from the mounting surface, with the mounting center of the solid-state light-emitting element 3 being taken as the reference point, and the conductor B 2b has a structure in which it is disposed so that a part or the whole thereof fits into the recess of the conductor A 2a.

Embodiment 1 of the semiconductor light-emitting device further includes a wavelength converter 4 on the main light extraction surface of the solid-state light-emitting element 3, and it is preferable that the wavelength converter 4 emit light with a longer wavelength than that of primary light 15 emitted by the solid-state light-emitting element 3, through excitation by the primary light 15.

Furthermore, as shown in FIGS. 1 to 5, it is preferable that the conductor B 2b is disposed in such a manner as to have the outer frame center in a position to avoid the centerlines of the vertical and horizontal directions of the solid-state light-emitting element 3, and it is preferable that the conductor A 2a have a shape with rotational symmetry. According to this, the conductor B 2b is disposed in a place near the power supply electrode (generally, disposed in a position to avoid the centerlines of the vertical and horizontal directions of the solid-state light-emitting element 3) of the solid-state light-emitting element 3, and thereby an alignment configuration can be obtained in which the space above the heat dissipating substrate 1 is used effectively to adapt to the structure and operating principle of the solid-state light-emitting element 3. Thus the size of the semiconductor light-emitting device can be reduced.

The semiconductor light-emitting devices shown in FIGS. 1, 2, and 5 to 8 are examples, in each of which the solid-state light-emitting element 3 has a structure including a pair of the power supply electrode A 14a and the power supply electrode B 14b on the upper and lower surfaces. FIGS. 3 and 4 are examples, in each of which the solid-state light-emitting element 3 has a structure including a pair of the power supply electrode A 14a and the power supply electrode B 14b on the upper surface.

Furthermore, the semiconductor light-emitting devices shown in FIGS. 1 to 5 are examples in which the respective solid-state light-emitting elements 3 have the following structures: a structure with the power supply electrodes A 14a that are provided in diagonally opposed positions, respectively, on the upper surface of the rectangular parallelepiped shape; a structure with power supply electrodes A 14a that are provided in the positions of adjacent corners, respectively, on the upper surface of the rectangular parallelepiped shape; a structure with a pair of the power supply electrode A 14a and the power supply electrode B 14b that are provided in diagonally opposed positions on the upper surface of the rectangular parallelepiped shape; a structure with two pairs of the power supply electrode A 14a and the power supply electrode B 14b that are provided in the positions of adjacent corners on the upper surface of the rectangular parallelepiped shape; and a structure with two pairs of structures, each of which has two power supply electrodes A 14a that are provided in the positions of adjacent corners on the upper surface of the rectangular parallelepiped shape, are provided in diagonally opposed positions on the upper surface of the rectangular parallelepiped shape.

The semiconductor light-emitting devices shown in FIGS. 6 to 8 are examples in which the respective solid-state light-emitting elements 3 have the following structures: a structure with one power supply electrode A 14a that is provided at one corner on the upper surface of the rectangular parallelepiped shape; a structure with the power supply electrodes A 14a that are provided in diagonally opposed positions, respectively, on the upper surface of the rectangular parallelepiped shape; and a structure with the power supply electrodes A 14a that are provided in the positions of adjacent corners, respectively, on the upper surface of the rectangular parallelepiped shape. With each of such structures, heat generated by the solid-state light-emitting element 3 that increases with an increase in input power is conducted uniformly at a high speed to the high thermal conductors (for example, the conductor A 2a, heat dissipating substrate 1, and external heat dissipator (not shown)) disposed below the solid-state light-emitting element 3 through heat conduction performed using the whole lower surface of the solid-state light-emitting element 3 that serves as a mounting surface. Therefore the temperature increase in the solid-state light-emitting element 3 can be controlled. At the same time, the heat also tends to be conducted to be diffused in the horizontal direction of the mounting surface that diverges from the lower surface of the solid-state light-emitting element 3, through the conductor A 2a (that is formed so as to have an edge along the whole outer periphery of the lower surface of the solid-state light-emitting element 3) that has good thermal conductive properties and that is composed mainly of metal. In addition, a symmetrical structure is obtained in which the path lengths of heat conduction in the 360 degrees horizontal directions of the lower surface of the solid-state light-emitting element 3 that becomes a heat source on the mounting surface are relatively balanced, and thereby heat tends to be diffused relatively uniformly. Accordingly, local heating in the solid-state light-emitting element 3 can be controlled although it is achieved indirectly. In this manner, the heat dissipation efficiency is intended to be increased by fully utilizing the good thermal conductive properties and the relatively large area of the portion of the conductor A 2a that is not located under the lower surface of the solid-state light-emitting element 3, and thereby a decrease in the luminous efficiency of the solid-state light-emitting element 3 due to the temperature increase and uneven heat dissipation (uneven temperature distribution) in the solid-state light-emitting element 3 is controlled, which allows the output power of the semiconductor light-emitting device to be increased.

Furthermore, while the heat dissipation paths of the heat that is conducted through the conductor A 2a in the horizontal directions of the mounting surface are obtained using the shape with no line symmetry of the conductor A 2a, the area ratio of the lower surface of the solid-state light-emitting element 3 in the central part (the central center-of-gravity part in the case of a homogeneous material) of the conductor A 2a can be increased. This makes it possible to achieve a reduction in size and an increase in output power of the semiconductor light-emitting device.

In the case where the conductor A 2a has line symmetry, when the heat dissipation paths of the heat that is conducted through the conductor A 2a in the horizontal directions of the mounting surface are intended to be obtained, the area ratio of the lower surface of the solid-state light-emitting element 3 in the central part of the conductor A 2a decreases inevitably, and therefore it is difficult to achieve higher-density mounting. However, as described in Embodiment 2, the conductor A 2a made to have such a shape allows a plurality of solid-state light-emitting elements to be disposed in close proximity, so that it is possible to mount the plurality of solid-state light-emitting elements with high density.

The phrase “has a shape substantially with rotational symmetry but no line symmetry” denotes that “has the shape concerned including the shape that can be distinguished clearly to be “a shape that cannot be considered to be the shape with rotational symmetry and line symmetry” through deletion of a part of “a shape with rotational symmetry and line symmetry” or addition of a shape to a part of “the shape with rotational symmetry and line symmetry”.

Preferably, the conductor A 2a has a larger area of the upper surface thereof as compared to the conductor B 2b. Accordingly, the relative area ratio of the conductor A 2a (a conductor on which the solid-state light-emitting element 3 is mounted) in the conductors X increases, and thereby a small-sized semiconductor light-emitting device with the solid-state light-emitting element 3 having excellent heat dissipation efficiency can be provided.

Preferably, the conductor A 2a has a shape based on the same shape as that of the lower surface of the solid-state light-emitting element 3. This allows heat that is conducted through the conductor A 2a in the horizontal directions of the mounting surface of the solid-state light-emitting element 3 to be diffused further uniformly. This results in less variation in temperature distribution in the solid-state light-emitting element 3 and therefore the output power can be increased.

The phrase “a shape based on the same shape as that of the lower surface of the solid-state light-emitting element 3” described above denotes the shape of the conductor A 2a in which, as shown in FIGS. 1 to 8 as examples, with the center of the lower surface of the solid-state light-emitting element 3 being taken as the reference point, when the shape of the lower surface is increased gradually at a constant enlargement ratio, a part or the whole of at least two sides of the shape of the lower surface (in the case where the shape of the lower surface is polygon) or at least two points of the shape of the lower surface (including the case where the shape of the lower surface has a curve (circle or elliptical shape)) are in contact with the outer frame of the conductor A 2a simultaneously with symmetry with respect to the center of the lower surface.

In the semiconductor light-emitting device of the present invention, it also is possible that the number of the conductors A 2a is less than that of the conductors B 2b as shown in, for example, FIGS. 1, 4, 5, 7, and 8.

Generally, since the solid-state light-emitting element 3 has a structure that allows it to be driven when electric power is supplied to a pair of power supply electrodes, at least one conductor B 2b remains extra and can be used as an auxiliary electrode. Consequently, it becomes possible to form a wiring pattern that allows the power supply terminal 22 to be switched.

The specific examples thereof are indicated in FIGS. 9 to 11 and will be described later.

Preferably, the conductors X that denote all the conductors A 2a and the conductors B 2b are provided on one flat surface of the heat dissipating substrate 1 as shown in FIGS. 1, 4, 5, and 7, and have a pattern substantially with rotational symmetry on one flat surface of the heat dissipating substrate 1. This simplifies the pattern shape of the conductors X, and thereby, for example, a reduction in production variations, an improvement in reliability, and a reduction in production cost can be achieved with respect to the heat dissipating substrate 1 with a wiring pattern.

Furthermore, not only the circuit design is facilitated but also a plurality of systems of electrical circuits with symmetry can be configured using an extra conductor B 2b (see FIGS. 9 to 11 to be described later).

Moreover, in the heat dissipating substrate 1, as shown in FIGS. 1, 4, 5, and 7, it is preferable that at least the axis of rotational symmetry of the conductor A 2a coincide with the center point of the heat dissipating substrate 1 (the center of gravity in the case of the homogeneous material), and it is more preferable that the axis of rotational symmetry of the conductors X having a pattern with rotational symmetry coincide with the center point of the heat dissipating substrate 1. In this case, it is no longer necessary to be concerned about the left, right, top, and bottom of the heat dissipating substrate 1. Accordingly, not only can human errors in the production process be reduced and thereby yield can be increased, but also the process can be simplified.

Preferably, the conductors X have an area ratio of at least 50% but less than 100% on the heat dissipating substrate 1. In this case, it is preferable that the conductors A 2a have a total area ratio of at least 50% of the conductors X. Furthermore, in this case, it is preferable that the heat dissipating substrate 1 have a shape with inversion symmetry, and the solid-state light-emitting element 3 have a mounting surface on the line of symmetry of the heat dissipating substrate 1. This increases the area ratios of the conductors A 2a on which the solid-state light-emitting element 3 is mounted and the conductors X, on the heat dissipating substrate 1. Accordingly, the heat dissipation properties of the conductors that commonly have high thermal conductivities can be utilized effectively, and therefore it is possible to control the temperature increase in the solid-state light-emitting element 3 to increase the output power of the semi-conductor light-emitting device.

Furthermore, the minimum required conductors X have a high area ratio on the heat dissipating substrate 1 and can have an alignment configuration in which the space above the heat dissipating substrate 1 is used effectively to further adapt to the structure and operating principle of the solid-state light-emitting element 3. Thus, the size of the semiconductor light-emitting device further can be reduced.

Furthermore, since the conductor A 2a accounts for a majority of the total area of the conductors X, the conductor A 2a that also functions as a heat dissipator of the solid-state light-emitting element 3 accounts for a high area ratio on the heat dissipating substrate 1. As a result, a semiconductor light-emitting device can be obtained that has a configuration in which the solid-state light-emitting element 3 has a high heat dissipation effect.

Moreover, the solid-state light-emitting element 3 is allowed to be located on the line of symmetry of the heat dissipating substrate 1, so that a good appearance also can be obtained.

These synergistic effects make it possible to obtain a small-sized, high-power semi-conductor light-emitting device with high production speed and high reliability.

Furthermore, generally, since the above-mentioned area ratio of the conductors A 2a with metallic luster or conductors X also increases, even in the case of using the heat dissipating substrate 1 with a relatively high light absorptance, the rate of loss of light absorbed by the heat dissipating substrate 1 is decreased, and thereby the light extraction efficiency is increased. As a result, the range of options of the heat dissipating substrate 1 is expanded, and it also becomes possible to employ a heat dissipating substrate 1 with higher thermal conductivity and good heat dissipation properties. Accordingly, it is possible to control the temperature increase in the solid-state light-emitting element 3 to increase the output power of the semiconductor light-emitting device.

From the viewpoint of improving the light extraction efficiency, it is preferable that the total area of the upper surface of the conductors A 2a located directly under the light output surface in the semiconductor light-emitting device account for at least 50% of the area of the light output surface, preferably at least 70%, and more preferably at least 90%. In this case, the above-mentioned area ratio of the conductors A 2a with metallic luster or conductors X located directly under the light output surface also increases. Accordingly, good light extraction efficiency is obtained and the output power of the semiconductor light-emitting device can be increased.

Moreover, in order to prevent light emitted by the solid-state light-emitting element 3 or the wavelength converter 4 from being absorbed by the heat dissipating substrate 1 and to allow the light to be reflected to improve the light extraction efficiency, it is preferable that an electrically insulating reflector with a visible light (with a wavelength range of 380 to 780 nm) reflectance of at least 50% and preferably at least 80% is provided at least in a portion with no conductors (the conductor A 2a and the conductor B 2b) formed on the heat dissipating substrate 1.

The insulating reflector may be provided to cover the conductor A 2a and the conductor B 2b.

For example, alumina (Al₂O₃), titania (TiO₂), or barium sulfate (BaSO₄) can be used for the electrically insulating reflector, and, for instance, a thick film formed of powder thereof can be used that has a thickness of about at least 5 mum but less than 1 mm.

The above-mentioned thick film can be formed by, for example, a common screen printing technique.

(Upper surface shape of solid-state light-emitting element 3, electrode lead-out part 21, and conductor C 5)

As shown in FIGS. 1 to 8 as examples, in the semiconductor light-emitting device of the present invention, the shape of the upper surface of the solid-state light-emitting element 3 located on the main light extraction surface side is polygon, preferably a quadrangle that is easy to produce, and more preferably a rectangular parallelepiped shape including a square, and it is preferable that the electrode lead-out part 21 of the solid-state light-emitting element 3 is provided at least at one corner of the upper surface of the solid-state light-emitting element 3. In this case, variations in luminescence intensity become less prominent since the portion with low luminescence intensity that is created by being shielded by the conductor C 5 (for instance, wire) that electrically connects the conductor B 2b and the electrode lead-out part 21 to each other is located at the corner of the solid-state light-emitting element 3.

Furthermore, as shown in FIGS. 1, 2, 5, 7, and 8 as examples, when using a solid-state light-emitting element 3 with a structure having a pair of the power supply electrode A 14a and the power supply electrode B 14b on the upper and lower surfaces, it also is preferable that even numbers of electrode lead-out parts 21 be provided.

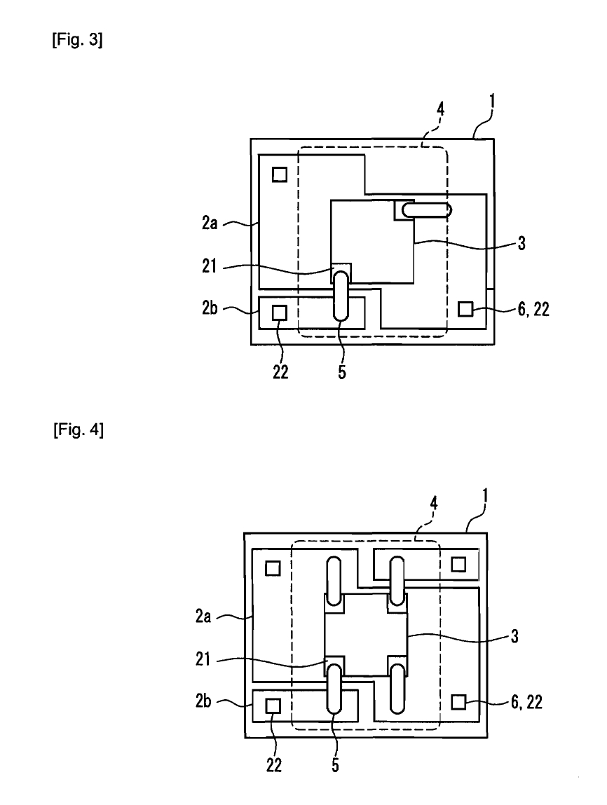

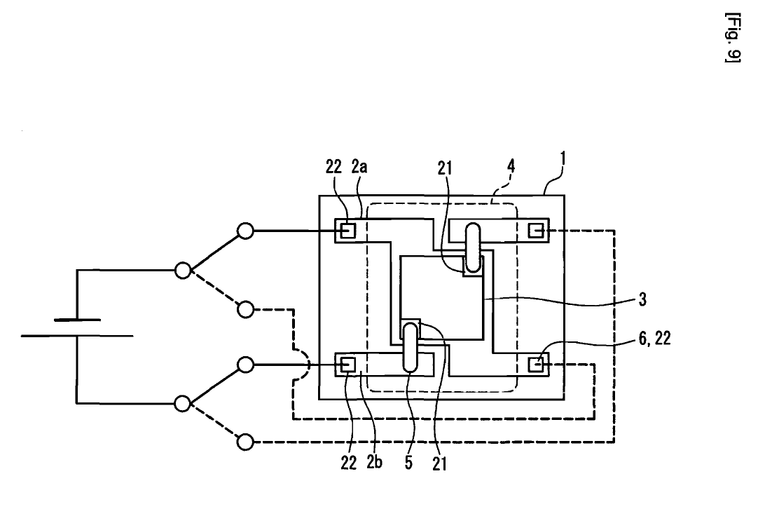

As shown in FIGS. 1, 5, and 7 as examples, the electrode lead-out parts 21 can be provided in diagonally opposed positions on the upper surface of the solid-state light-emitting element 3, or they also can be provided in the positions of adjacent corners on the upper surface of the solid-state light-emitting element 3 as shown in FIGS. 2 and 8 as examples. In this case, a plurality of electrode lead-out parts 21 can be provided and the number of the joint portions between the electrode lead-out parts 21 and the conductors C 5 can be increased. Accordingly, relatively high reliability in terms of electrical connection can be obtained.

Moreover, it also is possible to provide a plurality of conductors C 5 that are connected at least to the conductors B 2b. An increase in the number of the conductors C 5 also makes it possible to reduce the total resistance of the conductors C 5. Therefore, the amount of Joule heat generated in the conductors C 5 can be reduced, so that the temperature increase in the solid-state light-emitting element 3 can be controlled.

In the case of configurations shown in FIGS. 1, 5, and 7 as examples in which the electrode lead-out parts 21 are provided in the diagonally opposed positions on the upper surface of the solid-state light-emitting element 3, it becomes possible relatively easily to provide a semiconductor light-emitting device with a wiring pattern that allows the power supply terminals 22 to be switched as shown in FIG. 9 as an example. Accordingly, a light source device can be provided that can be restored easily without requiring replacement of the light source even when the semiconductor light-emitting device suffers from disconnection and stops lighting up.

On the other hand, similarly in the case of using the solid-state light-emitting element 3 with a structure having a pair of the power supply electrode A 14a and the power supply electrode B 14b on the upper surface, it is preferable that even numbers of the electrode lead-out parts 21 are provided as shown in FIG. 4 for the same reason. This makes it possible to increase the number of the conductors C 5.

Moreover, as shown in FIG. 4, a configuration is employed in which two pairs of a pair of the power supply electrode A 14a and the power supply electrode B 14b are provided in the positions of adjacent corners on the upper surface of the rectangular parallelepiped shape, and one of the power supply electrode A 14a and the power supply electrode B 14b and the other are electrically connected to the conductor A 2a and the conductor B 2b, respectively, so that as shown in FIG. 9 as an example, it also becomes possible to provide a semiconductor light-emitting device with a wiring pattern that allows the power supply terminals 22 to be switched.

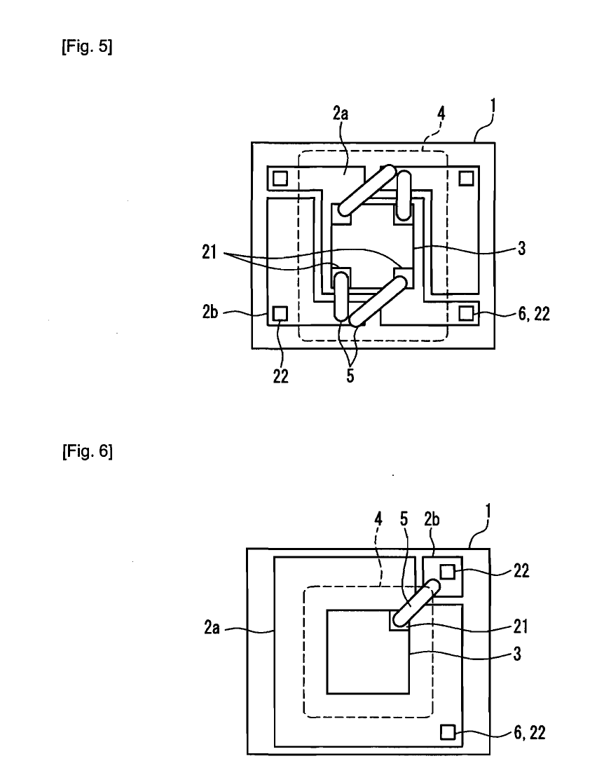

The semiconductor light-emitting device shown in FIG. 5 is configured to have both the characteristics (good points) of the semiconductor light-emitting devices shown in FIGS. 1 and 2. The electrode lead-out parts 21 are provided at four corners on the upper surface of the solid-state light-emitting element 3, and two electrode lead-out parts 21 provided at adjacent corners on the upper surface of the solid-state light-emitting element 3 and one conductor B 2b are electrically connected to each other using two conductors C 5. Thus, two means of supplying electric power (that is, means of supplying electric power to the solid-state light-emitting element 3) between the conductor A 2a and the conductor B 2b are provided. In this case, similar relatively high reliability to that of the semiconductor light-emitting device shown in FIG. 2 can be obtained, and it is possible to provide a semiconductor light-emitting device with a wiring pattern that allows the power supply terminals 22 to be switched in the same manner as in the case of the semiconductor light-emitting device shown in FIG. 1.

In FIGS. 1 to 8, the conductors C 5 are preferably metal. In this case, the conductors C 5 have increased thermal conductivity and thereby the conductors C 5 can be obtained that also serve as heat dissipating members.

In the semiconductor light-emitting device of the present invention, as shown in FIGS. 1 to 8, it is preferable that the solid-state light-emitting element 3 be mounted in a position to be a central part of the outer frame of the conductor A 2a, and the conductor A 2a have a shape based on the same shape as that of the lower surface of the solid-state light-emitting element 3 and be formed to have an edge along the whole outer periphery of the lower surface of the solid-state light-emitting element 3. Furthermore, it is preferable that the lower surface of the solid-state light-emitting element 3, the upper surface of the conductor A 2a, and the upper surface of the heat dissipating substrate 1 are arranged to coincide by the respective centers thereof. In this case, a configuration is obtained in which the area of the lower surface of the solid-state light-emitting element 3 that becomes a heat source is smaller than those of the upper surfaces of the conductor A 2a and the heat dissipating substrate 1 and the lower surface of the solid-state light-emitting element 3 is located within the outer frame of the conductor A 2a. Accordingly, the conductor A 2a and the heat dissipating substrate 1 function as good heat dissipators for the solid-state light-emitting element 3 that is a heat source, and therefore the temperature increase in the solid-state light-emitting element 3 is controlled. Furthermore, the conductor A 2a can tolerate a little the mounting misalignment of the solid-state light-emitting element 3. Thus, a semi-conductor light-emitting device can be obtained in which relatively high reliability can be obtained even when the production speed is increased.

Furthermore, it is preferable that all shapes of the lower surface of the solid-state light-emitting element 3, the upper surface of the conductor A 2a, and the upper surface of the heat dissipating substrate 1 are either those identical to one another or those based on the shapes identical to one another, and particularly either those of quadrangle (particularly, rectangular parallelepiped shapes including square) or those based on quadrangle. In this case, a configuration is obtained that has a heat dissipator in which the shape thereof is similar to the shape of the lower surface of the solid-state light-emitting element 3, and a configuration is obtained in which heat is dissipated in the horizontal directions relatively uniformly. Thus, it becomes possible to control local heating in the solid-state light-emitting element 3 and thereby to increase the output power of the semiconductor light-emitting device.

The aforementioned “shape based on quadrangle” denotes not only a simple quadrangle but also, for example, a shape having a projecting part in at least one side of a quadrangle (for example, the shape such as that of the conductor A2a shown in FIG. 1), a shape having a recessed part in at least one side of a quadrangle, a shape with at least one side of a quadrangle being wavy, or a shape with at least one corner of a quadrangle being rounded.

In the semiconductor light-emitting device of the present invention, when the shape of the upper surface of the solid-state light-emitting element 3 is a quadrangle, particularly a rectangular parallelepiped shape including square, it is preferable that the conductor C 5 is provided to be orthogonal to one side of the quadrangle to be the shape of the upper surface of the solid-state light-emitting element 3. In this case, the conductor C 5 can be shortened to the minimum required length and therefore the resistance of the conductor C 5 is reduced, which results in a reduction in heat generation.

In the case where the shape of the upper surface of the heat dissipating substrate 1 is a shape based on quadrangle, it is preferable that the conductor C 5 is provided in parallel with one side of the quadrangle on which the shape of the upper surface of the heat dissipating substrate 1 is based. This makes it possible to produce the semi-conductor light-emitting device by a simple mounting process and to reduce the production cost, which is accompanied by simplification of the process.

As shown in FIGS. 9 to 11 as specific examples, in the semiconductor light-emitting device of the present invention, the conductors B 2b and the electrode lead-out parts 21 of the solid-state light-emitting element 3 are electrically connected to each other with the conductors C 5, the conductors B 2b have a larger number of wiring structures than that of the conductor A 2a, and electric power is supplied to the solid-state light-emitting element 3 using a pair of the conductor A 2a and the conductor B 2b. Preferably, the semiconductor light-emitting device has a wiring structure that allows the same electric power to be supplied to the same solid-state light-emitting element 3 under the same conditions through switching of at least the conductors B 2b.

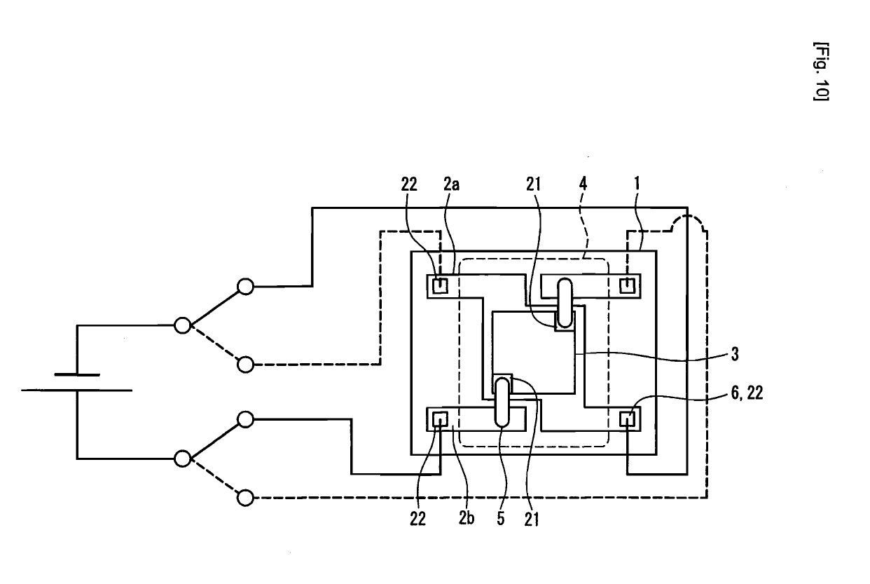

FIGS. 9 and 10 show specific examples, each of which has a configuration in which power supply terminals 22 of the conductors A 2a that are provided in plural per conductor A 2a also are switched. FIG. 11 shows a specific example with a configuration in which the power supply terminals 22 of the conductors A 2a are not switched but the conductors B 2b are switched.

As described above, the conductors X that are allowed to have wiring patterns with which the power supply terminals 22 can be switched make it possible to provide light source devices and lighting systems in each of which, for example, even when the semiconductor light-emitting device suffers from disconnection and stops lighting up in the dark, it can be restored by only a simple switching operation without replacing the light source and it can light up immediately under the same conditions.

Furthermore, the semiconductor light-emitting device can cope with the situation where partial disconnection has occurred due to problems during the process for producing it. Since it can be lit up using another electrical circuit system, it also becomes easy to improve the production yield.

Basically, the operational effects of the semiconductor light-emitting device according to the present invention with such a power supply configuration do not depend on, for example, the shapes of the conductors (the conductors A 2a and/or the conductors B 2b), arrangement of the conductors on the heat dissipating substrate 1, and the structure of the solid-state light-emitting element 3.

That is, the semiconductor light-emitting device according to the present invention with the above-mentioned power supply configuration includes the solid-state light-emitting element 3 that can be driven by supplying electric power through at least two power supply electrodes (the power supply electrode A 14a and the power supply electrode B 14b). The semiconductor light-emitting device is not particularly limited not only relative to shapes/arrangement of the wiring conductors and structures of the solid-state light-emitting element 3 but also, for example, configuration requirements of the semiconductor light-emitting device, as long as it is characterized by having a configuration in which a plurality of at least one-type power supply electrodes (either the power supply electrode A 14a or the power supply electrode B 14b) are provided, and having a wiring structure that allows the same electric power to be supplied to the same solid-state light-emitting element 3 under the same conditions through switching of the aforementioned plurality of one-type power supply electrodes.

The person skilled in the art can predict that, for example, even in the case of using the solid-state light-emitting element 3 with a flip-chip lower-surface two-electrode structure described with reference to FIG. 22, it is possible to provide, for example, a semiconductor light-emitting device that satisfies the same configuration requirements as those described above and that can provide the same operational effects.

Furthermore, it is apparent that the light source device or lighting system can be configured easily using a semiconductor light-emitting device of the present invention having a wiring structure that allows the same electric power to be supplied to the same solid-state light-emitting element 3 under the same conditions through switching of at least the conductors B 2b described above, and a circuit switching device 34 (see, for example, FIG. 37) for switching the power supply terminals 22 of the semi-conductor light-emitting device of the present invention.

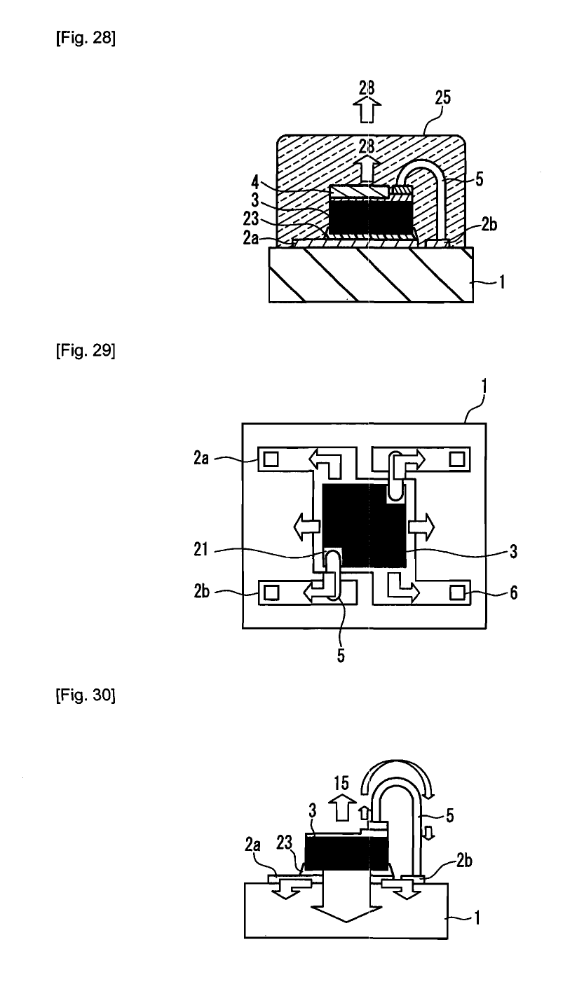

The same operational effects as those described in Embodiment 1 can be obtained in the same manner in a semiconductor light-emitting device that does not include the wavelength converter 4 on the main light extraction surface of the solid-state light-emitting element 3 and that emits, as output light 28 (see, for example, FIG. 28), the light component of the primary light 15 emitted by the solid-state light-emitting element 3 but does not emit, as output light 28, the light component of the wavelength conversion light obtained with the wavelength converter 4. Therefore, the semi-conductor light-emitting device of the present invention can be one without the wavelength converter 4 described above.

### Embodiment 2

The semiconductor light-emitting device of the present invention can include a plurality of at least conductors A 2a on one flat surface of the heat dissipating substrate 1 in the semiconductor light-emitting device of Embodiment 1. This makes it possible to include a plurality of solid-state light-emitting elements 3 and to increase the output power substantially in proportion to the number of the solid-state light-emitting elements 3.

Furthermore, as described above, a plurality of solid-state light-emitting elements 3 can be disposed in close proximity, by utilizing the shape with no line symmetry of the conductor A 2a, so that it becomes possible to mount a plurality of solid-state light-emitting elements 3 with high density.

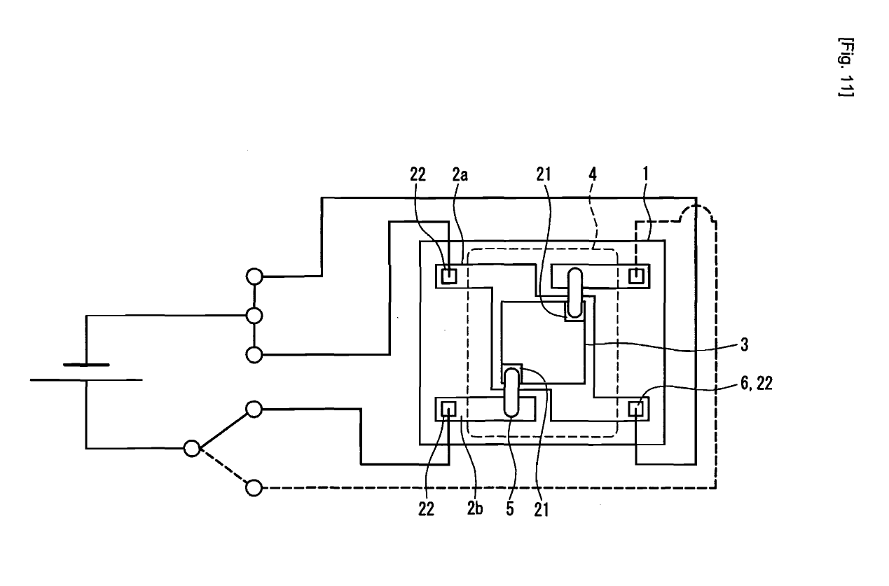

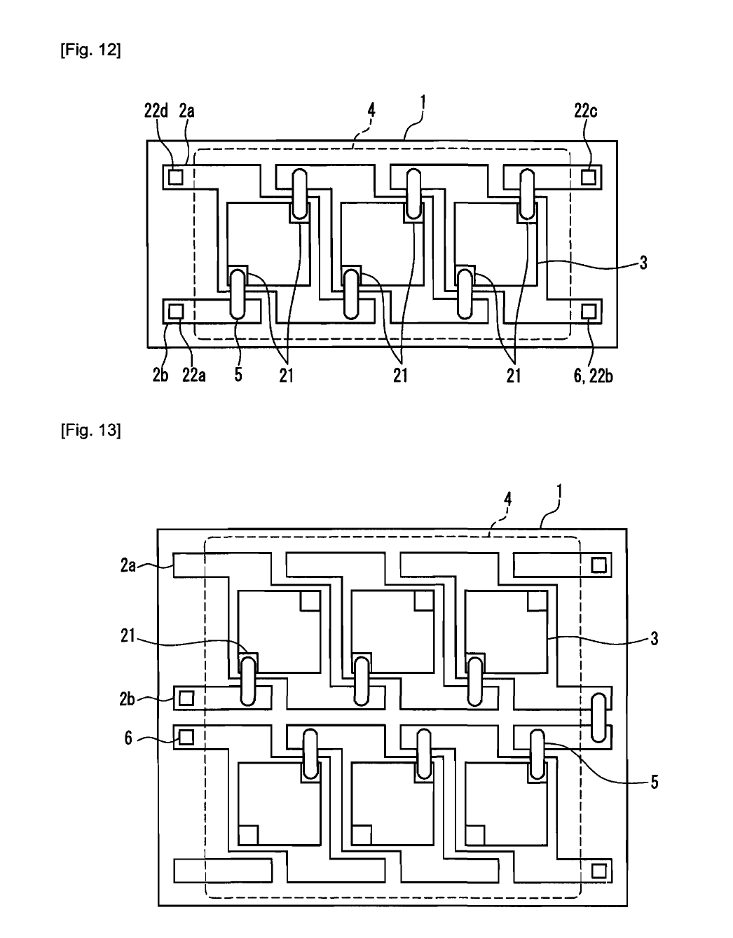

Examples thereof are shown in FIGS. 12 to 16. The details of the respective components and outline of the operational effects are as described above in Embodiment 1 and other sections and therefore the details thereof are not repeated here. Brief descriptions about the configuration are added as follows.

The semiconductor light-emitting device shown in FIG. 12 is a compact one with increased output power and a reduced size that was obtained by applying the technical ideas of the semiconductor light-emitting device described with reference to FIG. 1 and mounting and disposing three solid-state light-emitting elements 3 on one heat dissipating substrate 1 with high density.

As shown in FIG. 12, when the mounting surface of a solid-state light-emitting element 3 is viewed from above, the solid-state light-emitting element 3 is mounted so that the lower surface thereof is placed on the central part (the central center-of-gravity part in the case of a homogeneous material) of the outer frame of the conductor A 2a. The lower surface of the solid-state light-emitting element 3 is located inside the outer frame of the conductor A 2a, the areas of the respective upper surfaces of the solid-state light-emitting element 3, the conductor A 2a, and the heat dissipating substrate 1 decrease in the following order: solid-state light-emitting element 3, conductor A 2a, and heat dissipating substrate 1, and the conductor A 2a has a shape substantially with rotational symmetry but no line symmetry.

FIG. 12 shows the case where the solid-state light-emitting elements 3 are mounted in positions on which the central parts of the outer frames of the conductors A 2a fall, each of the conductors A 2a has a shape based on the same shape as that of the lower surface of the solid-state light-emitting element 3, and each of the solid-state light-emitting elements 3 is formed to have an edge along the whole outer periphery of the lower surface of the solid-state light-emitting element 3.

Moreover, each solid-state light-emitting element 3 is mounted in such a manner that the whole lower surface thereof to be a surface opposing to the main light extraction surface adheres to the conductor A 2a. When the mounting surfaces of the solid-state light-emitting elements 3 are viewed from above, the wavelength converter 4 has a configuration in which the upper surfaces of all the solid-state light-emitting elements 3 are located inside the outer frame of the wavelength converter 4, and the wavelength converter 4 is disposed above the light extraction surfaces of the solid-state light-emitting elements 3. In this case, almost all primary light (not shown) emitted by a plurality of solid-state light-emitting elements 3 enters the wavelength converter 4 to be converted into wavelength conversion light, which then is emitted. Accordingly, by effectively using photons emitted by the solid-state light-emitting elements 3, the output power of the semiconductor light-emitting device can be increased.

In order to simplify the production process, it is more preferable that one wavelength converter 4 is provided above all the plurality of solid-state light-emitting elements 3.

As shown in FIG. 12, with respect to three conductors A 2a, both an individual conductor A 2a and a collective of conductors A 2a have shapes having rotational symmetry but no line symmetry, and the three conductors A 2a are larger in the area of the upper surfaces than the conductors B 2b.

Each of the conductors A 2a has a shape based on the same shape (square) as that of the lower surface of each solid-state light-emitting element 3. A plurality of conductors B 2b are provided (two in FIG. 12), and one of them can be used as an auxiliary electrode. In this configuration, not only the conductors A 2a but also the conductors X are disposed on the heat dissipating substrate 1 with regularity and rotational symmetry. This makes it possible to mount the solid-state light-emitting elements 3 with higher density and to achieve a reduction in size and an increase in output power of the semiconductor light-emitting device.

In the semiconductor light-emitting device shown in FIG. 12, the conductors X have a wiring pattern that allows power supply terminals to be switched. That is, the semi-conductor light-emitting device shown in FIG. 12 can light up under the same conditions even when the power supply terminal A 22a and the power supply terminal B 22b are switched into the power supply terminal C 22c and the power supply terminal D 22d.

The total area of the upper surfaces of the conductors A 2a accounts for at least 30% of the area of one flat surface of the heat dissipating substrate 1 on which the solid-state light-emitting elements 3 are mounted. On the other hand, the total area of the upper surfaces of the conductors A 2a located directly below the light output surface in the semiconductor light-emitting device accounts for at least 50% (at least 80%) of the area of the aforementioned light output surface (denotes the area of the wavelength converter 4 in the top view shown in FIG. 12).

The shape of the upper surface of each solid-state light-emitting element 3 located on the main light extraction surface side is a quadrangle (square). The electrode lead-out parts 21 of the solid-state light-emitting element 3 are provided at corners on the upper surface of the solid-state light-emitting element 3.

Even numbers (two in this example) of electrode lead-out parts 21 are provided per solid-state light-emitting element 3 and are provided in diagonally opposed positions on the upper surface.

The conductors B 2b and the electrode lead-out parts 21 are electrically connected to each other with the conductors C 5. Preferably, the conductors C 5 are metal.

Furthermore, each of the shapes of the upper surfaces of the solid-state light-emitting elements 3, conductors A 2a, and heat dissipating substrate 1 is either quadrangle or a shape based on quadrangle, and the upper surfaces of all the solid-state light-emitting elements 3, conductors A 2a, and heat dissipating substrate 1 are arranged so that the centers thereof coincide with one another.

Each of the conductors A 2a is formed so as to have an edge along the whole outer periphery of the lower surface of the corresponding solid-state light-emitting element 3.

Moreover, each of the conductors C 5 is provided to be orthogonal to one side of the quadrangle to be the shape of the upper surface of the corresponding solid-state light-emitting element 3. Each of the conductors C 5 is provided in parallel with one side of the quadrangle to be a base of the shape of the upper surface of the heat dissipating substrate 1.

In this manner, the small-sized, high-power semiconductor light-emitting device is configured.

The semiconductor light-emitting device shown in FIG. 13 is a modified example of the semiconductor light-emitting device described with reference to FIG. 12. Two semiconductor light-emitting devices shown in FIG. 12 are disposed to be arranged in two rows on one heat dissipating substrate 1, and further these are electrically connected in series, so that six solid-state light-emitting elements 3 in total are driven.

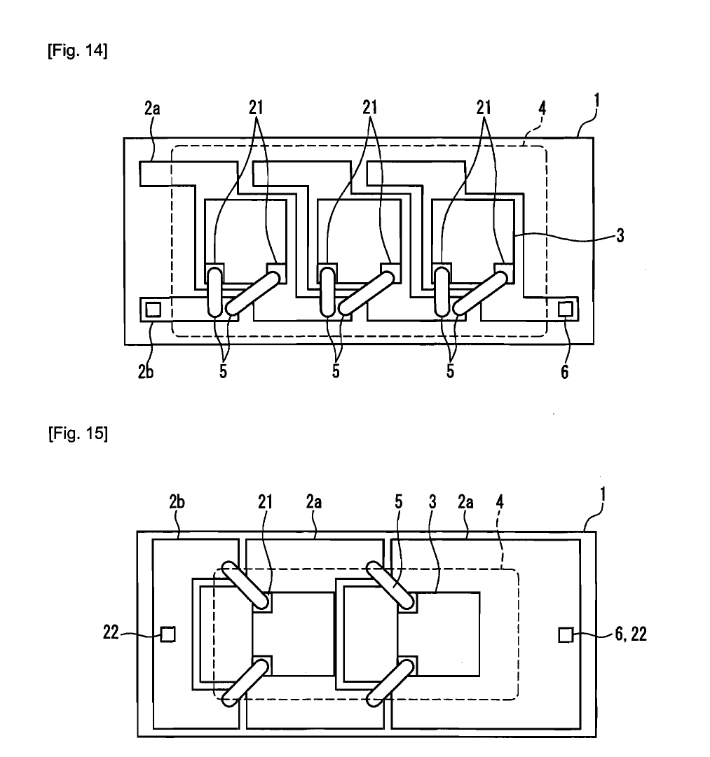

The semiconductor light-emitting device shown in FIG. 14 is a modified example of the semiconductor light-emitting device described with reference to FIG. 12. The number of components contained in the semiconductor light-emitting device shown in FIG. 12 is reduced and thereby the production cost is reduced. On the other hand, by using the semiconductor light-emitting device shown in FIG. 2, in one solid-state light-emitting element 3, two electrode lead-out parts 21 provided in the positions of adjacent corners on the upper surface and one conductor B 2b are electrically connected to each other using the conductors C 5, so that the generation of Joule heat in the conductors C 5 is reduced to control the temperature increase in the solid-state light-emitting element 3. Furthermore, the number of the joint portions between the electrode lead-out parts 21 and the conductors C 5 is doubled, so that high reliability in terms of electrical connection is obtained.

The semiconductor light-emitting devices shown in FIGS. 15 and 16 each are a modified example of the semiconductor light-emitting device described with reference to FIG. 12, wherein two solid-state light-emitting elements 3 are mounted to be disposed on one heat dissipating substrate 1 and thereby an increase in output power, a reduction in size, and miniaturization were achieved. Furthermore, with respect to the semiconductor light-emitting devices shown in FIGS. 15 and 16, in one solid-state light-emitting element 3, two electrode lead-out parts 21 provided in the positions of adjacent corners on the upper surface and one conductor B 2b are electrically connected using the conductors C 5, so that Joule heat in the conductors C 5 is reduced to control the temperature increase in the solid-state light-emitting element 3, and the number of the joint portions between the electrode lead-out parts 21 and the conductors C 5 is doubled, so that high reliability in terms of electrical connection is obtained.

FIGS. 15 and 16 each show, as an example of Embodiment 2, a configuration with line symmetry, with the centerline in the horizontal direction of the heat dissipating substrate 1 being taken as the axis of inversion symmetry.

The semiconductor light-emitting device shown in FIG. 15 is a semiconductor light-emitting device in which the conductors X account for an area ratio of at least 90% on the heat dissipating substrate 1, the numbers of the conductors A 2a and the conductor B 2b are two and one, respectively, and the conductor B 2b and conductor A 2a that are located left and right each are provided with one power supply terminal 22. This makes it possible to improve heat dissipation efficiency and light extraction efficiency of the conductors X (particularly, the conductor A 2a) and thereby the output power of the semiconductor light-emitting device can be increased.

On the other hand, the semiconductor light-emitting device shown in FIG. 16 is a semiconductor light-emitting device in which the numbers of the conductors A 2a and the conductors B 2b are two each, a pair of two conductors B 2b located on the left each are provided with one power supply terminal 22, one conductor A 2a located on the right is provided with two power supply terminals 22, and further the conductors C 5 are disposed to be orthogonal to both one side of the upper surface to be quadrangle of the solid-state light-emitting element 3 and one side of the heat dissipating substrate 1 to be quadrangle. This allows the conductors C 5 to be shortened to further reduce the resistance of the conductors C 5 and thereby not only the heat generation due to Joule heat in the conductors C 5 can be controlled but also mounting is facilitated.

It is obvious that in addition thereto, a number of modified examples are conceivable using the technical ideas of the present invention.

For the same reason as that described in Embodiment 1, basically, it is no problem even when the semiconductor light-emitting device of Embodiment 2 is not provided with the wavelength converter 4.

### Embodiment 3

Hereinafter, for example, the arrangement of the solid-state light-emitting elements 3 is described in further detail.

FIG. 26 shows a cross section (side face) taken on line I-I′ shown in FIG. 1 of the semiconductor light-emitting device according to Embodiment 1 shown in FIG. 1 as an example.

In FIG. 26, the wavelength converter 4 is not shown. The arrangement of the wavelength converter 4 will be described in Embodiment 4.

As shown in FIG. 26 as a specific example, the semiconductor light-emitting device of the present invention includes at least one conductor A 2a, a conductor B 2b, and a solid-state light-emitting element 3 on one side of an insulating heat dissipating substrate 1. The solid-state light-emitting element 3 is mounted on (fixed onto) the conductor A 2a but is not mounted on the conductor B 2b. The semiconductor light-emitting device is characterized as follows. The solid-state light-emitting element 3 has a pair of power supply electrodes either on the upper surface or on the upper and lower surfaces thereof (FIG. 26 shows, as an example, one having a pair of power supply electrodes on the upper and lower surfaces) and further is mounted (fixed) using, for example, an adhesive 23 (selectable from a widerange of materials such as a silver paste and a solder) in such a manner that the whole lower surface (a surface opposing the main light extraction surface) adheres to the conductor A 2a. When the mounting surface of the solid-state light-emitting element 3 is viewed from above, although it is difficult to see from the side view, the solid-state light-emitting element 3 is mounted in a position to be the central part of the outer frame of the conductor A 2a and the lower surface of the solid-state light-emitting element 3 is located inside the outer frame of the conductor A 2a. The areas of the respective upper surfaces of the solid-state light-emitting element 3, the conductor A 2a, and the heat dissipating substrate 1 increase in the following order: the solid-state light-emitting element 3, the conductor A 2a, and the heat dissipating substrate 1. The conductor A 2a has a shape substantially with rotational symmetry but no line symmetry.

According to the configuration of the above-mentioned semiconductor light-emitting device, heat generated in the solid-state light-emitting element 3 that increases with an increase in input power is conducted uniformly at a high speed to the high thermal conductors (for example, the conductor A 2a, heat dissipating substrate 1, and an external heat dissipator (not shown)) disposed below the solid-state light-emitting element 3 through heat conduction performed using the whole lower surface of the solid-state light-emitting element 3 that serves as a mounting surface. Therefore the temperature increase in the solid-state light-emitting element 3 can be controlled. At the same time, the heat also tends to be conducted and diffused in the horizontal direction of the mounting surface that diverges from the lower surface of the solid-state light-emitting element 3, through the conductor A 2a with good thermal conductivity that is composed mainly of metal or the heat dissipating substrate 1 that also serves as the conductor A 2a. Thus, the local heating in the solid-state light-emitting element 3 can be controlled. In this manner, good thermal conductive properties, relatively large surface areas, and enveloping volumes of the conductor A 2a and the heat dissipating substrate 1 are fully utilized to increase the heat dissipation efficiency in the directly downward direction, obliquely downward directions, and lateral directions of the solid-state light-emitting element 3. Thus, the decrease in luminous efficiency caused by the temperature increase and uneven heat dissipation in the solid-state light-emitting element 3 can be controlled.

The semiconductor light-emitting device of the present invention is configured to have the wavelength converter 4 (not shown in FIG. 26) above the main light extraction surface (not shown) of the solid-state light-emitting element 3. This wavelength converter 4 is configured to emit light with a longer wavelength than that of primary light 15 emitted by the solid-state light-emitting element 3 through excitation by the primary light 15. Thus a semiconductor light-emitting device is completed.

The adhesive 23 to be used may be selected suitably from resin-based adhesives (for instance, a silicone resin-based adhesive), inorganic-based adhesives, and others, with consideration given to the structure of the solid-state light-emitting element 3, the electrode arrangement, as well as the properties and material of the heat dissipating substrate 1 (particularly, for example, whether it is an electrically insulating substrate or an electrically conductive substrate).

For the inorganic-based adhesive, an electrically insulating inorganic adhesive (for instance, low-melting-point glass) or an electrically conductive inorganic adhesive (for instance, a metal paste (particularly, a silver paste) or a solder (Au—Sn, Ag—Sn)) may be used suitably, with consideration given to the structure of the solid-state light-emitting element 3, the electrode arrangement, and the properties and material of the heat dissipating substrate 1.

It also is preferable that, for example, the conductor A 2a and the power supply electrode are made of the same metal material (for instance, Au) and are joined physically through application of external force by, for example, pressurization or ultrasonic vibration without using the adhesive 23.

In the case of the semiconductor light-emitting device according to the present invention including the aforementioned solid-state light-emitting element 3 with the face-up upper-surface two-electrode structure as shown in FIG. 17, in both the cases where the heat dissipating substrate 1 is an insulating substrate and it is an electrically conductive substrate, the adhesive 23 to be used also can be an electrically insulating adhesive (for example, the aforementioned resin-based adhesive or insulating inorganic adhesive) or an electrically conductive adhesive (for example, the aforementioned electrically conductive inorganic adhesive).

On the other hand, in the case of the semiconductor light-emitting device according to the present invention including the solid-state light-emitting element 3 with the upper- and lower-electrode structure as shown in FIGS. 19 to 21, in order to electrically connect the conductor A 2a and the power supply electrode B 14b of the solid-state light-emitting element 3, an electrically conductive adhesive (for instance, the aforementioned electrically conductive inorganic adhesive) can be selected as the adhesive 23.

As shown in FIG. 26, the semiconductor light-emitting device of the present invention may be configured with at least a heat dissipating substrate 1 that is an insulating substrate, a conductor A 2a, an adhesive 23, and a solid-state light-emitting element 3 that are stacked together.

The conductor B 2b may be disposed on the heat dissipating substrate 1 as shown in FIG. 26 as a specific example but also can be disposed in a place that is not on or above the heat dissipating substrate 1.

The positions of the conductor A 2a and the conductor B 2b to be disposed are not particularly limited as long as they are disposed with at least an insulator (including a gap) being interposed therebetween.

One of a pair of the power supply electrode A 14a and the power supply electrode B 14b of the solid-state light-emitting element 3 is electrically connected to the conductor A 2a and the other is electrically connected to the conductor B 2b.

At least the other of the pair of the power supply electrode A 14a and the power supply electrode B 14b of the solid-state light-emitting element 3 and the conductor B 2b are electrically connected to each other, with the conductor C 5 being connected to both.

The conductor C 5 to be used can be, for example, a metal wire (for example, a gold wire).

In the semiconductor light-emitting device with such electrical connections, electric power can be supplied to the solid-state light-emitting element 3 using the conductor A 2a and the conductor B 2b. Then the solid-state light-emitting element 3 converts electrical energy into light through an electro-optic conversion action, and this light is emitted as primary light 15 from the solid-state light-emitting element 3.

As shown in FIG. 27 and FIG. 28, in the semiconductor light-emitting device of the present invention, it is preferable that the whole of the solid-state light-emitting element 3 is sealed directly or indirectly with a light transmissive object 25. Preferably, the light transmissive object 25 is in contact with at least the wiring electrode A 2a and more preferably, also is in contact with the heat dissipating substrate 1. This makes it possible to obtain heat dissipation paths for the solid-state light-emitting element 3 that reach the wiring electrode A 2a and the heat dissipating substrate 1 (both function as good heat dissipators) through the light transmissive object 25. Accordingly, not only the heat dissipation area and heat dissipation enveloping volume increase but also the heat dissipation cross-section area of the heat dissipation paths also increases. Thus, the heat dissipation effect increases and the temperature increase in the solid-state light-emitting element 3 can be controlled.

Furthermore, since the heat dissipation paths, through which heat is dissipated uniformly, are obtained throughout the whole periphery of the solid-state light-emitting element 3, the increasing temperature of the periphery of the solid-state light-emitting element 3 is made uniform. As a result, the local heating in the solid-state light-emitting element 3 is controlled and thereby an increase in output power also is promoted.

These heat dissipation paths are described later in detail with reference to drawings.

The above-described phrase “the whole of the solid-state light-emitting element 3 is sealed directly or indirectly with a light transmissive object 25” denotes that as shown in FIG. 27, the light transmissive object 25 includes a main light extraction surface and is in direct contact with the whole periphery except for the lower surface of the solid-state light-emitting element 3 and thereby the solid-state light-emitting element 3 is sealed to be enclosed, or that as shown in FIG. 28, the light transmissive object 25 is in contact with the whole periphery except for the lower surface of the solid-state light-emitting element 3, including, for example, the wavelength converter 4, and thereby the solid-state light-emitting element 3 is sealed to be enclosed indirectly.

The light transmissive object 25 to be used can be, for example, translucent resin (for instance, silicone resin or fluorine resin) or a translucent low-melting-point inorganic material (for instance, low-melting-point glass).

Many of those light transmissive objects 25 have relatively high refractive indices. Particularly, in the configuration (see FIG. 27) in which the light transmissive object 25 includes the main light extraction surface and is in direct contact with the whole periphery of the solid-state light-emitting element 3 except for the lower surface thereof and there the solid-state light-emitting element 3 is sealed to be enclosed, the light extraction efficiency of the primary light 15 emitted by the solid-state light-emitting element 3 increases and thus, this configuration also is preferable for increasing the output power of the semiconductor light-emitting device.

It also is preferable that various inorganic materials are contained in the translucent resin or in the translucent low-melting-point inorganic material in order to improve the thermal conductive properties of the light transmissive object 25.

The inorganic material to be contained in the aforementioned translucent resin can be selected from, for example, a translucent inorganic material with optical transparency, a light reflective inorganic material with light reflectivity, a high thermal conductive inorganic material with good thermal conductive properties (with a thermal conductivity of at least 3 W/mK, preferably at least 10 W/mK, and more preferably at least 100 W/mK), a high refractive index inorganic material with a high refractive index (a refractive index of at least 1.2, preferably about at least 1.4 but lower than 4.0 at room temperature in the visible wavelength range of 380 to 780 nm), a light diffusion inorganic material that diffuses primary light 15, and an inorganic phosphor that absorbs the primary light 15 and emits visible light, and at least one of these may be used. It also is preferable that these are used in suitable combinations as required.

Examples of the translucent inorganic materials that can be used include various oxides (for example, aluminum oxide, silicon dioxide, titanium dioxide, magnesium oxide, yttrium oxide, other rare earth oxides, yttrium aluminum garnet, SrTiO₃, and other composite oxides), various nitrides (for example, aluminum nitride, boron nitride, silicon nitride, gallium nitride, and gallium indium nitride), and carbide such as silicon carbide.

Examples of the light reflective inorganic material that can be used include the afore-mentioned various oxides, sulfate such as barium sulfate, and various metals (for example, Al, Ti, Au, and Ag).

Examples of the above-mentioned high thermal conductive inorganic material that can be used include the aforementioned various oxides, the aforementioned various nitrides, various carbides (such as silicon carbide), carbon, and the aforementioned various metals.

The high refractive index inorganic material to be used can be, for example, the aforementioned translucent inorganic material.

Examples of the light diffusion inorganic material that can be used include powder (particles) with a center particle diameter (D₅₀) of about at least 0.1 mum but smaller than 1 mm (submicron to submillimeter) of at least one selected from the translucent inorganic material and the light reflective inorganic material.

The inorganic phosphor to be used can be, for example, the aforementioned inorganic phosphor.

The shape and aspect of the inorganic material to be contained in the translucent resin are not particularly limited. However, inorganic materials that are preferable in terms of easy handling and easy control of thermal conductive properties are particles that are known as powder or a filler, and are, for example, nanoparticles, submicron particles, micron particles, and submillimeter particles, with a mean diameter or a center particle diameter (D₅₀) of about at least 1 nm but smaller than 1 mm.

The abovementioned particles that are preferable for obtaining the light transmissive object 25 with good light transmission properties are particles, each of which has a spherical or quasi-spherical shape, or nanoparticles (with the aforementioned mean diameter or center particle diameter (D₅₀) being about at least 1 nm but smaller than 100 nm). The use of these particles makes it possible to form a light transmissive object 25 with excellent optical transmittance.

FIGS. 29 to 31 each are a schematic view showing heat dissipation paths of heat generated in the solid-state light-emitting element 3 in a mounted structure (a structure with the solid-state light-emitting element 3 mounted on the conductor A 2a located on the heat dissipating substrate 1) shown in FIG. 1 or 26 as a typical example of the semiconductor light-emitting device according to the present invention.

In FIGS. 29 to 31, the heat generation portions are indicated with black and the heat dissipation paths are indicated with arrows.

As shown in FIG. 29, in the semiconductor light-emitting device of the present invention, heat generated in the solid-state light-emitting element 3 that increases with an increase in input power is allowed to be conducted in the horizontal direction of the mounting surface that diverges from the lower surface of the solid-state light-emitting element 3, and through the heat dissipating substrate 1 and conductor A 2a that has good thermal conductivity and that is composed mainly of metal, and thereby it thermally diffuses relatively uniformly with high symmetry at a high speed. This makes it possible to control the local heating in the solid-state light-emitting element 3 that tends to occur increasingly with an increase in size of the solid-state light-emitting element 3.

Furthermore, as shown in FIG. 30, in a semiconductor light-emitting device of the present invention, the generated heat is conducted uniformly and evenly at a high speed to the high thermal conductors (for example, the conductor A 2a, heat dissipating substrate 1, and external heat dissipator (not shown)) disposed below the solid-state light-emitting element 3 through heat conduction performed using the whole lower surface of the solid-state light-emitting element 3 that serves as a mounting surface.

Moreover, the conductor C 5 also is allowed to be composed mainly of metal and to have good thermal conductivity, so that it can be used as a heat dissipating member.

As described above, good thermal conductive properties, relatively large surface areas, and enveloping volumes of the conductor A 2a and the heat dissipating substrate 1 are fully utilized to increase the heat dissipation efficiency in the directly downward direction, obliquely downward directions, and lateral directions of the solid-state light-emitting element 3, so that the decrease in luminous efficiency caused by the temperature increase and uneven heat dissipation in the solid-state light-emitting element 3 can be controlled.

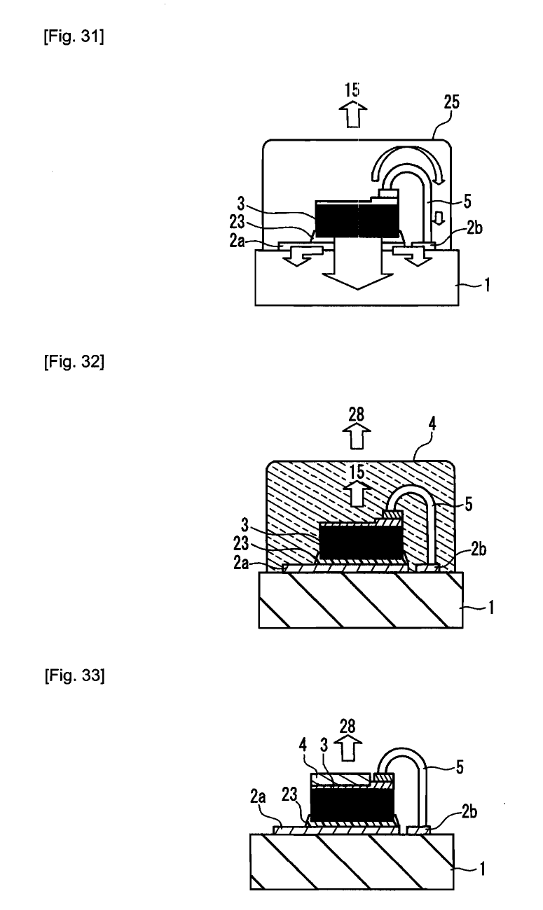

On the other hand, as shown in FIG. 31, the whole heat generation portion of the solid-state light-emitting element 3 is in contact with a light transmissive object 25 with better thermal conductivity than that of various gases (for instance, air) to be sealed therewith so as to be enclosed, and thereby the heat generated in the solid-state light-emitting element 3 may be conducted to the conductor A 2a and the heat dissipating substrate 1 through the light transmissive object 25. This makes it possible to obtain heat dissipation paths, through which heat is dissipated uniformly, throughout the whole periphery of the heat generation portion to make uniform the temperature increase in the vicinity of the solid-state light-emitting element 3, and to control the local heating in the solid-state light-emitting element 3 to increase the output power of the semiconductor light-emitting device.

In Embodiment 3, the solid-state light-emitting element 3 was described using an example that had a structure with a pair of power supply electrodes on the upper and lower surfaces. However, it is obvious that similar operational effects can be obtained even in the case of the solid-state light-emitting element 3 having a structure with a pair of power supply electrodes on the upper surface.

For the same reason as that described in Embodiment 1, the semiconductor light-emitting device of Embodiment 3 also may be one with no wavelength converter 4.

### Embodiment 4

Hereinafter, for example, the arrangement of the wavelength converter 4 will be described with reference to drawings.

FIGS. 28, 32, and 33 each show a cross section (side face) taken on line I-I′ shown in FIG. 1 of, for example, the semiconductor light-emitting device of Embodiment 1 shown in FIG. 1.

In Embodiment 4, for example, the arrangement of the wavelength converter 4 is described using, as a typical example, the semiconductor light-emitting device of Embodiment 1 shown in FIG. 1.

In any of the cases of the semiconductor light-emitting devices shown in FIGS. 28, 32, and 33, the phosphor contained in the wavelength converter 4 is excited by the primary light 15 emitted from the solid-state light-emitting element 3, and thereby output light 28 contains at least light whose wavelength has been converted by the wavelength converter 4.

The output light 28 further may contain the primary light 15, and may be a mixed color light containing both components of the primary light 15 and the wavelength conversion light (not shown).

The semiconductor light-emitting devices shown in FIGS. 28, 32, and 33 are examples of the semiconductor light-emitting device formed in such a manner that the wavelength converter 4 adheres to at least the main light extraction surface of the solid-state light-emitting element 3.

In the semiconductor light-emitting device shown in FIG. 32, the wavelength converter 4 is used that is formed by dispersing, for example, phosphor particles 17b (see FIG. 23) in translucent resin (particularly, silicone resin). The whole of the solid-state light-emitting element 3 is sealed directly with the wavelength converter 4, and the wavelength converter 4 is in contact with the wiring electrode A 2a and the heat dissipating substrate 1.

The semiconductor light-emitting device with such a configuration makes it possible not only to obtain the heat dissipation paths for the solid-state light-emitting element 3 that reach the wiring electrode A 2a and the heat dissipating substrate 1 through the wavelength converter 4 but also to increase the heat dissipation area and heat dissipation enveloping volume of the wavelength converter 4 itself. Accordingly, the heat dissipation effects of both the solid-state light-emitting element 3 and the wavelength converter 4 increase, and thereby the temperature increase in the solid-state light-emitting element 3 and the wavelength converter 4 is controlled.

Furthermore, since heat dissipation paths, through which heat is dissipated uniformly, are obtained throughout the whole periphery of the solid-state light-emitting element 3, the increasing temperature in the vicinity of the solid-state light-emitting element 3 is uniformized. As a result, local heating in the solid-state light-emitting element 3 is controlled and thereby an increase in output power is promoted.

In the semiconductor light-emitting device shown in FIG. 33, one of the various wavelength converters 4 that have been described in some columns relating to the wavelength converter is used as a small piece. The wavelength converter 4 is formed so as to adhere to at least the main light extraction surface of the solid-state light-emitting element 3. Preferably, the wavelength converter 4 is bonded to the main light extraction surface.

In the semiconductor light-emitting device with such a configuration, the area of the main light extraction surface of the solid-state light-emitting element 3 is substantially equal to that of the light emitting surface of the semiconductor light-emitting device, and all the photons of the primary light 15 are incident on the wavelength converter 4 at the moment the primary light 15 is emitted. Accordingly, it is possible to provide a high-intensity point light source that is suitable, for example, for a vehicle headlamp from the viewpoint of the device configuration.

In the semiconductor light-emitting device with such a point light source configuration, the area of the wavelength converter 4 on which light is incident is small. Accordingly, generally, the temperature of the wavelength converter 4 tends to increase, and it becomes difficult to increase the output power through temperature quenching of the wavelength converter 4, which is a problem.

However, with the aforementioned configuration, it is possible to obtain, particularly by bonding, relatively good heat dissipation paths, through which heat is dissipated in the lower direction through the solid-state light-emitting element 3 (generally known for having high thermal conductivity in many cases) although heat that is generated through wavelength conversion and is accumulated to cause the temperature increase in the wavelength converter 4 is high. Since this serves to control the temperature increase in the wavelength converter 4, an increase in output power also is promoted in the semiconductor light-emitting device with such a point light source configuration.

As described above, the wavelength converter 4 is a wavelength converter (for example, translucent phosphor ceramic) made only of inorganic materials with a relatively high thermal conductivity, and is preferably a wavelength converter containing an inorganic phosphor (for example, the aforementioned Y₃Al₅O₁₂:Ce³⁺— based yellow-green phosphor) with less temperature quenching.

The aforementioned bonding can be carried out using either an inorganic or organic translucent material as an adhesive.

Specific examples of the adhesive include silicone-based resin, fluorine-based resin, and a low-melting-point inorganic material with a melting point of about 500 degrees C or lower (for instance, low-melting-point glass).

Such adhesives are readily available and many of them are practically well-proven.

Accordingly, bonding can be performed by a relatively simple process.

The semiconductor light-emitting device shown in FIG. 28 is a modified example of the semiconductor light-emitting device shown in FIG. 33 and is configured to seal indirectly the whole solid-state light-emitting element 3 with the light transmissive object 25 described in Embodiment 3 and to allow the light transmissive object 25 to be in contact with the wiring electrode A 2a and the heat dissipating substrate 1 in the semiconductor light-emitting device shown in FIG. 33.

The functions and effects of this configuration are the same as in the case of Embodiment 3 and therefore descriptions thereof are not repeated here.

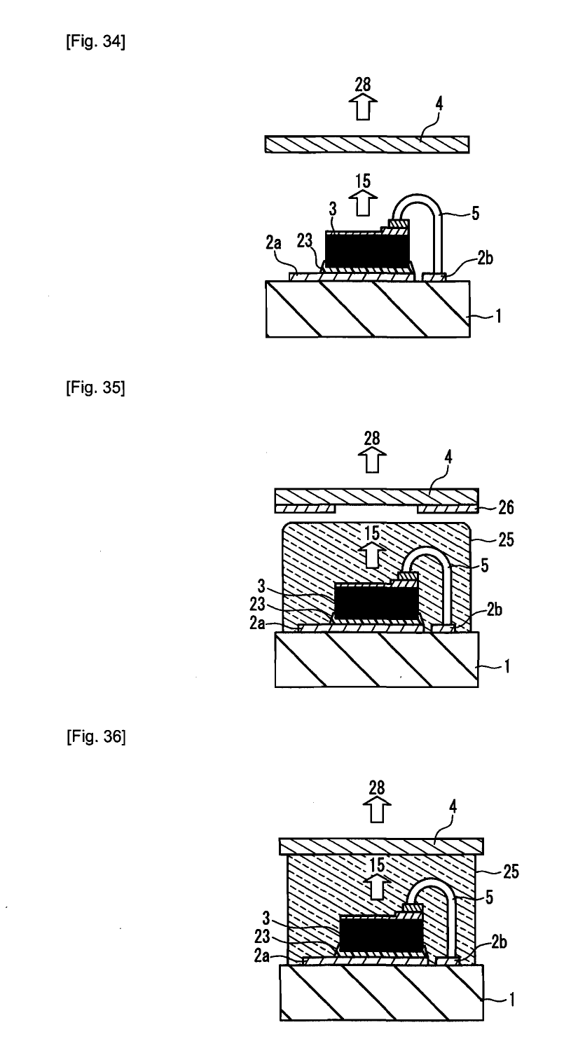

On the other hand, the semiconductor light-emitting devices shown in FIGS. 34 to 36 are examples of the semiconductor light-emitting device in which the wavelength converter 4 is disposed above at least the main light extraction surface of the solid-state light-emitting element 3 without being in contact with the main light extraction surface.

The semiconductor light-emitting device shown in FIG. 34 is a semiconductor light-emitting device with a configuration in which one of the various wavelength converters 4 that have been described in some columns relating the wavelength converter is disposed, with a gap being interposed, above the mounted structure (a structure with the solid-state light-emitting element 3 mounted on the conductor A 2a located on the heat dissipating substrate 1) described in Embodiment 3 with reference to FIG. 26.

The semiconductor light-emitting device shown in FIG. 35 is a semiconductor light-emitting device with a configuration in which one of the various wavelength converters 4 that have been described in some columns relating the wavelength converter is disposed, with a gap being interposed, above the mounted structure (a structure with the solid-state light-emitting element 3 mounted on the conductor A 2a located on the heat dissipating substrate 1) in which the light transmissive object 25 described with reference to FIG. 27 in Embodiment 3 is in direct contact with the whole periphery of the solid-state light-emitting element 3 to seal the solid-state light-emitting element 3 so that the element 3 is enclosed therein.

In this example, as shown in FIG. 35, a light shielding object 26 is provided on one side of the wavelength converter 4, and thereby only light components with high directionality of the primary light 15 emitted by the solid-state light-emitting element 3 are allowed to be incident on the wavelength converter 4, so that variations in color of the output light 28 are reduced that are caused by the difference in the optical path length of the primary light 15 that passes through the wavelength converter 4.

In this case, the ratio of area of the wavelength converter 4 on which primary light 15 is incident is low, and thereby the portion of the wavelength converter 4 on which no light is incident functions as a heat dissipator. This allows the temperature increase in the wavelength converter 4 to be controlled and thereby the temperature quenching in the wavelength converter 4 is controlled. Thus, an increase in output power of the semiconductor light-emitting device is promoted.

When the light shielding object 26 is formed of a material with high thermal conductivity (for instance, an inorganic material selected from, for example, various metals, semiconductors, silicides, nitrides, and carbides) and further a configuration is employed in which the light shielding object 26 adheres or bonded to the wavelength converter 4, the light shielding object 26 also functions as a good heat dissipator, which is further preferable.

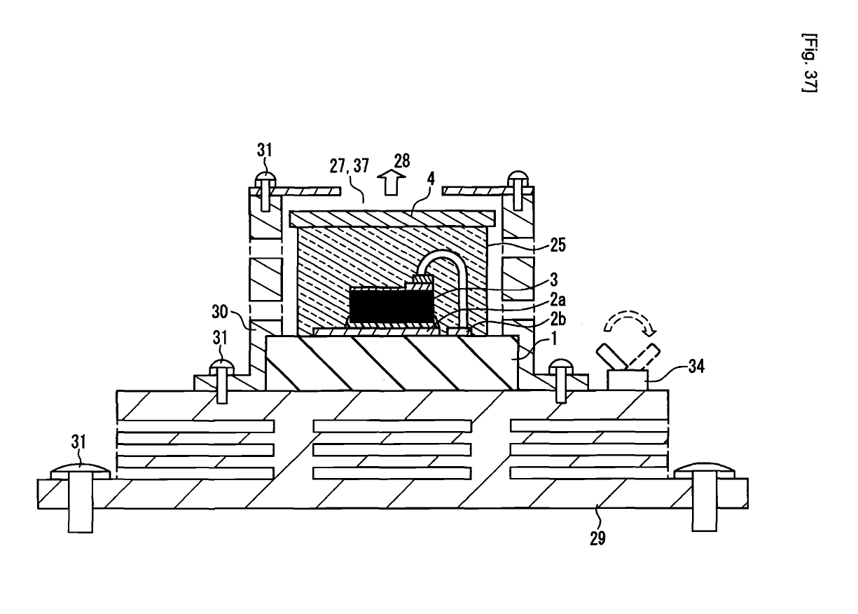

The semiconductor light-emitting device shown in FIG. 36 is a semiconductor light-emitting device with a configuration in which one of various wavelength converters 4 (at least one wavelength converter 4 that has been described in some columns relating the wavelength converter) is disposed on the light transmissive object 25 of a mounted structure (a structure with the solid-state light-emitting element 3 mounted on the conductor A 2a located on the heat dissipating substrate 1) in which the light transmissive object 25 described with reference to FIG. 27 in Embodiment 3 is in direct contact with the whole periphery of the solid-state light-emitting element 3 to seal the solid-state light-emitting element 3 so that the element 3 is enclosed therein. In this case, the primary light 15 that has passed through the light transmissive object 25 is incident on the wavelength converter 4, and as described in Embodiment 3, the light transmissive object 25 increases the light extraction efficiency of the primary light 15 emitted by the solid-state light-emitting element 3, so that an increase in output power of the semiconductor light-emitting device is promoted. Furthermore, the light transmissive object 25 itself functions as a heat dissipator for releasing the heat of the wavelength converter 4 that is generated accompanying the wavelength conversion. As described in Embodiment 3, in a preferred embodiment, the light transmissive object 25 is formed of an inorganic material with high thermal conductivity (for example, a translucent inorganic material, a light reflective inorganic material, a high thermal conductive inorganic material, a high refractive index inorganic material, a light diffusion inorganic material, or an inorganic phosphor) contained therein. Accordingly, since it can function as a better heat dissipator, the temperature quenching in the light wavelength converter 4 is controlled and thereby an increase in output power of the semiconductor light-emitting device is promoted.

As shown in FIG. 36, the wavelength converter 4 is preferably one with a light output surface whose area is larger than that of the main light extraction surface of the solid-state light-emitting element 3. Since this allows the wavelength converter 4 to have a relatively large heat dissipation area, the wavelength converter 4 itself has good heat dissipation properties.

Furthermore, in order to obtain excellent heat resistance and good heat dissipation properties of the wavelength converter 4 itself, the wavelength converter 4 is either a forming body containing an inorganic phosphor or a complex containing an inorganic phosphor and preferably is formed to be provided on the light transmissive object 25, and more preferably is formed to be bonded onto the light transmissive object 25. This makes it possible to obtain heat dissipation paths that pass through the light transmissive object 25 to dissipate heat and thereby to control the temperature increase in the wavelength converter 4.

The aforementioned bonding can be performed using either an inorganic or organic translucent material as an adhesive.

The adhesive to be used can be a resin-based translucent adhesive (for instance, a silicone resin-based adhesive) or a low-melting-point inorganic adhesive (for example, low-melting-point glass). Such adhesives are readily available and therefore bonding can be performed by a simple process.

Furthermore, it is preferable that the wavelength converter 4 is one formed of the aforementioned ceramic-based forming body with excellent linear transmittance and the light transmissive object 25 is one formed of the aforementioned light diffusion inorganic material contained therein. This makes it possible to control temperature quenching and color separation of the mixed color light. Thus, it becomes possible to provide a semiconductor light-emitting device that is excellent in terms of increased output power and uniformization of luminescence color.

Similarly in Embodiment 4, the solid-state light-emitting element 3 was described using an example with a structure having a pair of power supply electrodes on the upper and lower surfaces thereof. However, it is apparent that the same operational effects can be obtained even in the case of the solid-state light-emitting element 3 with a structure having a pair of power supply electrodes on the upper surface.

### Embodiment 5

Hereinafter, an embodiment of the light source device with a semiconductor light-emitting device of the present invention used therein is described.

FIG. 37 is a sectional side view showing an example of a light source for general lighting that is configured using a semiconductor light-emitting device of the present invention.

In FIG. 37, the semiconductor light-emitting device 27 is a semiconductor light-emitting device described in Embodiments 1 to 4 and emits output light 28 upon electric power supply.

Furthermore, as described in Embodiments 3 and 4, the mounted structure 37 is a structure with the solid-state light-emitting element 3 and others mounted on the heat dissipating substrate 1 and emits primary light upon electric power supply.

The external heat dissipator 29 is one with, for example, a heat dissipating fin and is used for dissipating heat generated in the semiconductor light-emitting device 27 to cool the semiconductor light-emitting device 27.

As shown in FIG. 37, the light source device of Embodiment 5 is characterized by being configured using the semiconductor light-emitting device 27 of the present invention.

Preferably, the light source device of Embodiment 5 is characterized by being formed of a combination of at least the semiconductor light-emitting device 27 of the present invention and the external heat dissipator 29 (or characterized by being formed of a combination of at least the mounted structure 37, the wavelength converter 4, and the external heat dissipator 29). The light source device of Embodiment 5 has a configuration in which the semiconductor light-emitting device 27 of the present invention (or mounted structure 37) and the external heat dissipator 29 are joined to each other using, for example, fixing jigs 30 and mounting screws 31, and at least the heat generated during operation of the semiconductor light-emitting device 27 (or mounted structure 37) of the present invention is dissipated through the external heat dissipator 29. This makes it possible to provide a compact light source device that emits high-power illumination light.

Hereinafter, respective components are described briefly but an increase in output power by controlling the temperature increase in, for example, the solid-state light-emitting element 3 is as described earlier in Embodiments 3 and 4 and therefore the description thereof is not repeated here.

The light source device shown in FIG. 37 is one with the semiconductor light-emitting device 27 of the present invention fixed to the central part of the external heat dissipator 29 using fixing jigs 30.

The wavelength converter 4 (for instance, the aforementioned translucent phosphor ceramic) is fixed onto the (resin-based) light transmissive object 25 in such a manner as to adhere thereto, and the light transmissive object 25 is formed in such a manner as to directly cover the main light extraction surface of the solid-state light-emitting element 3. In this case, primary light (not shown) emitted by the solid-state light-emitting element 3 is extracted with high light extraction efficiency to enter the wavelength converter 4 due to the presence of resin with a relatively high refractive index that adheres onto the main light extraction surface of the solid-state light-emitting element 3. Thus, high output light 28 can be obtained.

In order to increase, even if only slightly, the cooling efficiency of the semiconductor light-emitting device 27 according to the present invention, some vents are provided for the fixing jigs 30 located on the side faces of the light source device of Embodiment 5.

Although it is not shown in FIG. 37, a light source device that has been described with reference to FIGS. 9 to 11 is obtained that includes a semiconductor light-emitting device in which the conductors X have a wiring pattern that allows the power supply terminals to be switched. Moreover, the light source device further including a circuit switching device 34 for switching the power supply terminals is obtained (the circuit configuration is as shown in FIG. 9 as a specific example and therefore the description thereof is not repeated).

The circuit switching device 34 to be used can be selected suitably from an automatic device and a manual device, with the automatic device having a circuit-disconnection detection function and an automatic switching function and being able to detect disconnection and to switch the circuit automatically.

As described earlier, the light source device of Embodiment 5 has a configuration in which the mounted structure 37 is excellent in heat dissipation properties and heat resistance, and therefore it is possible to reduce the enveloping volume of the external heat dissipator 29 to obtain a small-sized compact light source device.

### Embodiment 6

Hereinafter, another embodiment of the light source device is described in which a semiconductor light-emitting device of the present invention is used.

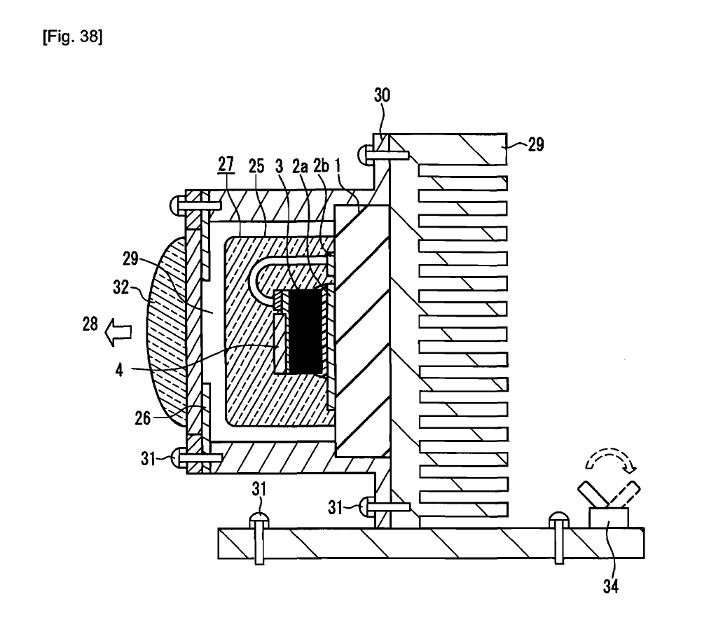

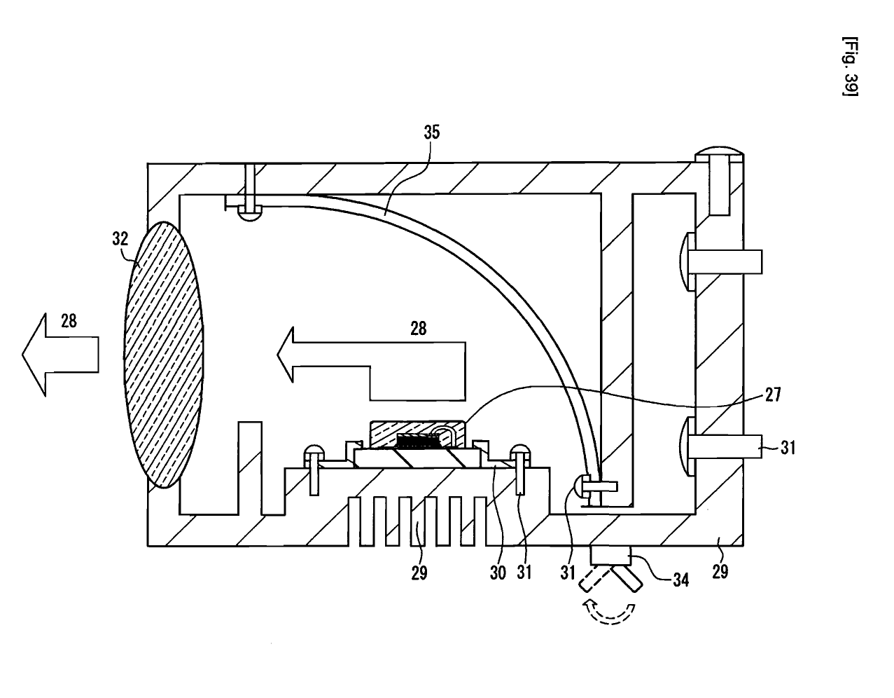

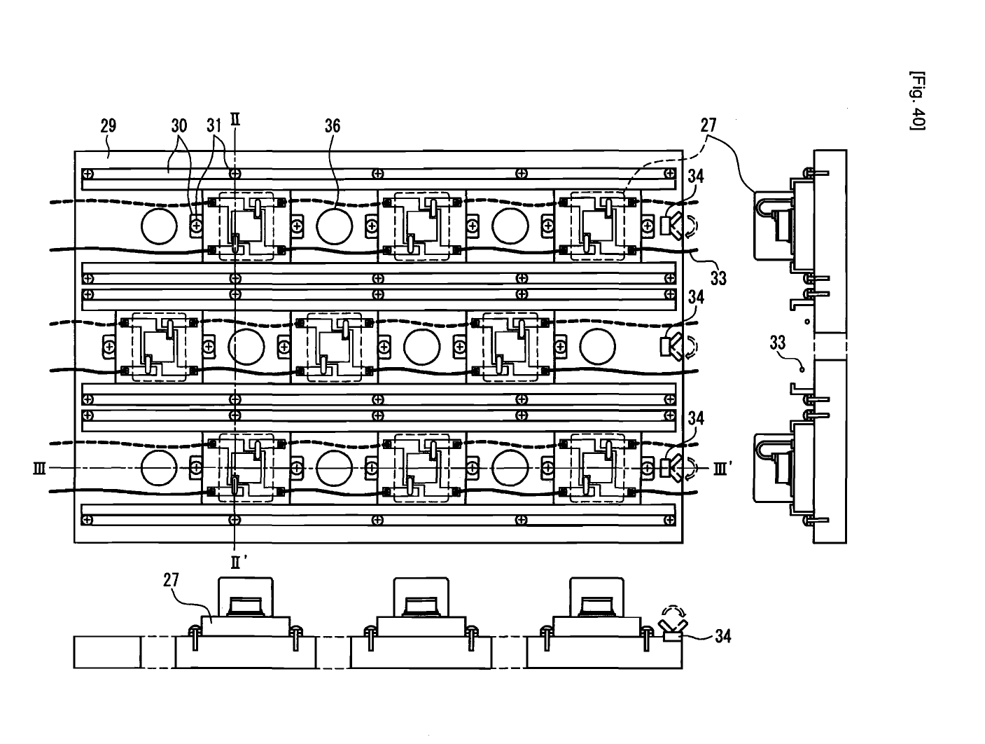

FIGS. 38 and 39 each are a sectional side view showing an example of headlight equipment (for example, a projection light source or a vehicle headlamp) configured with a semiconductor light-emitting device of the present invention.

As shown in FIGS. 38 and 39, the light source device of Embodiment 6 also is characterized by being configured using the semiconductor light-emitting device 27 of the present invention. Preferably, the light source device of Embodiment 6 is characterized by being formed of a combination of at least the semiconductor light-emitting device 27 of the present invention and the external heat dissipator 29. This makes it possible to provide a small-sized compact light source device that emits a high power front light.

In FIGS. 38 and 39, the semiconductor light-emitting device 27 is any of the semi-conductor light-emitting devices described in Embodiments 1 to 4 and emits output light 28 upon electric power supply.

In the light source device of Embodiment 6, the semiconductor light-emitting device with the configuration shown in FIG. 28 is used in order to obtain a high power point light source.

That is, in the light source device of Embodiment 6, any one of various wavelength converters 4 (for example, a resin phosphor film and translucent phosphor ceramic) that have been described earlier is used as a small piece. The wavelength converter 4 is formed so as to adhere to at least the main light extraction surface of the solid-state light-emitting element 3. Preferably, the wavelength converter 4 is bonded to the main light extraction surface.

In the light source device with such a configuration, the area of the main light extraction surface of the solid-state light-emitting element 3 is substantially equal to that of the light emitting surface of the semiconductor light-emitting device, and all the photons of the primary light are incident on the wavelength converter 4 at the moment the primary light is emitted. Thus, it is possible to provide a high-intensity point light source.

A preferable wavelength converter 4 is a wavelength converter made only of inorganic materials and is, for example, translucent phosphor ceramic, phosphor glass, or the aforementioned MGC optical conversion member. Such a wavelength converter made only of inorganic materials has high thermal conductivity and therefore tends not to accumulate heat. Accordingly, even in a semiconductor light-emitting device with such a configuration in which the energy density of light that is incident on the wavelength converter 4 is high, the temperature increase in the wavelength converter 4 is relatively controllable and thereby output light 28 with high energy efficiency can be obtained.

In Embodiment 6, however, the semiconductor light-emitting device that is used for the light source device is not limited thereto.

On the other hand, the external heat dissipator 29 is, for example, a heat dissipator with a heat dissipating fin, a structure with a heat dissipation function, or a water-cooling jacket. It is used to dissipate heat generated in the semiconductor light-emitting device 27 to cool the semiconductor light-emitting device 27.

In FIGS. 38 and 39, light source devices are provided with an optical lens 32 for collecting light emitted by the semiconductor light-emitting device 27 of the present invention. In FIG. 38, a light source device further is provided with a light shielding object 26 for obtaining a desired light distribution pattern. However, these fittings may be used by being selected suitably as required.

Moreover, similarly in the light source device of Embodiment 6, it can be provided with such a circuit switching device 34 as described with respect to the light source device of Embodiment 5 shown in FIG. 37.

Hereinafter, respective components are described briefly but an increase in output power by controlling the temperature increase in the solid-state light-emitting element 3 and the wavelength converter 4 is as described earlier in Embodiments 3 and 4 and therefore the description thereof is not repeated here.

The light source device shown in FIG. 38 is an example of a light source device for front lighting and is configured so that the semiconductor light-emitting device 27 of the present invention is fixed to the external heat dissipator 29 using the fixing jigs 30, and the output light 28 emitted from the semiconductor light-emitting device 27 in the lateral direction is emitted directly as output light from the light source device.

The light source device shown in FIG. 39 is an example of a vehicle headlamp and is configured so that the semiconductor light-emitting device 27 of the present invention is fixed to the external heat dissipator 29 using the fixing jigs 30, the output light 28 emitted from the semiconductor light-emitting device 27 in the upper direction in FIG. 39 is reflected by a reflector 35 to turn to the lateral direction, which is then emitted as output light of the light source device.

The light source device of Embodiment 6 has a configuration that is excellent in heat dissipation properties and heat resistance. Accordingly, the enveloping volume of the external heat dissipator 29 can be reduced and thereby a small-sized compact light source device can be obtained.

### Embodiment 7

Hereinafter, still another embodiment of the light source device is described in which a semiconductor light-emitting device of the present invention is used.

FIG. 40 includes a top view and schematic sectional side views (cross sectional views taken on lines II-II′ and III-III′ shown in the top view) that show an example of a liquid crystal backlight that is configured using a semiconductor light-emitting device of the present invention.

The semiconductor light-emitting device 27 and external heat dissipator 29 are as described earlier in Embodiments 5 and 6 and therefore the descriptions thereof are not repeated.

Furthermore, an increase in output power by controlling the temperature increase in, for example, the solid-state light-emitting element 3 also is as described earlier in Embodiments 3 and 4 and therefore the description thereof is not repeated here.

As shown in FIG. 40, the light source device of Embodiment 7 also is characterized by being configured using semiconductor light-emitting devices 27 of the present invention.

Preferably, the light source device of Embodiment 7 is characterized by being formed of a combination of at least a semiconductor light-emitting device 27 of the present invention and the external heat dissipator 29. For instance, it is configured to fix the semiconductor light-emitting device 27 of the present invention to the external heat dissipator 29 using, for example, fixing jigs 30 and mounting screws 31, and to dissipate at least the heat generated during operation of the semiconductor light-emitting device 27 of the present invention, through the external heat dissipator 29, so that a light source device that emits high intensity backlight light can be provided.

The light source device shown in FIG. 40 is configured so that a plurality of semi-conductor light-emitting devices 27 are disposed on one side of a planar external heat dissipator 29 and the whole one side of the planar external heat dissipator 29 emits light.

In order to increase cooling efficiency of the semiconductor light-emitting device 27, vents 36 also can be provided for the external heat dissipator 29.

In order to obtain a surface light source that emits more uniform light, it is preferable that a plurality of semiconductor light-emitting devices 27 are disposed on one side of the planar external heat dissipator 29 at substantially equal intervals.

Moreover, the light source device of Embodiment 7 also can be provided with a circuit switching device 34 as described earlier with respect to the light source device of Embodiment 5 shown in FIG. 37.

As shown in FIG. 40, the light source device is configured to allow, for example, the fixing jigs 30 and the mounting screws 31 to be attached/detached to attach/detach the semiconductor light-emitting device 27 and thereby to replace it. Thus, it allows failures such as disconnection to be handled easily at low cost.

It is apparent that in addition to those described above, a large number of modified examples of the light source devices using semiconductor light-emitting devices of the present invention are conceivable based on similar technical ideas.

### Embodiment 8

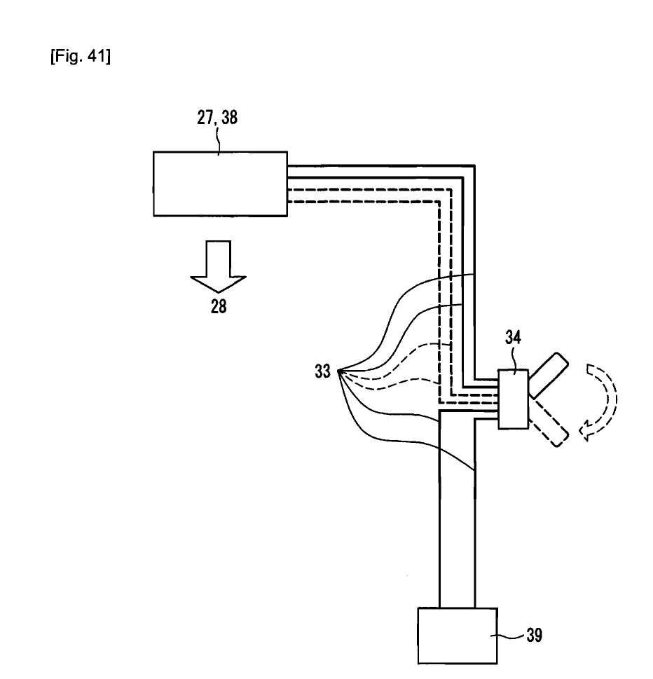

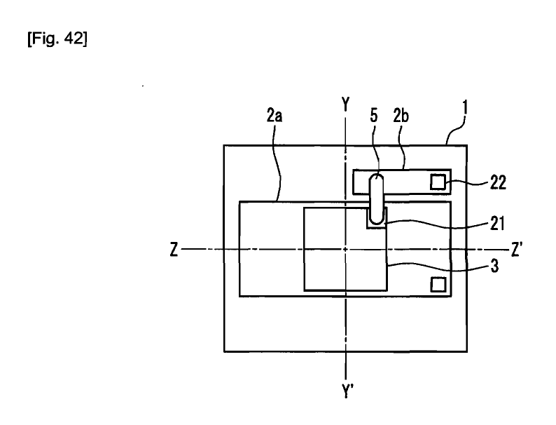

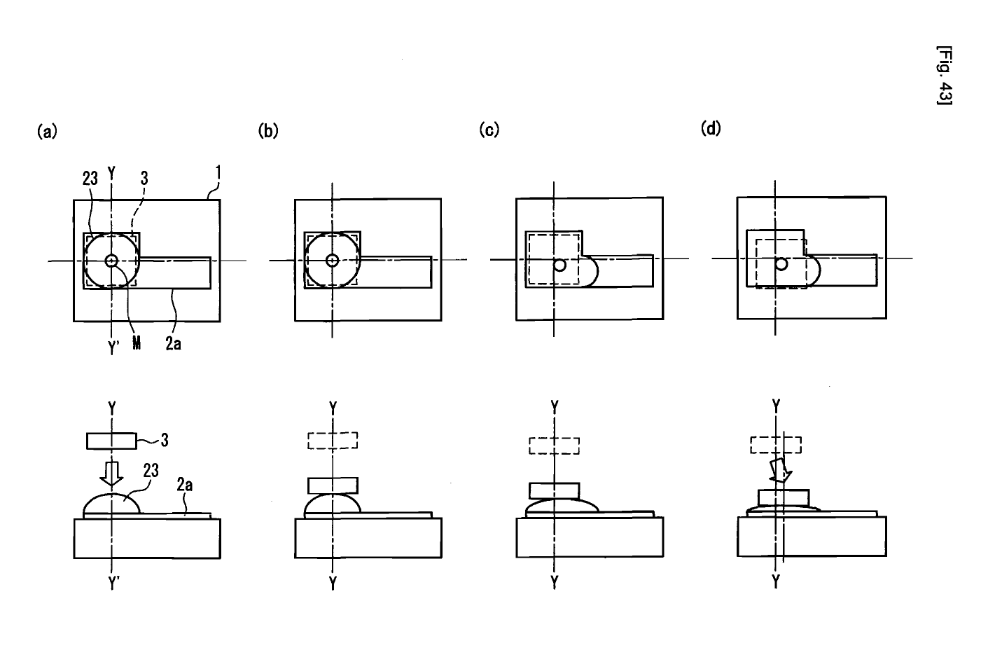

FIG. 41 is a diagram showing an example of the lighting system according to the present invention.

The lighting system of Embodiment 8 is characterized by being configured using at least a circuit switching device 34 for switching power supply terminals of the semi-conductor light-emitting device 27 and the semiconductor light-emitting device 27 (the semiconductor light-emitting device of the present invention described in Embodiment 1 or 2) of the present invention having a wiring structure that allows the same electric power to be supplied to the same solid-state light-emitting element 3 under the same conditions through switching of at least the conductor B2b.

That is, the lighting system of Embodiment 8 is one including a circuit switching device 34 and a semiconductor light-emitting device 27 (the semiconductor light-emitting device of the present invention described in Embodiments 1 or 2) of the present invention having a wiring structure that allows the same electric power to be supplied to the same solid-state light-emitting element 3 under the same conditions through switching of at least the conductor B 2b or a light source device 38 (for example, one of the light source devices of the present invention described in Embodiments 5 to 7) of the present invention provided with the above-mentioned semi-conductor light-emitting device 27 of the present invention.

In FIG. 41, the semiconductor light-emitting device 27 has a configuration in which as described in Embodiment 1 or 2, the conductors B 2a and the electrode lead-out parts 21 of the solid-state light-emitting element 3 are electrically connected to each other with conductors C 5, the conductors B 2b have a larger number of wiring structures as compared to the conductor A 2a, and electric power is supplied to the solid-state light-emitting element 3 using a pair of the conductor A 2a and the conductor B 2b. The semiconductor light-emitting device 27 is a semiconductor light-emitting device of the present invention having wiring structures that allow the same electric power to be supplied to the same solid-state light-emitting element 3 under the same conditions through switching of at least the conductor B 2b.

The lighting system of Embodiment 8 also can be configured using the light source device 38 of the present invention including the semiconductor light-emitting device 27 concerned instead of the semiconductor light-emitting device 27 of the present invention.

Furthermore, the circuit switching device 34 is used for switching the power supply terminals of the semiconductor light-emitting device according to the present invention and is the circuit switching device whose circuit configuration is described earlier as an example with reference to FIGS. 9 to 11.

The circuit switching device 34 can be either an automatic device or a manual device, with the automatic device having a circuit-disconnection detection function and an automatic switching function and being able to detect disconnection and to switch the circuit automatically.

Furthermore, a power supply 39 is used for supplying electric power to the semi-conductor light-emitting device 27 of the present invention or the light source device 38 of the present invention through power supply wirings 33 and a circuit switching device 34. The power supply 39 is a power supply or a power supply system that generates predetermined direct-current or alternating-current voltage or pulse voltage according to the power supply specification of the semiconductor light-emitting device 27 of the present invention or the light source device 38 of the present invention.

The lighting system thus configured is a highly convenient lighting system with consideration given to the following. That is, even if a wiring joint portion is disconnected due to, for example, the life of wiring or vibration and it stops lighting up, for example, in the darkness or while driving a vehicle at night, it can be restored instantly and light up immediately without requiring replacement of the light source.

In the lighting system of Embodiment 8, since the semiconductor light-emitting device 27 or the light source device 38 is configured to be excellent in heat dissipation properties and heat resistance, the enveloping volume of the external heat dissipator 29 can be reduced and thereby a small-sized compact lighting system can be obtained.

It is obvious that in addition to those described above, a large number of modified examples of the lighting system by using the semiconductor light-emitting device 27 or light source device 38 of the present invention and the circuit switching device 34 for switching power supply terminals of the semiconductor light-emitting device 27 are conceivable based on similar technical ideas.

### INDUSTRIAL APPLICABILITY

As described above, the present invention can provide semiconductor light-emitting devices with both high output power and high reliability as well as light source devices and lighting systems including the same, with the semiconductor light-emitting devices being able to be produced by a simple application of orthodox practical techniques and being able to be designed with consideration given to the case of lighting failures according to customer's needs and convenience. Thus, the present invention is of great practical value.

### REFERENCE SIGNS LIST

1 Heat dissipating substrate
2a Conductor A, that is patterned electrode
2b Conductor B, that is patterned electrode
3 Solid-state light-emitting element
4 Wavelength converter
5 Conductor C, that is conducting wire
6 Electrode pad
7 Insulating base
8 Electrically conductive base
9 Translucent base
10 Reflective layer
11 Semiconductor light-emitting layer
12 Translucent electrode
13 Electrode
14a Power supply electrode A
14b Power supply electrode B
15 Primary light
16 Translucent matrix
17 Phosphor
17a Phosphor forming body
17b Phosphor particles
20 Translucent adherend base
21 Electrode lead-out part
22 Power supply terminal
22a Power supply terminal A
22b Power supply terminal B
22c Power supply terminal C
22d Power supply terminal D
23 Adhesive
25 Light transmissive object
26 Light shielding object
27 Semiconductor light-emitting device
28 Output light
29 External heat dissipator
30 Fixing jig
31 Mounting screw
32 Optical lens
33 Power supply wiring
34 Circuit switching device
35 Reflector
36 Vent
37 Mounted structure
38 Light source device
39 Power supply

1. A semiconductor light-emitting device, comprising at least one conductor A, that is patterned electrode, a conductor B, that is patterned electrode, and a solid-state light-emitting element on one side of an insulating heat dissipating substrate,
with the solid-state light-emitting element being mounted on the conductor A but not being mounted on the conductor B,
wherein the solid-state light-emitting element has a pair of power supply electrodes either on an upper surface or on upper and lower surfaces thereof, and
further the solid-state light-emitting element is mounted in such a manner that a whole lower surface that is a surface opposing to a main light extraction surface of the solid-state light-emitting element adheres to the conductor A,
when a mounting surface of the solid-state light-emitting element is viewed from above,
the conductor A has an element mounting area on which the whole lower surface of the solid-state light-emitting element is mounted and a plurality of outflow-adhesive capturing areas that are provided adjacent to a periphery of the element mounting area without directional bias with respect to the periphery of the element mounting area,
the conductor A has a recess in a part of the outer periphery thereof and the conductor B has a structure in which it is disposed so that a part or the whole thereof fits into the recess of the conductor A,
one of the pair of power supply electrodes and the conductor B fitting into the recess of the conductor A are electrically connected to each other using a metal wire,
the conductor A has a shape that substantially has rotational symmetry about the element mounting area but does not have line symmetry, and
the conductor B is disposed in a portion adjacent to the periphery of the element mounting area other than the outflow-adhesive capturing areas while being separated electrically from the conductor A.

2. The semiconductor light-emitting device according to claim 1, wherein the conductor B is disposed in such a manner as to have an outer frame center in a position to avoid the centerlines of vertical and horizontal directions of the solid-state light-emitting element.

3. (canceled)

4. The semiconductor light-emitting device according to claim 3, wherein the solid-state light-emitting element is mounted in a position that falls on a central part of an outer frame of the conductor A, the conductor A has a shape based on the same shape as that of the lower surface of the solid-state light-emitting element, and it is formed to have an edge along the whole outer periphery of the lower surface of the solid-state light-emitting element.

5. The semiconductor light-emitting device according to claim 1, wherein a conductor X that denotes all the conductor A and the conductor B has an area ratio of at least 50% but less than 100% on the heat dissipating substrate.

6. The semiconductor light-emitting device according to claim 5, wherein the conductor A has a total area ratio of at least 50% of the conductor X.

7. The semiconductor light-emitting device according to claim 6, wherein the heat dissipating substrate has a shape with inversion symmetry, and the solid-state light-emitting element has a mounting surface on a line of symmetry of the heat dissipating substrate.

8. The semiconductor light-emitting device according to claim 1, wherein a conductor X that denotes all the conductor A and the conductor B has substantially rotational symmetry on one flat surface of the heat dissipating substrate.

9. The semiconductor light-emitting device according to claim 1, wherein the conductor B and an electrode lead-out part of the solid-state light-emitting element are electrically connected to each other with a conductor C, that is conducting wire, the conductor B has a larger number of wiring structures as compared to the conductor A, and electric power is supplied to the solid-state light-emitting element using a pair of the conductor A and the conductor B, and
the semiconductor light-emitting device has a wiring structure that allows the same electric power to be supplied to the same solid-state light-emitting element under the same conditions through switching at least the conductor B.

10. The semiconductor light-emitting device according to claim 1, wherein the solid-state light-emitting element has a structure including a semiconductor light-emitting layer that serves as a source of primary light near an upper surface when the mounting surface of the solid-state light-emitting element is taken as a lower surface, and electrodes on the upper and lower surfaces of the solid-state light-emitting element.

11. The semiconductor light-emitting device according to claim 1, further comprising a wavelength converter on the main light extraction surface of the solid-state light-emitting element, wherein the wavelength converter emits light with a longer wavelength than that of primary light through excitation by the primary light that is emitted by the solid-state light-emitting element.

12. The semiconductor light-emitting device according to claim 1, wherein a plurality of the conductors A are provided on one flat surface of the heat dissipating substrate.

13. A light source device, comprising a semiconductor light-emitting device according to claim 1.

14. A lighting system, comprising a semiconductor light-emitting device according to claim 9 and a circuit switching device for switching a power supply terminal of the semiconductor light-emitting device.

15. The semiconductor light-emitting device according to claim 1, wherein the conductor A has a shape including at least a shape extending in the opposing directions while diverging from the mounting surface, with the center of the element mounting area being taken as the reference point.

16. The semiconductor light-emitting device according to claim 1, wherein the total area of the upper surface of the conductors A located directly under a light output surface in the semiconductor light-emitting device account for at least 50% of the area of the light output surface.

17. A semiconductor light-emitting device, comprising at least one conductor A, that is patterned electrode, a conductor B, that is patterned electrode, and a solid-state light-emitting element on one side of an insulating heat dissipating substrate,
with the solid-state light-emitting element being mounted on the conductor A but not being mounted on the conductor B,
wherein the solid-state light-emitting element has a pair of power supply electrodes either on an upper surface or on upper and lower surfaces thereof, and
further the solid-state light-emitting element is mounted in such a manner that a whole lower surface that is a surface opposing to a main light extraction surface of the solid-state light-emitting element adheres to the conductor A,
when a mounting surface of the solid-state light-emitting element is viewed from above,
the conductor A has an element mounting area on which the whole lower surface of the solid-state light-emitting element is mounted and a plurality of outflow-adhesive capturing areas that are provided adjacent to a periphery of the element mounting area without directional bias with respect to the periphery of the element mounting area,
the conductor A has a recess in a part of the outer periphery thereof and the conductor B has a structure in which it is disposed so that a part or the whole thereof fits into the recess of the conductor A,
one of the pair of power supply electrodes and the conductor B fitting into the recess of the conductor A are electrically connected to each other using a metal wire,
the conductor A has a shape that substantially has line symmetry,
the conductor B is disposed in such a manner as to have an outer frame center in a position to avoid the centerlines of vertical and horizontal directions of the solid-state light-emitting element, and
the conductor B is disposed in a portion adjacent to the periphery of the element mounting area other than the outflow-adhesive capturing areas while being separated electrically from the conductor A.
